(19) United States
(12) Patent Application Publication
(10) Pub. No.: US 2026/0150273 A1
(43) Pub. Date: May 28, 2026

(54) SEMICONDUCTOR MEMORY DEVICE

(71) Applicant: Samsung Electronics Co., Ltd., Suwon-si (KR)

(72) Inventors: Hyungki Cho, Suwon-si (KR); Sungwon Yoo, Suwon-si (KR)

(21) Appl. No.: 19/391,573

(22) Filed: Nov. 17, 2025

(30) Foreign Application Priority Data
Nov. 28, 2024 (KR) 10-2024-0173947

(51) Int. Cl. H10B 12/00; H10D 1/68; H10D 30/67

(52) U.S. Cl. CPC H10B 12/488; H10B 12/482; H10D 1/714; H10D 30/6734; H10B 12/03; H10B 12/05

(57) ABSTRACT

A semiconductor memory device includes a semiconductor pattern, a capping structure surrounding the semiconductor pattern, a bit line electrically connected to an end of the semiconductor pattern in a first horizontal direction and extending in a vertical direction, an information storage element electrically connected to another end of the semiconductor pattern in the first horizontal direction, a word line intersecting with the semiconductor pattern and extending in a second horizontal direction orthogonal to the first horizontal direction, and a gate dielectric layer provided between the word line and the semiconductor pattern, in which the capping structure includes a first capping layer, a second capping layer, a third capping layer, and a fourth capping layer, and each of the first capping layer, the third capping layer, and the fourth capping layer has a thickness that is less than a thickness of the gate dielectric layer.

### CROSS-REFERENCE TO RELATED APPLICATION

This application claims priority to Korean Patent Application No. 10-2024-0173947, filed in the Korean Intellectual Property Office on Nov. 28, 2024, the disclosure of which is incorporated by reference herein in its entirety.

### BACKGROUND

As electronic products become smaller with multi-functions and higher performance, high-capacity semiconductor memory devices are used with an increased degree of integration to provide high-capacity semiconductor memory devices. The degree of integration of semiconductor memory devices that include a plurality of memory cells arranged in two dimensions may be determined by the area occupied by a unit memory cell. The degree of integration of two-dimensional semiconductor memory devices has increased but is still limited. A three-dimensional semiconductor memory device, which increases memory capacity by stacking memory cells in a vertical direction above a substrate to include a plurality of memory cells arranged in three dimensions, has been proposed.

### SUMMARY

In general, the present disclosure is directed toward a three-dimensional semiconductor memory device having improved operational reliability.

According to some implementations, the present disclosure is directed to a semiconductor memory device that includes a semiconductor pattern extending in a first horizontal direction, a capping structure surrounding the semiconductor pattern, a bit line electrically connected to an end of the semiconductor pattern in the first horizontal direction and extending in a vertical direction, an information storage element electrically connected to another end of the semiconductor pattern in the first horizontal direction, a word line intersecting with the semiconductor pattern and extending in a second horizontal direction orthogonal to the first horizontal direction, and a gate dielectric layer provided between the word line and the semiconductor pattern, wherein the capping structure includes a first capping layer, a second capping layer, a third capping layer, and a fourth capping layer, the first capping layer covering each of upper and lower surfaces of the semiconductor pattern, the second capping layer covering each of two side surfaces of the semiconductor pattern in the second horizontal direction, the third capping layer covering a side surface of the end of the semiconductor pattern which faces the bit line in the first horizontal direction, and the fourth capping layer covering a side surface of the other end of the semiconductor pattern which faces the information storage element in the first horizontal direction, and each of the first capping layer, the third capping layer, and the fourth capping layer has a thickness that is less than a thickness of the gate dielectric layer.

According to some implementations, the present disclosure is directed to a semiconductor memory device that includes a plurality of device separation layers apart from each other in each of a first horizontal direction and a second horizontal direction and extending in a vertical direction, the second horizontal direction being orthogonal to the first horizontal direction, a semiconductor pattern apart from the plurality of device separation layers and extending in the first horizontal direction between a pair of device separation layers adjacent to each other in the second horizontal direction, among the plurality of device separation layers, and between another pair of device separation layers adjacent to each other in the second horizontal direction, among the plurality of device separation layers, in a plan view, a capping structure surrounding the semiconductor pattern, a bit line electrically connected to an end of the semiconductor pattern in the first horizontal direction and extending in the vertical direction, an information storage element electrically connected to another end of the semiconductor pattern in the first horizontal direction, a word line intersecting with the semiconductor pattern and extending in the second horizontal direction, an insulating pattern provided between the word line and the information storage element, and a gate dielectric layer provided between the word line and the semiconductor pattern, wherein a portion of the capping structure which covers a side surface of the end of the semiconductor pattern and another portion of the capping structure which covers a side surface of the other end of the semiconductor pattern each have a thickness that is less than a thickness of the gate dielectric layer.

According to some implementations, the present disclosure is directed to a semiconductor memory device that includes a plurality of device separation layers apart from each other in each of a first horizontal direction and a second horizontal direction and extending in a vertical direction, the second horizontal direction being orthogonal to the first horizontal direction, a semiconductor pattern apart from the plurality of device separation layers, extending in the first horizontal direction, and comprising an oxide semiconductor material between a pair of device separation layers adjacent to each other in the second horizontal direction, among the plurality of device separation layers, and between another pair of device separation layers adjacent to each other in the second horizontal direction, among the plurality of device separation layers, in a plan view, a capping structure including a first capping layer, a second capping layer, a third capping layer, and a fourth capping layer and completely surrounding the semiconductor pattern, the first capping layer covering each of upper and lower surfaces of the semiconductor pattern, the second capping layer covering each of two side surfaces of the semiconductor pattern in the second horizontal direction, the third capping layer covering a side surface of an end of the semiconductor pattern in the first horizontal direction, and the fourth capping layer covering a side surface of another end of the semiconductor pattern in the first horizontal direction, a bit line electrically connected to the end of the semiconductor pattern in the first horizontal direction, in contact with the third capping layer, and extending in the vertical direction, an information storage element in contact with the fourth capping layer, electrically connected to the other end of the semiconductor pattern in the first horizontal direction, and including a first electrode, a second electrode, and a capacitor dielectric layer provided between the first electrode and the second electrode, a word line intersecting with the semiconductor pattern and extending in the second horizontal direction, an insulating pattern provided between the word line and the first electrode and in contact with the first capping layer, and a gate dielectric layer provided between the word line and the semiconductor pattern and in contact with the first capping layer, wherein each of the third capping layer and the fourth capping layer has a thickness that is less than a thickness of each of the second capping layer and the gate dielectric layer.

### BRIEF DESCRIPTION OF THE DRAWINGS

Example implementations will be more clearly understood from the following detailed description, taken in conjunction with the accompanying drawings.

FIGS. 1A and 1B are each an equivalent circuit diagram illustrating an example of a memory cell array of a semiconductor memory device according to some implementations.

FIG. 2 is a block diagram illustrating an example of a semiconductor memory device according to some implementations.

FIG. 3 is a perspective view illustrating an example of a memory cell included in a semiconductor memory device according to some implementations

FIGS. 4A to 4F, 5A to 5F, 6A to 6F, 7A to 7F, 8A to 8F, 9A to 9F, 10A to 10F, 11A to 11F, 12A to 12F, 13A to 13F, 14A to 14F, 15A to 15F, 16A to 16F, 17A to 17F, and 18A to 18F are diagrams illustrating an example of a method of manufacturing a semiconductor memory device according to some implementations.

FIGS. 19A to 19F are diagrams illustrating an example of a semiconductor memory device according to some implementations.

FIG. 20 is a perspective view illustrating an example of a memory cell included in a semiconductor memory device according to some implementations.

FIGS. 21A to 21F are diagrams illustrating an example of a semiconductor memory device according to some implementations.

### DETAILED DESCRIPTION

Hereinafter, example implementations will be explained in detail with reference to the accompanying drawings.

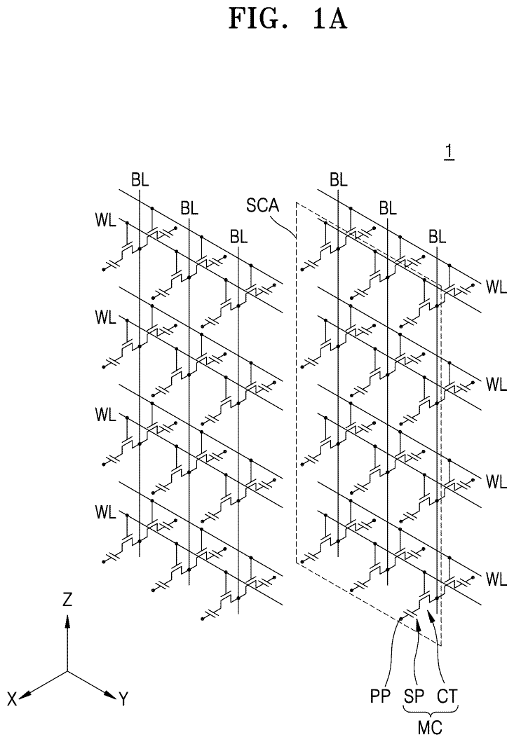

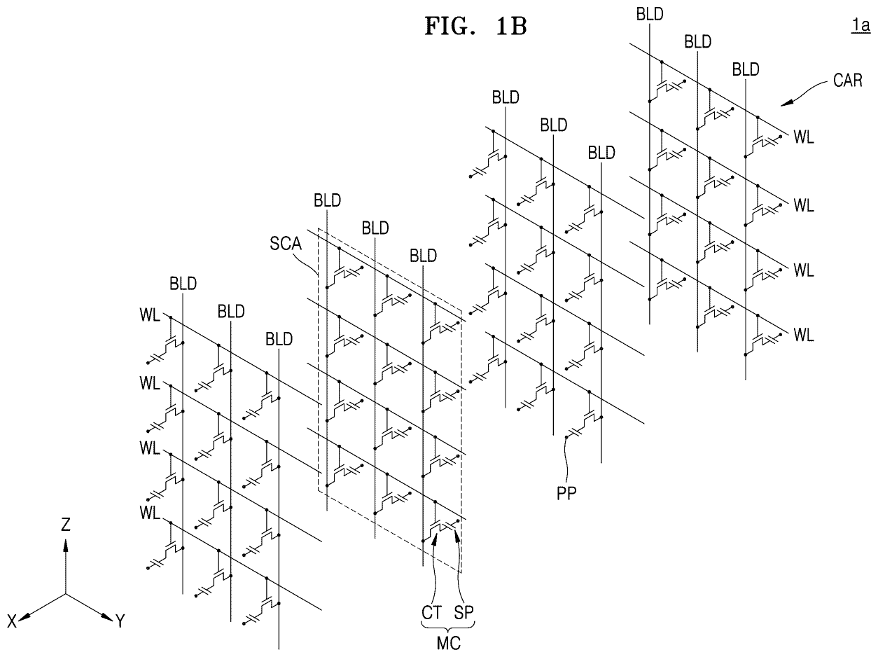

FIGS. 1A and 1B are each an equivalent circuit diagram illustrating an example of a memory cell array of a semiconductor memory device according to some implementations. In FIG. 1A, a memory cell array of a semiconductor memory device 1 may include a plurality of sub-cell arrays SCA. The sub-cell array SCA may include a plurality of bit lines BL, a plurality of word lines WL, and a plurality of memory cells MC. Each of the plurality of memory cells MC may include a cell transistor CT and an information storage element SP. One cell transistor CT may be arranged between one word line WL and one bit line BL. The information storage element SP may be a memory element capable of storing data.

The word line WL may be a conductive pattern (e.g., a metal line) arranged above a substrate to be apart from the substrate. In the memory cell array of the semiconductor memory device 1, the plurality of word lines WL may be apart from each other in each of a first horizontal direction (X direction) and a vertical direction (Z direction), and may extend in a second horizontal direction (Y direction). The second horizontal direction (Y direction) may be orthogonal to the first horizontal direction (X direction). The word lines WL within one sub-cell array SCA may be apart from each other in the vertical direction (Z direction). The bit line BL may extend in the vertical direction (Z direction) from the substrate. The bit lines BL within one sub-cell array SCA may be apart from each other in the second horizontal direction (Y direction).

In the memory cell array of the semiconductor memory device 1, the plurality of bit lines BL may extend in the vertical direction (Z direction), and may be apart from each other in each of the first horizontal direction (X direction) and the second horizontal direction (Y direction). The plurality of sub-cell arrays SCA may be arranged in the first horizontal direction (X direction).

In some implementations, the information storage element SP may be a memory element using a capacitor, a memory element using a magnetic tunnel junction pattern, or a memory element using a variable resistor including a phase change material. For example, the memory cell MC may be a dynamic random-access memory (DRAM) cell, and the information storage element SP may be a capacitor. In some implementations, the information storage element SP may be a transistor capable of storing data together with the cell transistor CT. For example, the memory cell MC may be a two-transistor-zero-capacitor (2T-0C) DRAM cell. The word line WL may be referred to as a first conductive line, and the bit line BL may be referred to as a second conductive line.

A gate of the cell transistor CT may be connected to the word line WL, and a source region of the cell transistor CT may be connected to the bit line BL. The information storage element SP may be connected to a drain region of the cell transistor CT. In some implementations, the information storage element SP may be a capacitor including a first electrode, a second electrode, and a capacitor dielectric layer provided between the first electrode and the second electrode, wherein the first electrode of the capacitor may be connected to the drain region of the cell transistor CT, and the second electrode of the capacitor may be connected to a ground wiring PP. The word line WL may surround at least a portion of a channel region of the cell transistor CT. The channel region of the cell transistor CT may be located between the source region and the drain region of the cell transistor CT.

In some implementations, the word line WL may have a gate-all-around shape covering upper and lower surfaces and two side surfaces in the second horizontal direction (Y direction) of the channel region of the cell transistor CT. In some implementations, the word line WL may have a double-gate shape covering the upper and lower surfaces of the channel region of the cell transistor CT. In some implementations, the word line WL may have a single-gate shape covering one of the upper and lower surfaces of the channel region of the cell transistor CT.

The memory cell array of the semiconductor memory device 1 may include a plurality of sub-cell arrays SCA each including: a plurality of memory cells MC arranged apart from each other in rows and columns in the second horizontal direction (Y direction) and the vertical direction (Z direction), respectively; a plurality of bit lines BL connected to the cell transistors CT of the memory cells MC, which are arranged in the vertical direction (Z direction), extending in the vertical direction (Z direction), and arranged apart from each other in the second horizontal direction (Y direction); and a plurality of word lines WL extending in the second horizontal direction (Y direction) and arranged apart from each other in the vertical direction (Z direction), wherein the plurality of sub-cell arrays SCA may be arranged in the first horizontal direction (X direction). The semiconductor memory device 1 may include a plurality of memory cell arrays.

The first horizontal direction (X direction), the second horizontal direction (Y direction), and the vertical direction (Z direction) may be referred to as a first direction, a second direction, and a third direction, respectively. In some implementations, the first horizontal direction (X direction), the vertical direction (Z direction), and the second horizontal direction (Y direction) may be referred to as a first direction, a second direction, and a third direction, respectively. The first direction, the second direction, and the third direction may be orthogonal to each other.

Two sub-cell arrays SCA adjacent to each other in the first horizontal direction (X direction) may share bit lines BL. The source regions of the cell transistors CT respectively included in the two sub-cell arrays SCA may be connected to the bit lines BL shared by the two sub-cell arrays SCA. From each of the bit lines BL shared by the two sub-cell arrays SCA, the source regions and drain regions of the respective cell transistors CT and the respective information storage elements SP of the two sub-cell arrays SCA may be arranged in opposite directions. For example, the cell transistor CT of one of the two sub-cell arrays SCA and the cell transistor CT of the other sub-cell array SCA may be connected to one bit line BL shared by the two sub-cell arrays SCA, wherein the source region of the cell transistor CT, the drain region of the cell transistor CT, and the information storage element SP of one sub-cell array SCA may be sequentially arranged in the first horizontal direction (X direction), and the source region of the cell transistor CT, the drain region of the cell transistor CT, and the information storage element SP of the other sub-cell array SCA may be sequentially arranged in a direction opposite to the first horizontal direction (X direction). For example, between a pair of bit lines BL sequentially arranged adjacent to each other in the first horizontal direction (X direction) among the plurality of bit lines BL, two memory cells MC may be arranged at the same vertical level in the first horizontal direction (X direction).

In FIG. 1B, the memory cell array of the semiconductor memory device 1a may include a plurality of sub-cell arrays SCA. The sub-cell array SCA may include a plurality of bit lines BLD, a plurality of word lines WL, and a plurality of memory cells MC. Each of the plurality of memory cells MC may include a cell transistor CT and an information storage element SP. One cell transistor CT may be arranged between one word line WL and one bit line BLD. The plurality of sub-cell arrays SCA may be arranged in the first horizontal direction (X direction).

The plurality of word lines WL may extend in the second horizontal direction (Y direction). The word lines WL within one sub-cell array SCA may be apart from each other in the vertical direction (Z direction). The bit line BLD may extend in the vertical direction (Z direction). The bit lines BLD within one sub-cell array SCA may be apart from each other in the second horizontal direction (Y direction).

A gate of the cell transistor CT may be connected to the word line WL, and a source region of the cell transistor CT may be connected to the bit line BLD. The information storage element SP may be connected to a drain region of the cell transistor CT. The word line WL may surround at least a portion of a channel region of the cell transistor CT.

A pair of bit lines BLD adjacent to each other in the first horizontal direction (X direction) may perform substantially the same function as one bit line BL shown in FIG. 1A. For example, when one bit line BL shown in FIG. 1A is separated into two bit lines BL that are apart from each other in the first horizontal direction (X direction), the two bit lines BL may become a pair of bit lines BLD that are adjacent to each other in the first horizontal direction (X direction), as shown in FIG. 1B. The source region and drain region of the cell transistor CT and the information storage element SP may be arranged in the first horizontal direction (X direction) or a direction opposite to the first horizontal direction (X direction), from the bit line BLD connected to the source region of the cell transistor CT. The source regions and drain regions of the cell transistors CT, which are respectively connected to two bit lines BLD adjacent to each other in the first horizontal direction (X direction), and the information storage elements SP respectively connected to the cell transistors CT may be arranged in opposite directions. For example, the source region and drain region of the cell transistor CT, which is connected to one of the two bit lines BLD adjacent to each other in the first horizontal direction (X direction), and the information storage element SP connected to the cell transistor CT may be sequentially arranged in the first horizontal direction (X direction), and the source region and drain region of the cell transistor CT, which is connected to the other bit line BLD, and the information storage element SP connected to the cell transistor CT may be sequentially arranged in a direction opposite to the first horizontal direction (X direction). For example, the plurality of bit lines BLD may include a first bit line, a second bit line, a third bit line, and a fourth bit line that are sequentially arranged adjacent to each other in the first horizontal direction (X direction), wherein a memory cell MC may not be arranged between the first bit line and the second bit line, two memory cells MC may be arranged between the second bit line and the third bit line at the same vertical level in the first horizontal direction (X direction), and a memory cell MC may not be arranged between the third bit line and the fourth bit line.

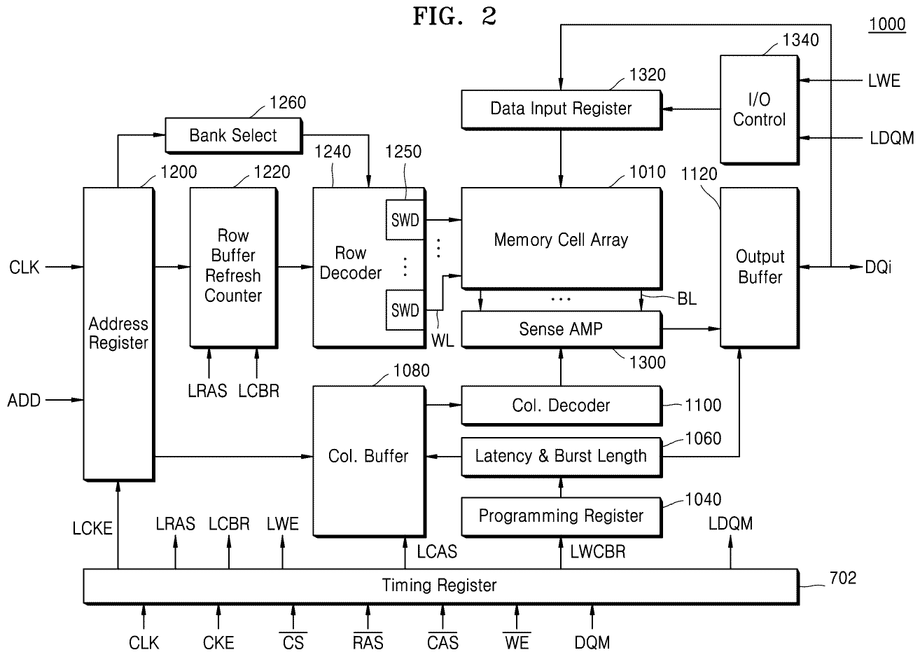

FIG. 2 is a block diagram illustrating an example of a semiconductor memory device according to some implementations. In FIG. 2, a semiconductor memory device 1000 may include a memory cell array 1010 including a DRAM cell, which is a memory cell, and various circuit blocks for driving the DRAM cell. For example, a timing register 702 may be activated when a chip select signal CSB is changed from an inactive level (e.g., logic high) to an active level (e.g., logic low). The timing register 702 may receive command signals, such as a clock signal CLK, a clock enable signal CKE, a chip select signal CSB, a row address strobe signal RASB, a column address strobe signal CASB, a write enable signal WEB, and a data input/output mask signal DQM, from the outside, and may process the received command signals to generate various internal command signals, such as LCKE, LRAS, LCBR, LWE, LCAS, LWCBR, and LDQM, for controlling the circuit blocks.

Some of the internal command signals generated by the timing register 702 may be stored in a programming register 1040. For example, latency information or burst length information associated with data output may be stored in the programming register 1040. The internal command signals stored in the programming register 1040 may be provided to a latency/burst length controller 1060, and the latency/burst length controller 1060 may provide a control signal for controlling the latency or burst length of data output to a column decoder 1100 or an output buffer 1120 through a column address buffer 1080.

An address register 1200 may receive a clock signal CLK and an address signal ADD from the outside. A row address signal may be provided to a row decoder 1240 through a row address buffer 1220. Also, a column address signal may be provided to the column decoder 1100 through the column address buffer 1080. The row address buffer 1220 may further receive a refresh address signal generated by a refresh counter in response to refresh commands LRAS and LCBR, and may provide one of the row address signal and the refresh address signal to the row decoder 1240. Also, the address register 1200 may provide a bank signal for selecting a bank to a bank selector 1260.

The row decoder 1240 may decode the row address signal or the refresh address signal input from the row address buffer 1220. The row decoder 1240 may include a plurality of sub-word line drivers 1250. The sub-word line driver 1250 may activate a word line WL of the memory cell array 1010. The sub-word line drivers 1250 may be arranged in blocks at certain intervals within the row decoder 1240 so as to be adjacent to the memory cell array 1010. For example, the sub-word line driver 1250 may be arranged adjacent to an end of the memory cell array 1010 so as to be perpendicular to a sense amplifier 1300.

The column decoder 1100 may decode the column address signal, and may perform a selection operation on a bit line BL of the memory cell array 1010. For example, a column selection line may be applied to the semiconductor memory device 1000, and a selection operation may be performed through the column selection line.

The sense amplifier 1300 may amplify data of a memory cell selected by the row decoder 1240 and the column decoder 1100, and may provide the amplified data to the output buffer 1120. The output buffer 1120 may output output data DQi. Data to be written to a data cell may be provided to the memory cell array 1010 through a data input register 1320, and an input/output controller 1340 may control a data transmission operation through the data input register 1320.

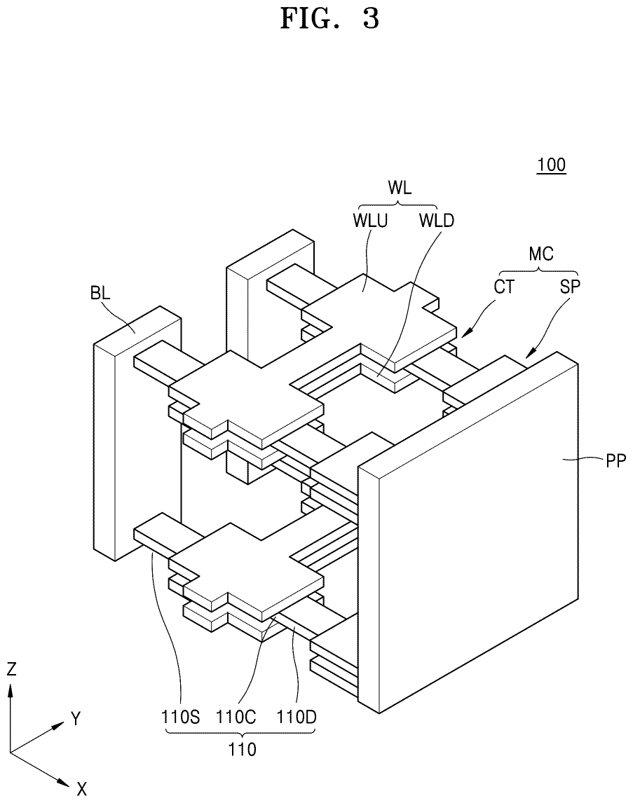

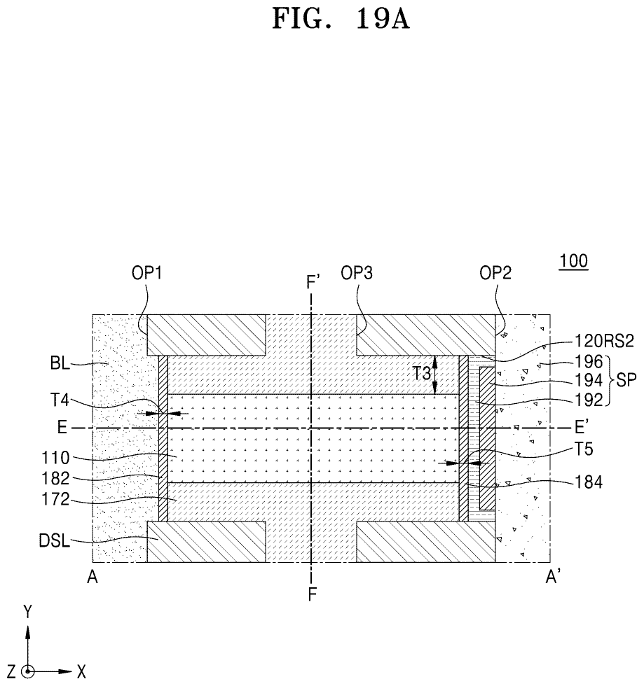

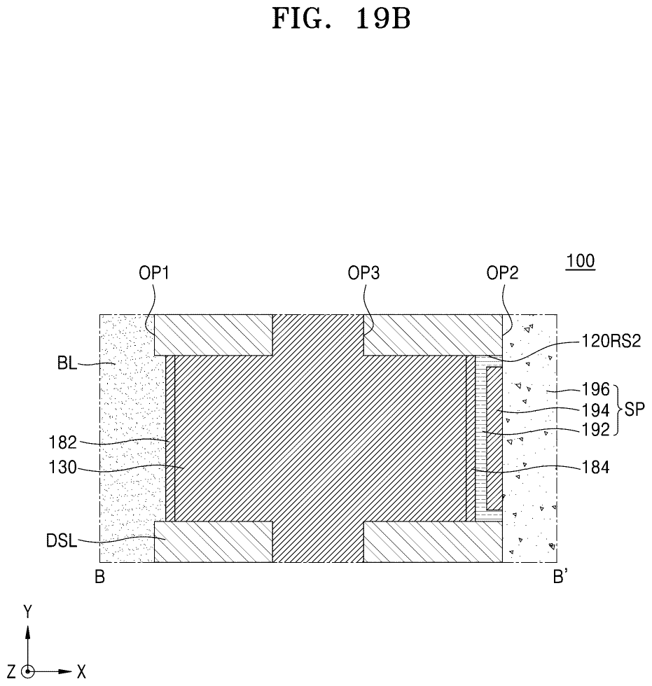

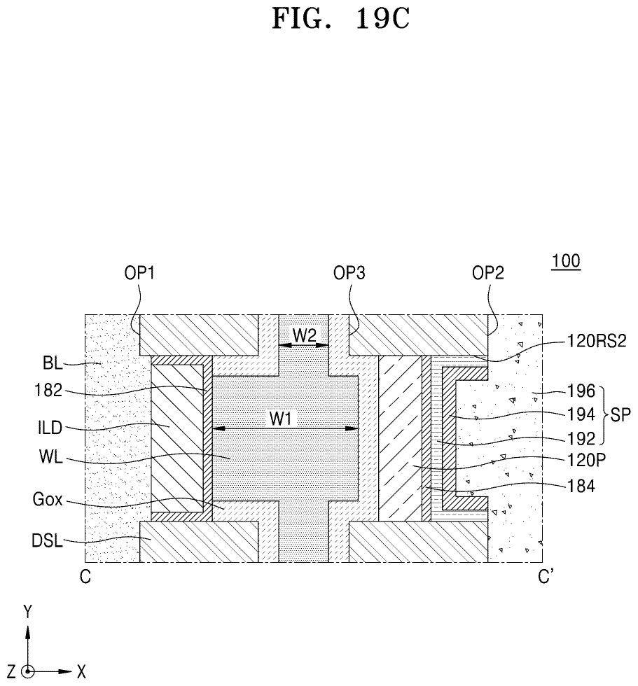

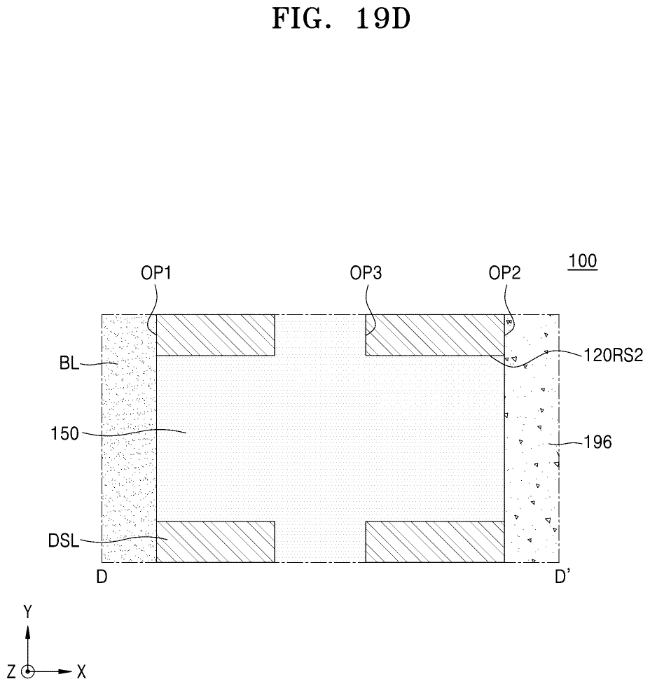

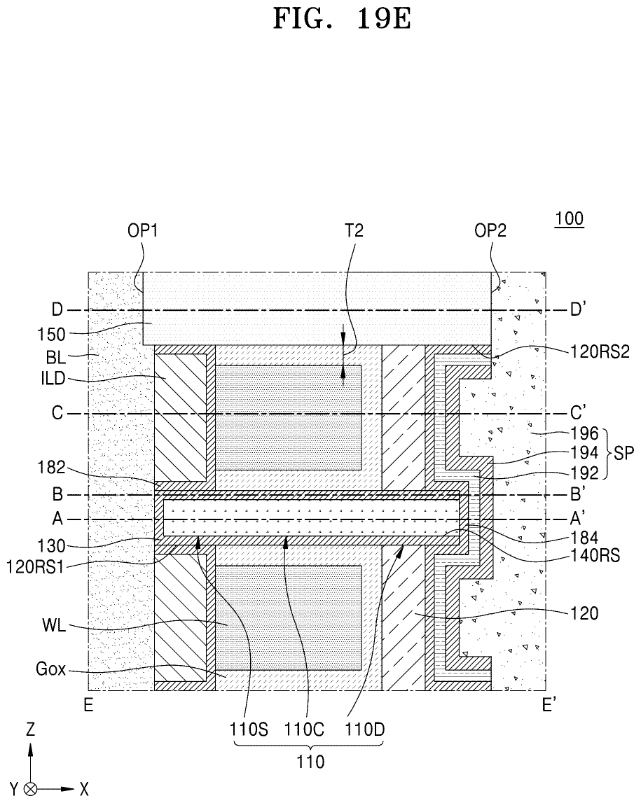

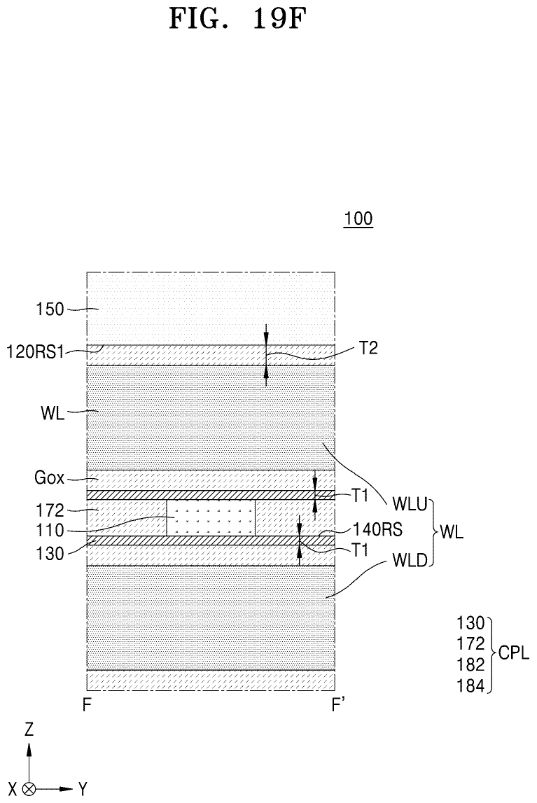

FIG. 3 is a perspective view illustrating an example of a memory cell included in a semiconductor memory device according to some implementations. In FIG. 3, a semiconductor memory device 100 may include a memory cell MC including a cell transistor CT and an information storage element SP. The cell transistor CT may be arranged between a word line WL and a bit line BL. The cell transistor CT may include a semiconductor pattern 110. An end of the semiconductor pattern 110 may face the bit line BL, and the other end of the semiconductor pattern 110 may face the information storage element SP. The end of the semiconductor pattern 110 may be electrically connected to the bit line BL, and the other end of the semiconductor pattern 110 may be electrically connected to the information storage element SP. A capping structure CPL (see FIG. 19F) may be provided between the semiconductor pattern 110 and the bit line BL and between the semiconductor pattern 110 and the information storage element SP. The capping structure CPL (see FIG. 19F) may have a relatively small thickness to enable electrical connection between the semiconductor pattern 110 and the bit line BL and between the semiconductor pattern 110 and the information storage element SP through tunneling.

The word line WL may intersect with the semiconductor pattern 110 and extend in the second horizontal direction (Y direction), the bit line BL may extend in the vertical direction (Z direction), and the semiconductor pattern 110 may extend in the first horizontal direction (X direction). A gate dielectric layer Gox (see FIGS. 19E and 19F) may be provided between the word line WL and the semiconductor pattern 110. In some implementations, the bit line BL, the semiconductor pattern 110, and the information storage element SP may be sequentially located in the first horizontal direction (X direction).

The semiconductor pattern 110 may include a source region 110S, a drain region 110D, and a channel region 110C located between the source region 110S and the drain region 110D. The source region 110S of the semiconductor pattern 110 may be electrically connected to the bit line BL. The drain region 110D of the semiconductor pattern 110 may be electrically connected to the information storage element SP. In some implementations, the information storage element SP may be a capacitor including a first electrode, a second electrode, and a capacitor dielectric layer provided between the first electrode and the second electrode, wherein the first electrode of the capacitor may be electrically connected to a drain region of the cell transistor CT, and the second electrode of the capacitor may be connected to a ground wiring PP. The word line WL may surround at least a portion of the channel region 110C of the semiconductor pattern 110.

In some implementations, the word line WL may have a double-gate shape covering upper and lower surfaces of the channel region 110C of the semiconductor pattern 110. For example, the word line WL may include a lower word line WLD located below the semiconductor pattern 110 and an upper word line WLU located above the semiconductor pattern 110. For example, the upper word line WLU may cover the upper surface of the channel region 110C of the semiconductor pattern 110, and the lower word line WLD may cover the lower surface of the channel region 110C of the semiconductor pattern 110.

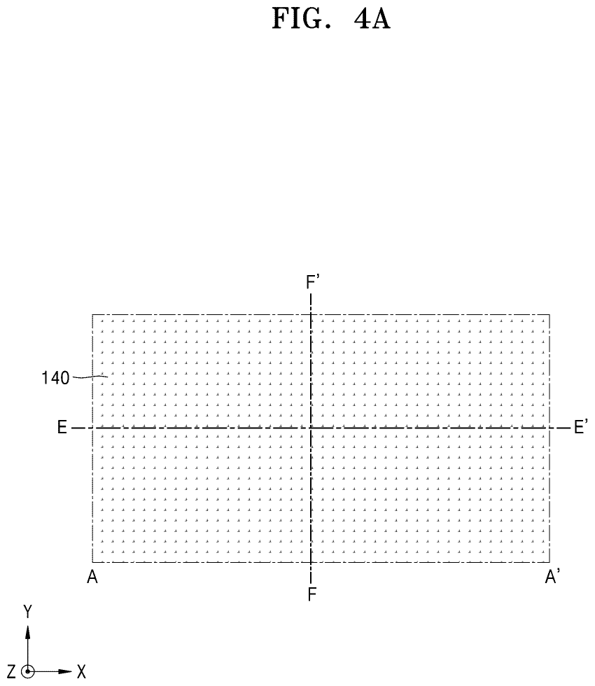

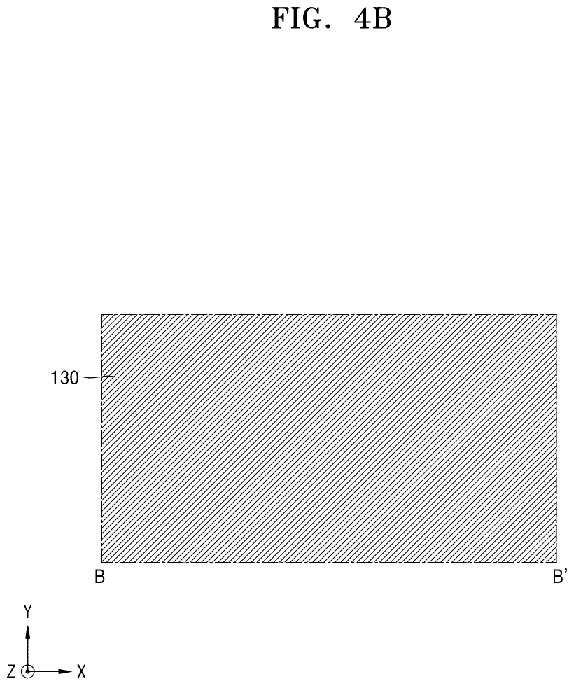

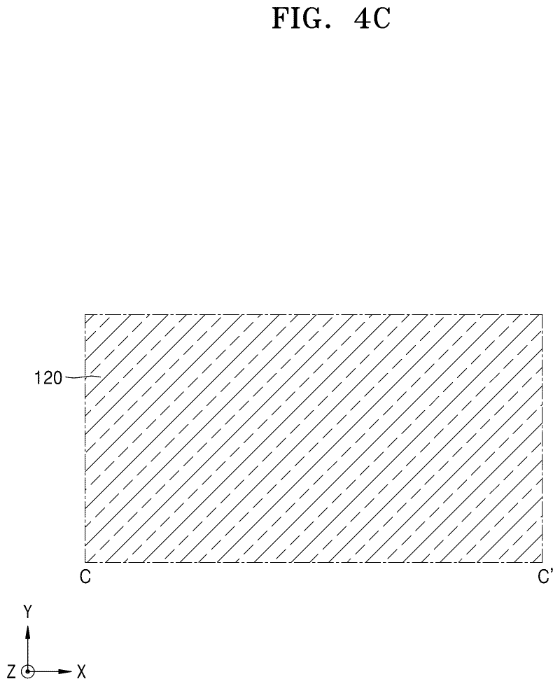

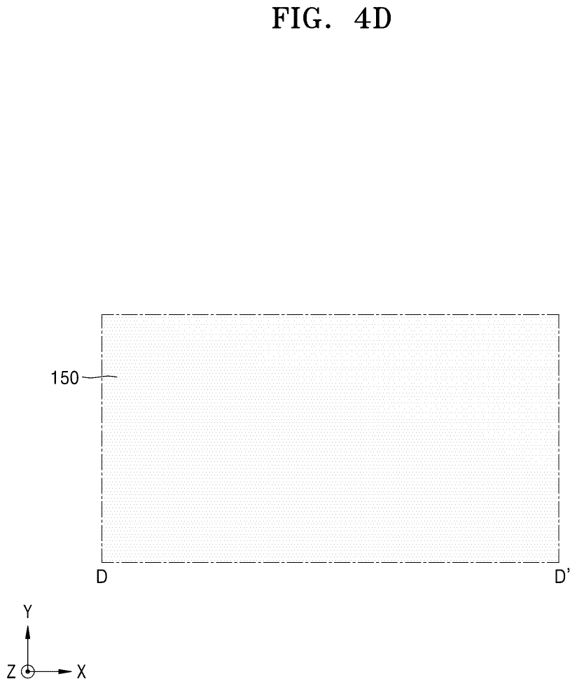

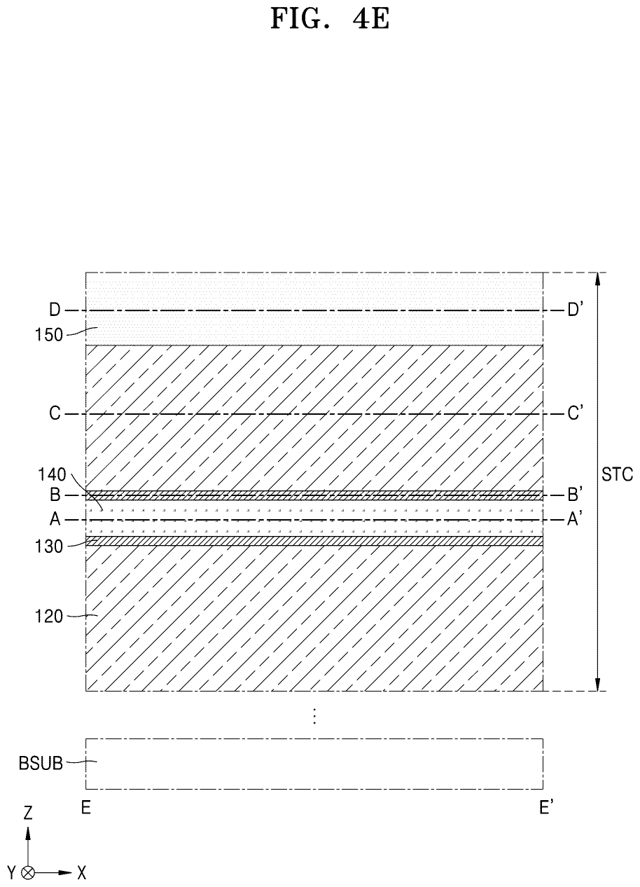

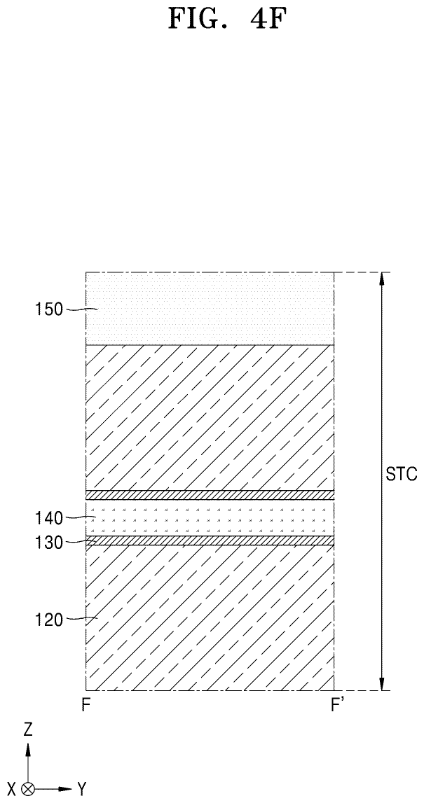

FIGS. 4A to 4F, 5A to 5F, 6A to 6F, 7A to 7F, 8A to 8F, 9A to 9F, 10A to 10F, 11A to 11F, 12A to 12F, 13A to 13F, 14A to 14F, 15A to 15F, 16A to 16F, 17A to 17F, and 18A to 18F are diagrams illustrating an example of a method of manufacturing a semiconductor memory device according to some implementations. In detail, FIGS. 4A, 5A, 6A, 7A, 8A, 9A, 10A, 11A, 12A, 13A, 14A, 15A, 16A, 17A, and 18A are horizontal cross-sectional views of a portion taken along a line A-A′ of FIGS. 4E, 5E, 6E, 7E, 8E, 9E, 10E, 11E, 12E, 13E, 14E, 15E, 16E, 17E, and 18E; FIGS. 4B, 5B, 6B, 7B, 8B, 9B, 10B, 11B, 12B, 13B, 14B, 15B, 16B, 17B, and 18B are horizontal cross-sectional views of a portion taken along a line B-B′ of FIGS. 4E, 5E, 6E, 7E, 8E, 9E, 10E, 11E, 12E, 13E, 14E, 15E, 16E, 17E, and 18E; FIGS. 4C, 5C, 6C, 7C, 8C, 9C, 10C, 11C, 12C, 13C, 14C, 15C, 16C, 17C, and 18C are horizontal cross-sectional views of a portion taken along a line C-C′ of FIGS. 4E, 5E, 6E, 7E, 8E, 9E, 10E, 11E, 12E, 13E, 14E, 15E, 16E, 17E, and 18E; FIGS. 4D, 5D, 6D, 7D, 8D, 9D, 10D, 11D, 12D, 13D, 14D, 15D, 16D, 17D, and 18D are horizontal cross-sectional views of a portion taken along a line D-D′ of FIGS. 4E, 5E, 6E, 7E, 8E, 9E, 10E, 11E, 12E, 13E, 14E, 15E, 16E, 17E, and 18E; FIGS. 4E, 5E, 6E, 7E, 8E, 9E, 10E, 11E, 12E, 13E, 14E, 15E, 16E, 17E, and 18E are vertical cross-sectional views of a portion taken along a line E-E′ of FIGS. 4A, 5A, 6A, 7A, 8A, 9A, 10A, 11A, 12A, 13A, 14A, 15A, 16A, 17A, and 18A; and FIGS. 4F, 5F, 6F, 7F, 8F, 9F, 10F, 11F, 12F, 13F, 14F, 15F, 16F, 17F, and 18F are vertical cross-sectional views of a portion taken along a line F-F′ of FIGS. 4A, 5A, 6A, 7A, 8A, 9A, 10A, 11A, 12A, 13A, 14A, 15A, 16A, 17A, and 18A.

In FIGS. 4A to 4F together, a plurality of stack structures STC may be stacked above a base substrate BSUB. Each of the plurality of stack structures STC may include two sacrificial insulating layers 120, two first capping layers 130, a sacrificial semiconductor layer 140, and a vertical separation insulating layer 150. Each of the sacrificial insulating layer 120, the first capping layer 130, the sacrificial semiconductor layer 140, and the vertical separation insulating layer 150 may be formed by a chemical vapor deposition (CVD), plasma enhanced CVD (PECVD), or atomic layer deposition (ALD) process.

For example, each of the plurality of stack structures STC may include a sacrificial semiconductor layer 140, a first capping layer 130, and a sacrificial insulating layer 120 that are arranged both above and below the sacrificial semiconductor layer 140, and a vertical separation insulating layer 150 covering the sacrificial insulating layer 120 on the upper side of the stack structure STC. That is, each of the plurality of stack structures STC may be a stacked structure in which one sacrificial insulating layer 120, one first capping layer 130, the sacrificial semiconductor layer 140, the other first capping layer 130, the other sacrificial insulating layer 120, and the vertical separation insulating layer 150 are arranged from the lower side to the upper side of the stack structure STC. Within the stack structure STC, the one first capping layer 130 and the one sacrificial insulating layer 120 that are arranged below the sacrificial semiconductor layer 140 may be referred to as a first lower capping layer and a lower sacrificial insulating layer, respectively, and the other first capping layer 130 and the other sacrificial insulating layer 120 that are arranged above the sacrificial semiconductor layer 140 may be referred to as a first upper capping layer and an upper sacrificial insulating layer, respectively.

Although FIGS. 4E and 4F show one stack structure STC above the base substrate BSUB for convenience of illustration, stack structures STC may be repeatedly stacked in the vertical direction (Z direction) above the base substrate BSUB. For example, the vertical separation insulating layer 150 may be provided between each pair of sub-structures each including the sacrificial semiconductor layer 140, and the first capping layer 130 and the sacrificial insulating layer 120 that are arranged both above and below the sacrificial semiconductor layer 140. For example, the vertical separation insulating layer 150 included in another stack structure STC may be arranged below the one sacrificial insulating layer 120 on the lower side of the stack structure STC. That is, between each pair of a plurality of vertical separation insulating layers 150 arranged above the base substrate BSUB in the vertical direction (Z direction), a sub-structure including the sacrificial semiconductor layer 140, and the first capping layer 130 and the sacrificial insulating layer 120 that are arranged both above and below the sacrificial semiconductor layer 140 may be arranged.

The base substrate BSUB may include, for example, silicon (Si), for example, crystalline Si, polycrystalline Si, or amorphous Si. In some implementations, the base substrate BSUB may include a semiconductor element, such as germanium (Ge), or at least one compound semiconductor selected from silicon germanium (SiGe), silicon carbide (SiC), gallium arsenide (GaAs), indium arsenide (InAs), and indium phosphide (InP). In some implementations, the base substrate BSUB may include a silicon-on-insulator (SOI) substrate or a germanium-on-insulator (GeOI) substrate. For example, the base substrate BSUB may include a buried oxide (BOX) layer. In some implementations, the base substrate BSUB may include a conductive region, for example, an impurity-doped well or an impurity-doped structure.

The sacrificial insulating layer 120 may include a material having an etch selectivity with respect to each of the base substrate BSUB, the first capping layer 130, the sacrificial semiconductor layer 140, and the vertical separation insulating layer 150. The sacrificial insulating layer 120 may include a nitride, an oxynitride, a carbonate, or an oxycarbonitride. For example, the sacrificial insulating layer 120 may include silicon nitride (SiN), silicon oxynitride (SiON), silicon carbonate (SiCO), or silicon oxycarbonitride (SiOCN). In some implementations, the sacrificial insulating layer 120 may include silicon nitride.

The first capping layer 130 may include a material having an etch selectivity with respect to each of the base substrate BSUB, the sacrificial insulating layer 120, the sacrificial semiconductor layer 140, and the vertical separation insulating layer 150. The first capping layer 130 may include at least one selected from silicon oxide, a high-k dielectric material having a higher dielectric constant than silicon oxide, and a ferroelectric material. For example, the high-k dielectric material and the ferroelectric material may include at least one material selected from hafnium oxide (HfO), hafnium silicate (HfSiO), hafnium oxynitride (HfON), hafnium silicon oxynitride (HfSiON), lanthanium oxide (LaO), lanthanium aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). In some embodiments, the first capping layer 130 may include a metal oxide. For example, the first capping layer 130 may include aluminum oxide (AlO) or hafnium oxide (HfO).

The sacrificial semiconductor layer 140 may include a semiconductor material. In some implementations, the sacrificial semiconductor layer 140 may include a material having similar etch characteristics as the base substrate BSUB, or may include the same material as the base substrate BSUB. In some implementations, the sacrificial semiconductor layer 140 may be include Si, Ge, SiGe, or a combination thereof. The sacrificial semiconductor layer 140 may include a single-crystalline semiconductor material or a polycrystalline semiconductor material. For example, the sacrificial semiconductor layer 140 may include single-crystalline Si or polysilicon.

The vertical separation insulating layer 150 may include at least one of silicon oxide and a low-k dielectric material having a lower dielectric constant than silicon oxide. For example, the vertical separation insulating layer 150 may include plasma enhanced oxide (PEOX), tetraethyl orthosilicate (TEOS), boro tetraethyl orthosilicate (BTEOS), phosphorous tetraethyl orthosilicate (PTEOS), boro phospho tetraethyl orthosilicate (BPTEOS), boro silicate glass (BSG), phospho silicate glass (PSG), boro phospho silicate glass (BPSG), etc. The low-k dielectric material may include, for example, fluorine-doped silicon oxide, organosilicate glass, carbon-doped oxide, porous silicon oxide, porous organosilicate glass, spin-on organic polymeric dielectric, spin-on silicon based polymeric dielectric, or a combination thereof, but is not limited thereto.

The first capping layer 130 may be formed thinner than each of the sacrificial insulating layer 120, the sacrificial semiconductor layer 140, and the vertical separation insulating layer 150. For example, the first capping layer 130 may be formed to have a first thickness T1, and each of the sacrificial insulating layer 120, the sacrificial semiconductor layer 140, and the vertical separation insulating layer 150 may be formed to have a thickness that is greater than the first thickness T1. The first capping layer 130 may be formed to have the first thickness T1 that may cause tunneling while blocking hydrogen movement between two layers between which the first capping layer 130 is provided. For example, the first thickness T1 may be 3 nm or less. In some embodiments, the first thickness T1 may be about 1 nm to about 1.5 nm. In some implementations, each of the sacrificial insulating layer 120, the sacrificial semiconductor layer 140, and the vertical separation insulating layer 150 may be formed to have a thickness of about 10 nm to about 40 nm. The sacrificial insulating layer 120 may be formed thicker than the first capping layer 130 and the sacrificial semiconductor layer 140. The sacrificial semiconductor layer 140 may be formed thinner than the sacrificial insulating layer 120 and thicker than the first capping layer 130. In some implementations, the vertical separation insulating layer 150 may be formed thinner than the sacrificial insulating layer 120, but is not limited thereto. For example, the vertical separation insulating layer 150 may be formed to have the same thickness as the sacrificial insulating layer 120, or may be formed thicker than the sacrificial insulating layer 120.

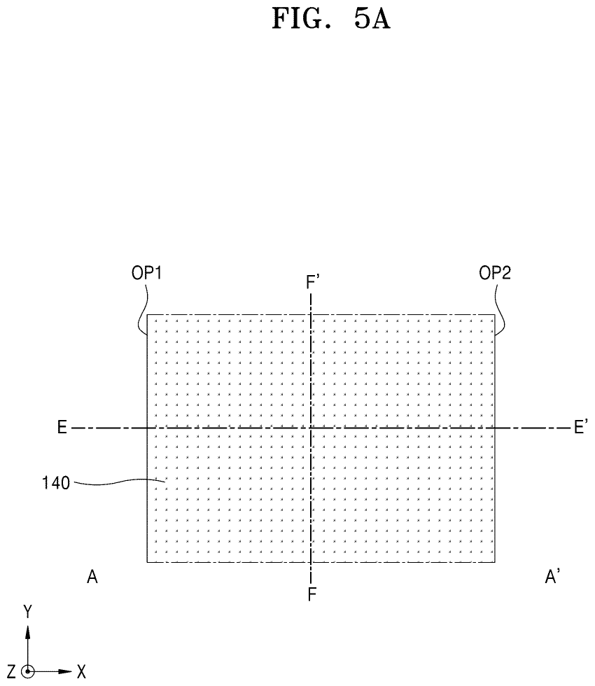

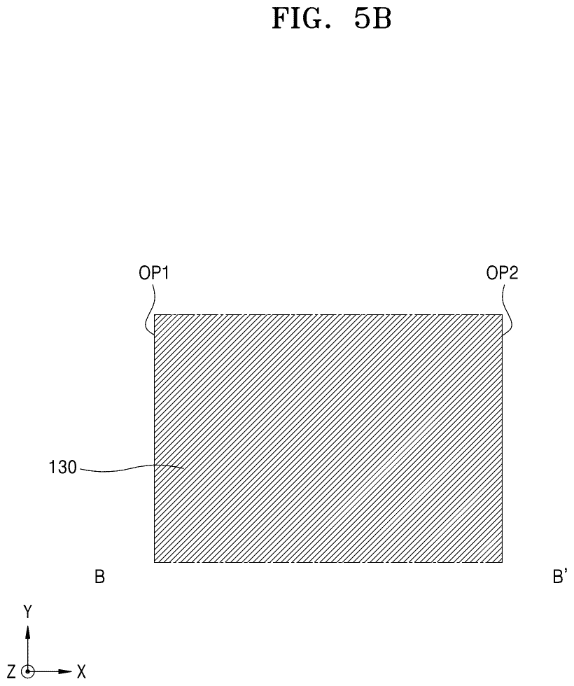

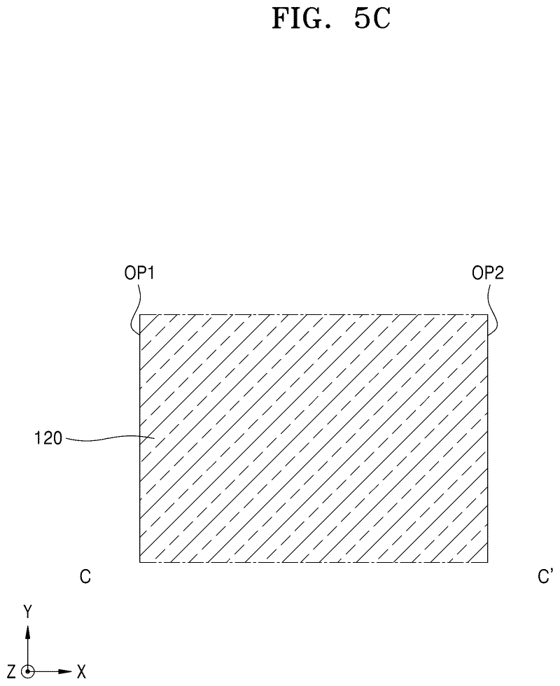

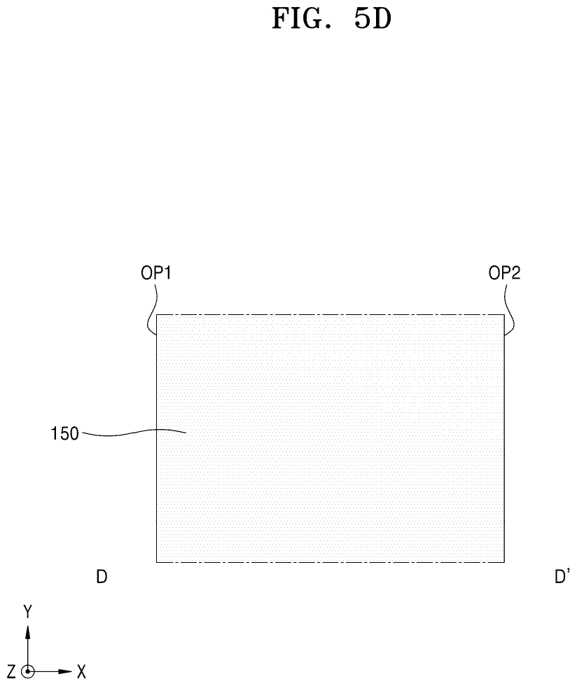

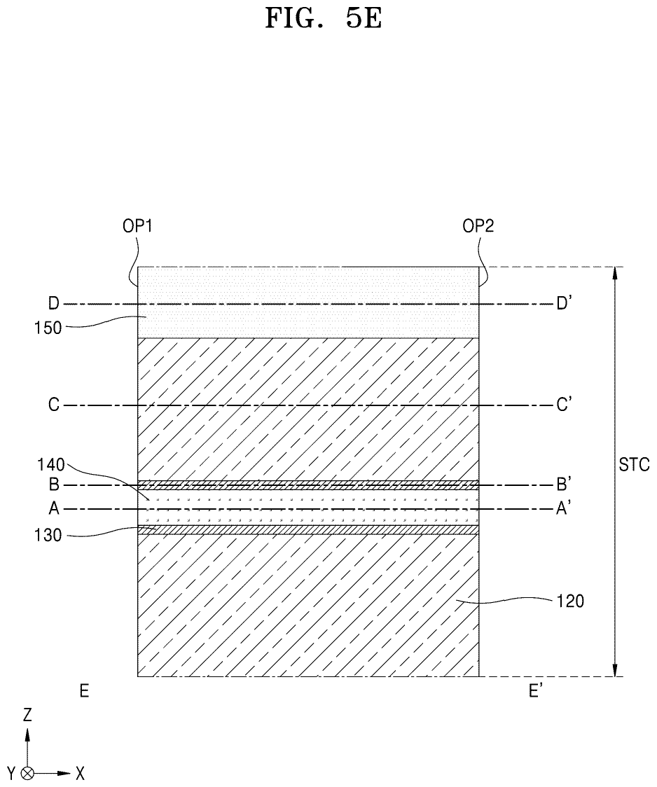

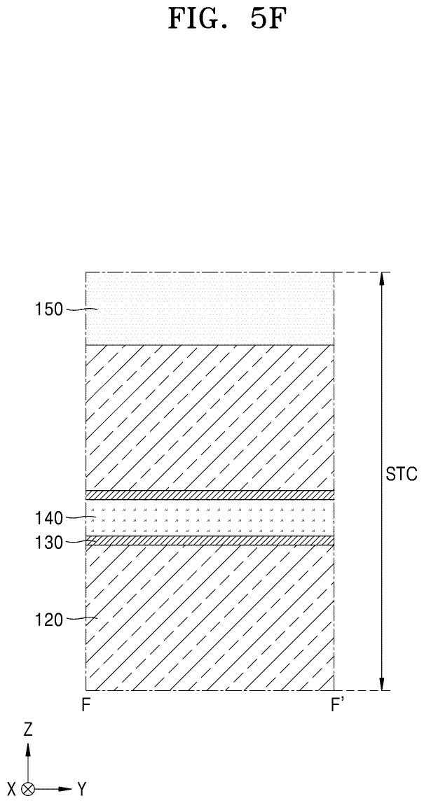

For convenience of illustration, FIGS. 5E, 6E, 7E, 8E, 9E, 10E, 11E, 12E, 13E, 14E, 15E, 16E, 17E, and 18E show only a portion corresponding to the stack structure STC portion of FIG. 4E, and FIGS. 5F, 6F, 7F, 8F, 9F, 10F, 11F, 12F, 13F, 14F, 15F, 16F, 17F, and 18F show only a portion corresponding to the stack structure STC portion of FIG. 4F.

In FIGS. 5A to 5F together, portions of the stack structure STC including the two sacrificial insulating layers 120, the two first capping layers 130, the sacrificial semiconductor layer 140, and the vertical separation insulating layer 150 may be removed to form a first opening OP1 and a second opening OP2 that are apart from each other in the first horizontal direction (X direction). For example, each of the first opening OP1 and the second opening OP2 may penetrate the vertical separation insulating layer 150, one sacrificial insulating layer 120, one first capping layer 130, the sacrificial semiconductor layer 140, the other first capping layer 130, and the other sacrificial insulating layer 120 included in the stack structure STC.

In a plan view, each of the first opening OP1 and the second opening OP2 may be formed to have a bar shape extending in the second horizontal direction (Y direction). The second horizontal direction (Y direction) may be orthogonal to the first horizontal direction (X direction). FIGS. 5A to 5D show that the first opening OP1 and the second opening OP2 have the same extension length in the second horizontal direction (Y direction), but present disclosure not limited thereto. In some implementations, the first opening OP1 and the second opening OP2 may have different extension lengths in the second horizontal direction (Y direction). For example, the second opening OP2 may have an extension length that is greater than the extension length of the first opening OP1 in the second horizontal direction (Y direction). For example, corresponding to the extension length of one second opening OP2 in the second horizontal direction (Y direction), a plurality of first openings OP1 that are apart from each other and each have an extension length that is less than the extension length of the second opening OP2 in the second horizontal direction (Y direction) may be arranged.

On an inner wall of each of the first opening OP1 and the second opening OP2, respective side surfaces of the two sacrificial insulating layers 120, the two first capping layers 130, the sacrificial semiconductor layer 140, and the vertical separation insulating layer 150 may be exposed. In some embodiments, the base substrate BSUB (see FIGS. 4E and 4F) may be exposed on a lower surface of each of the first opening OP1 and the second opening OP2. In some implementations, another vertical separation insulating layer 150 covering the base substrate BSUB (see FIGS. 4E and 4F) may be exposed on the lower surface of each of the first opening OP1 and the second opening OP2.

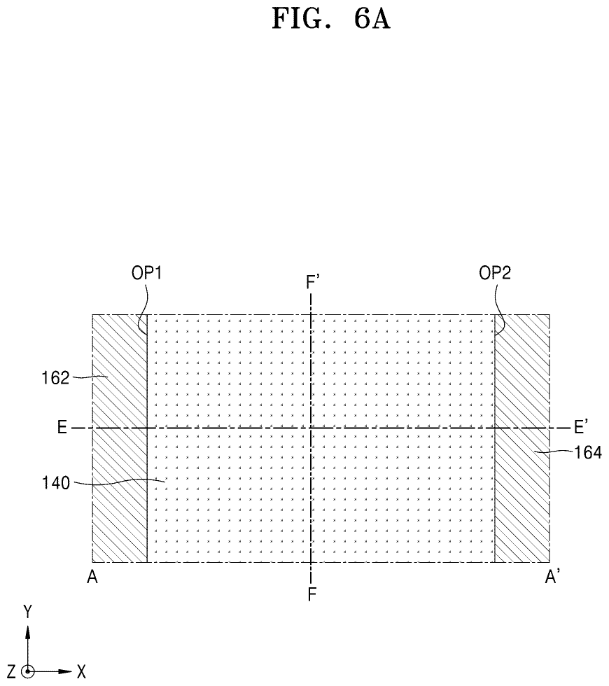

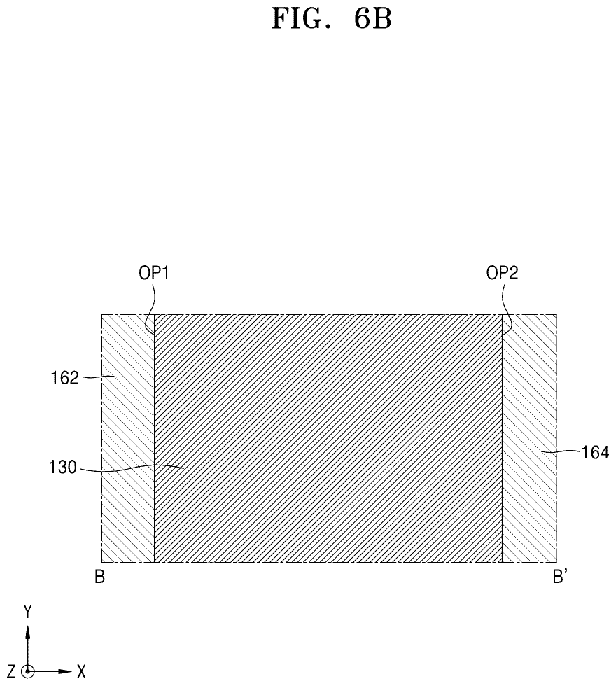

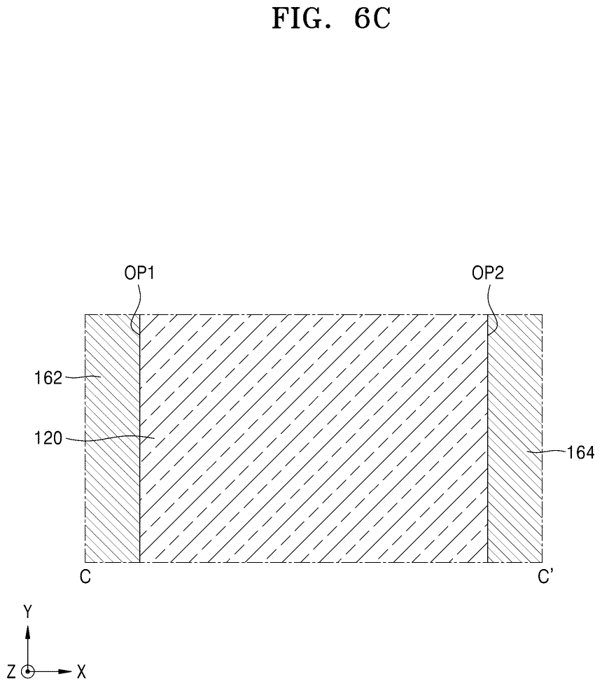

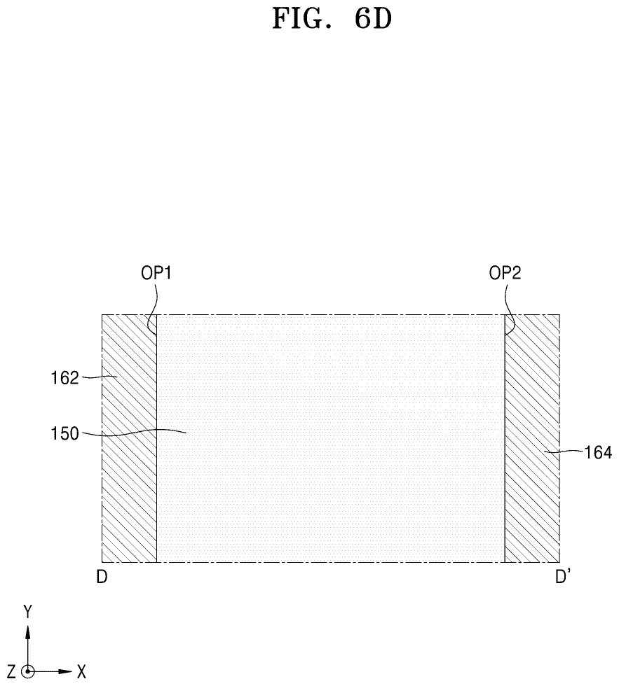

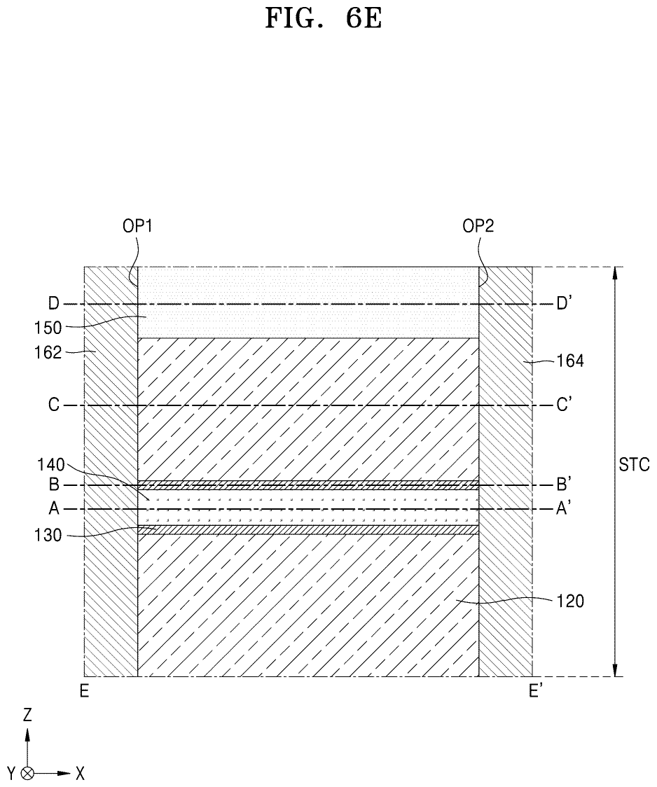

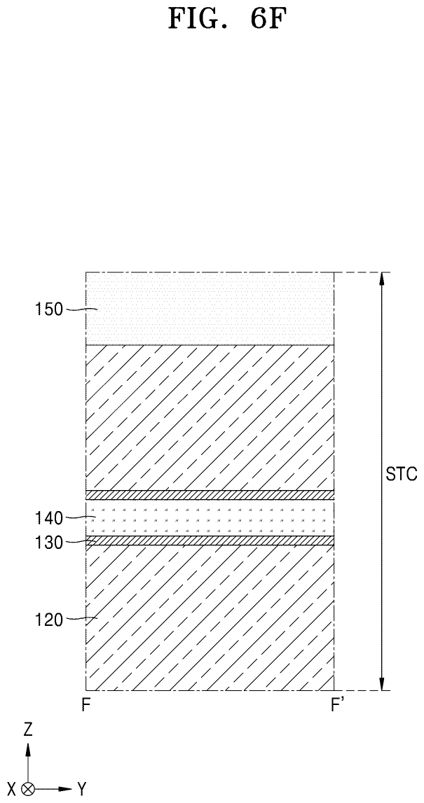

In FIGS. 6A to 6F, a first mold insulating layer 162 filling the first opening OP1 and a second mold insulating layer 164 filling the second opening OP2 may be formed. In some implementatons, each of the first mold insulating layer 162 and the second mold insulating layer 164 may include a material having an etch selectivity with respect to each of the sacrificial insulating layer 120, the first capping layer 130, the sacrificial semiconductor layer 140, and the vertical separation insulating layer 150. For example, each of the first mold insulating layer 162 and the second mold insulating layer 164 may include a silicon-containing insulating material, such as silicon oxide or silicon oxynitride, a carbon-containing material, such as an amorphous carbon layer (ACL) or a spin-on hardmask (SOH), or a combination thereof.

In some implementations, the first mold insulating layer 162 and the second mold insulating layer 164 may include the same material. For example, the first mold insulating layer 162 and the second mold insulating layer 164 may be formed by forming a mold insulating material layer that fills the first opening OP1 and the second opening OP2 and fills the stack structure STC, and then removing an upper portion of the mold insulating material layer so that the stack structure STC is exposed. The first mold insulating layer 162 and the second mold insulating layer 164 may include the same material.

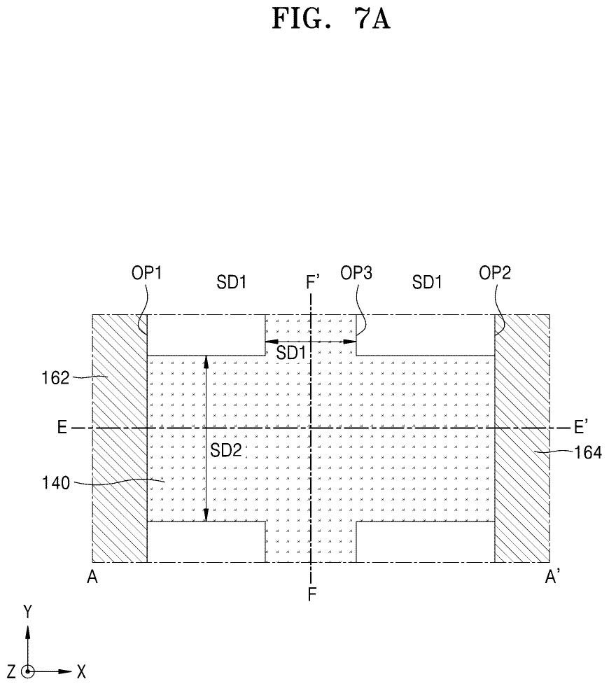

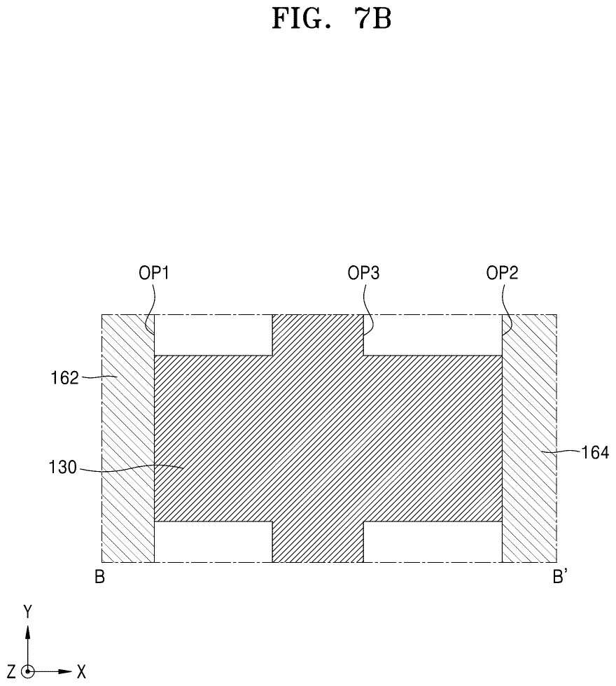

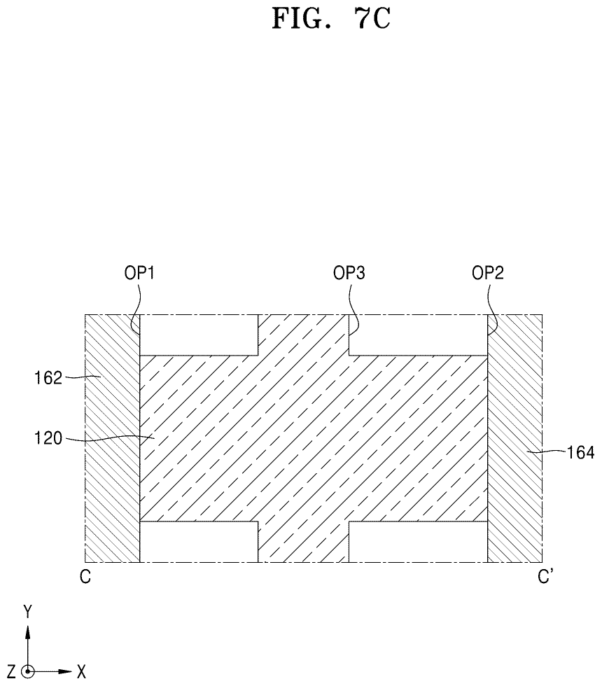

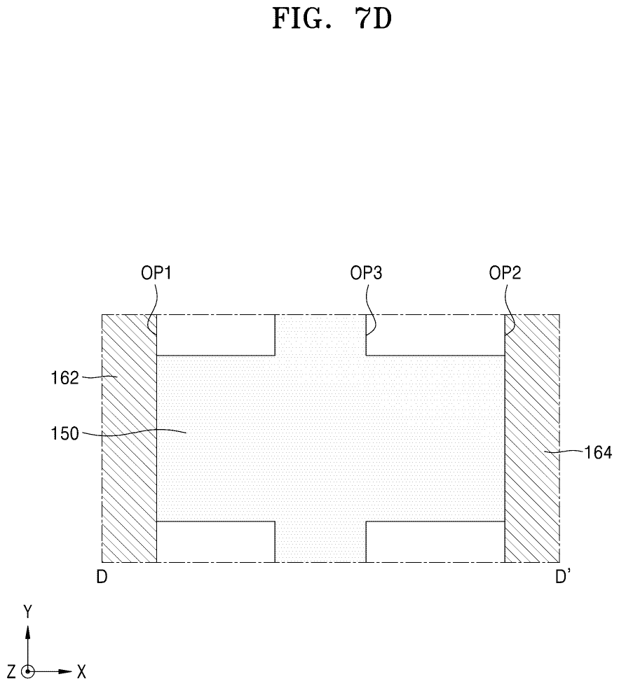

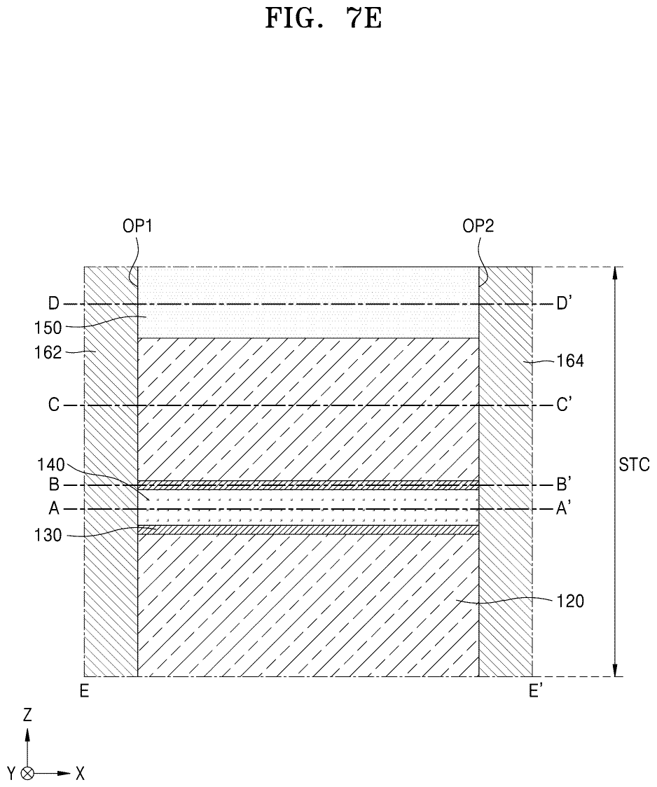

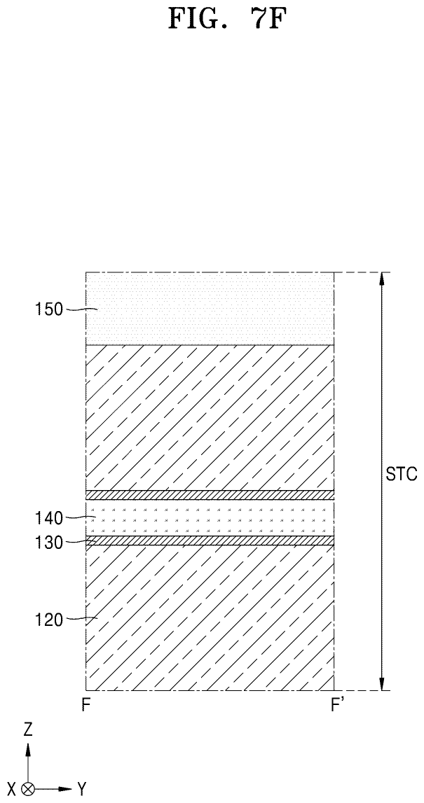

In FIGS. 7A to 7F, portions of the stack structure STC including the two sacrificial insulating layers 120, the two first capping layers 130, the sacrificial semiconductor layer 140, and the vertical separation insulating layer 150 may be removed to form a plurality of third openings OP3. Some of the plurality of third openings OP3 may be formed to be adjacent to the first opening OP1 and apart from each other in the second horizontal direction (Y direction), and others of the plurality of third openings OP3 may be formed to be adjacent to the second opening OP2 and apart from each other in the second horizontal direction (Y direction). For example, between the first opening OP1 and the second opening OP2, at least two pairs of third openings OP3 apart from each other in the first horizontal direction (X direction) may be arranged apart from each other in the second horizontal direction (Y direction).

Each of the plurality of third openings OP3 may be formed to have a horizontal width in the first horizontal direction (X direction) that is greater than the horizontal width thereof in the second horizontal direction (Y direction). For example, each of the plurality of third openings OP3 may be formed to have a bar shape or a bar shape with round corners, which extends in the first horizontal direction (X direction) in a plan view. A pair of third openings OP3 adjacent to each other in the first horizontal direction (X direction) may be apart from each other by a first separation distance SD1, and a pair of third openings OP3 adjacent to each other in the second horizontal direction (Y direction) may be apart from each other by a second separation distance SD2 that is greater than the first separation distance SD1.

On an inner wall of each of the plurality of third openings OP3, respective side surfaces of the two sacrificial insulating layers 120, the two first capping layers 130, the sacrificial semiconductor layer 140, and the vertical separation insulating layer 150, and at least one of the first mold insulating layer 162 and the second mold insulating layer 164 may be exposed.

Within one stack structure STC, one memory cell MC, as shown in FIG. 3, may be formed between two pairs of third openings OP3, that is, four third openings OP3, that are apart from each other in the first horizontal direction (X direction) and the second horizontal direction (Y direction) between the first opening OP1 and the second opening OP2.

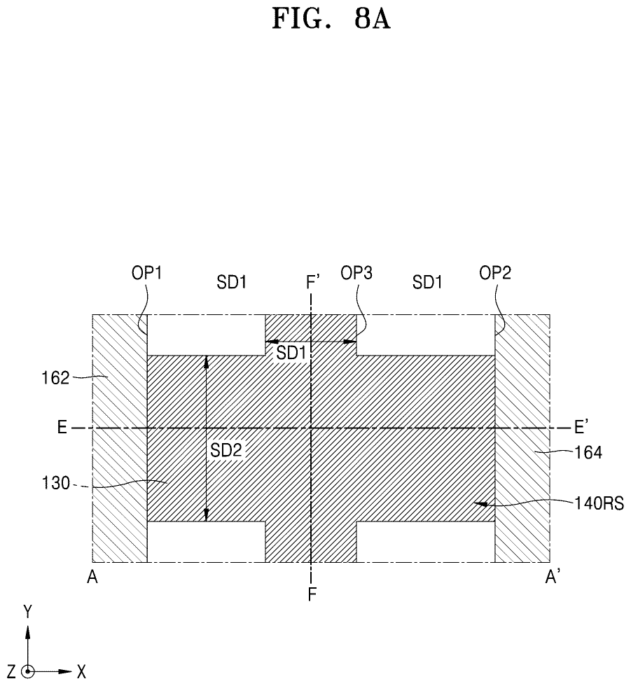

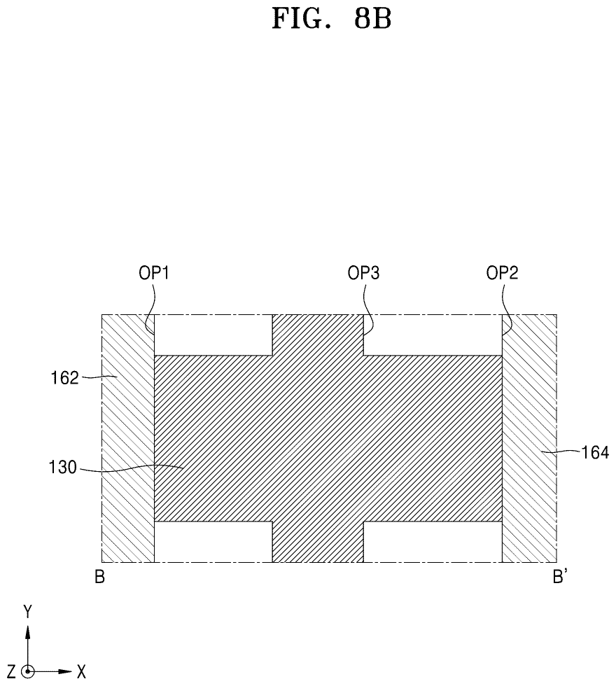

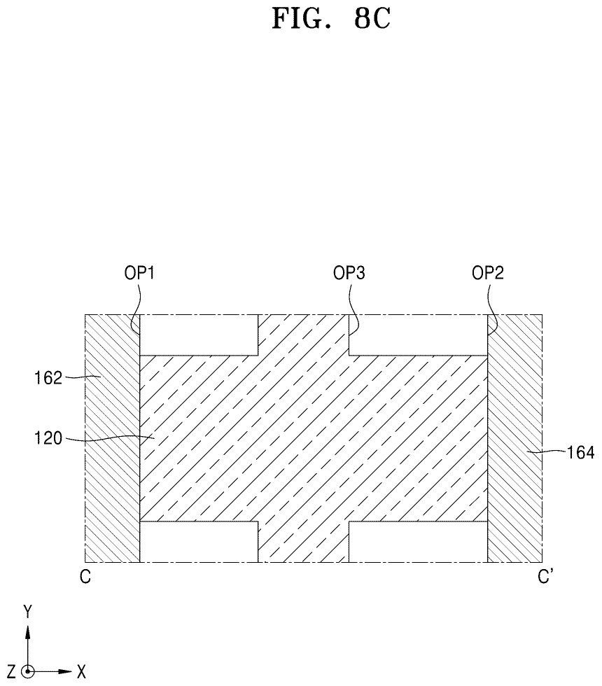

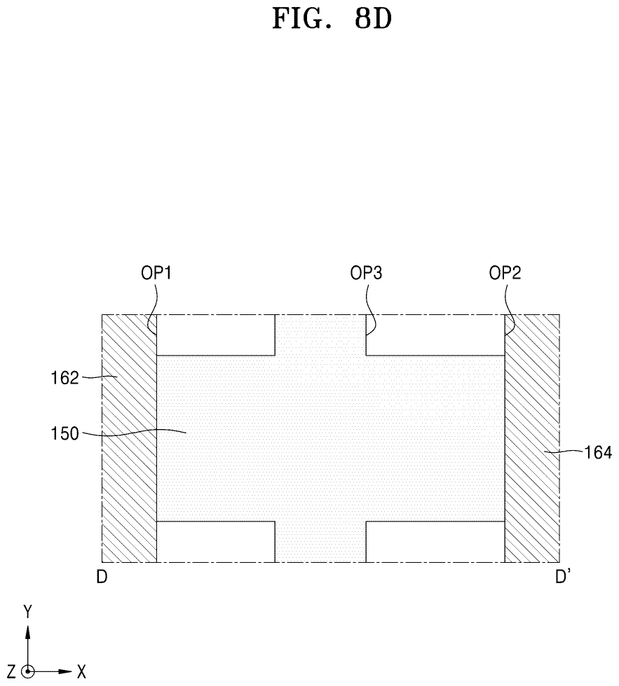

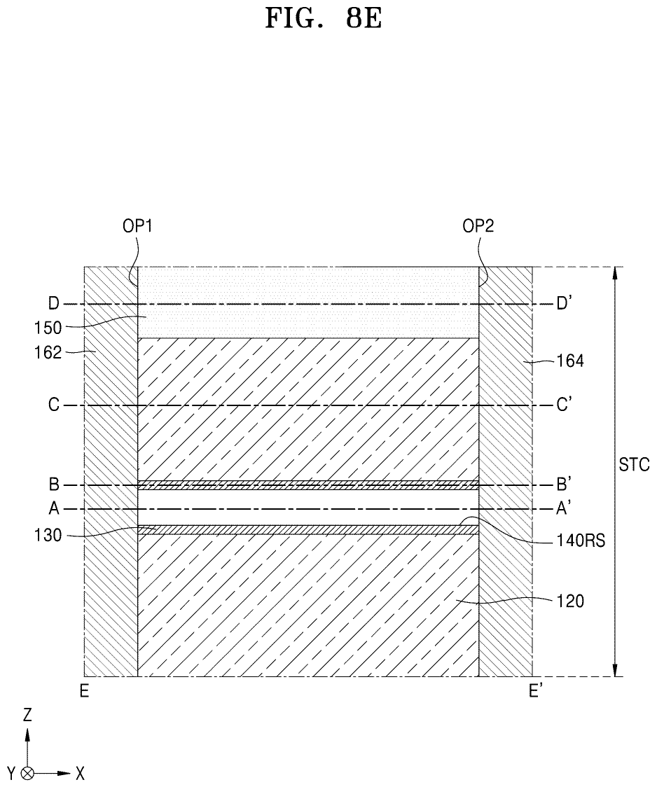

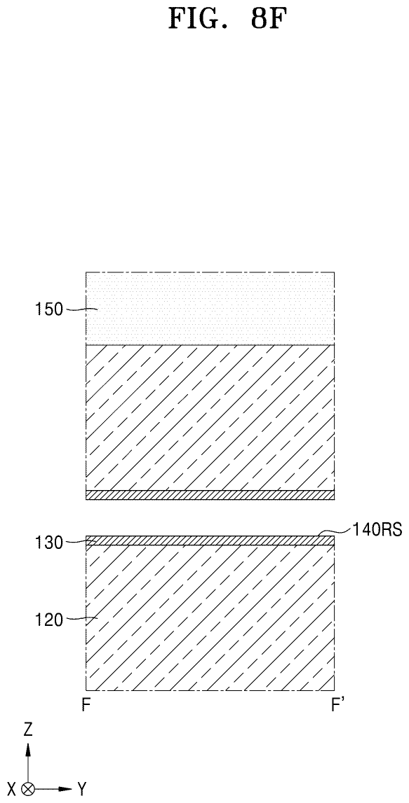

In FIGS. 7A to 7F and 8A to 8F, the sacrificial semiconductor layer 140 may be removed through the plurality of third openings OP3 to form a removal space 140RS. The removal space 140RS may be defined by the first opening OP1, the second opening OP2, the plurality of third openings OP3, and the two first capping layers 130. The removal space 140RS may be formed by performing an isotropic etching process to remove the sacrificial semiconductor layer 140 exposed through the plurality of third openings OP3.

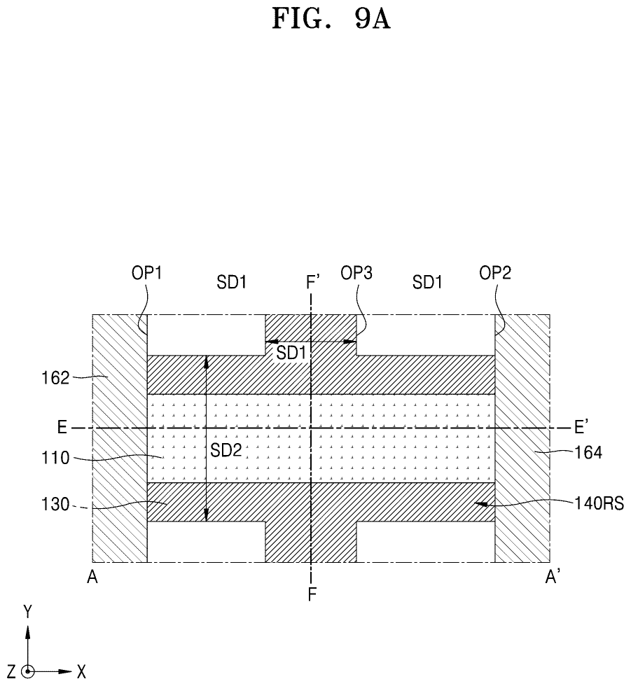

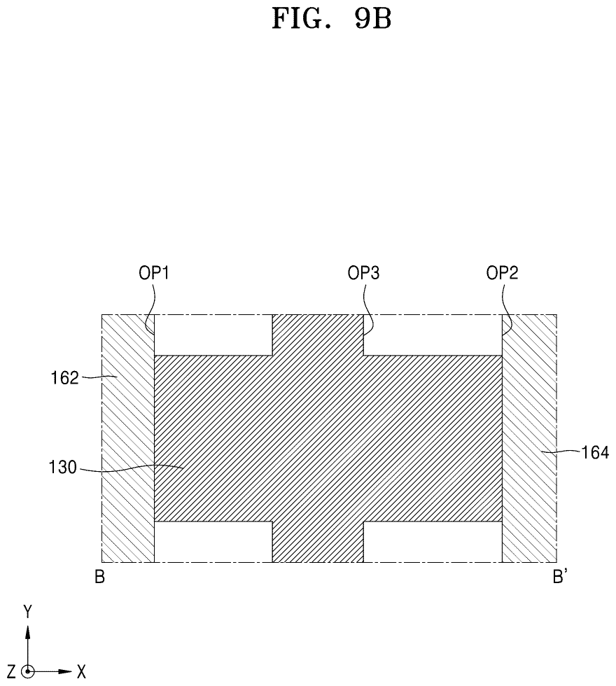

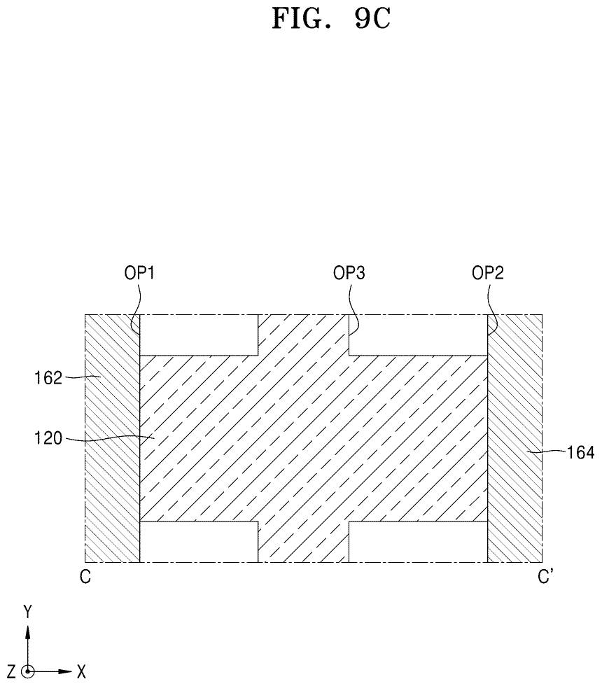

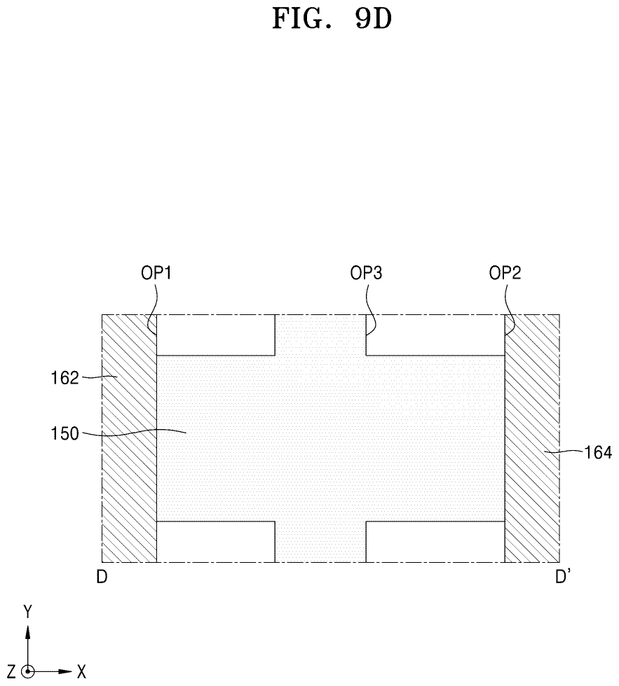

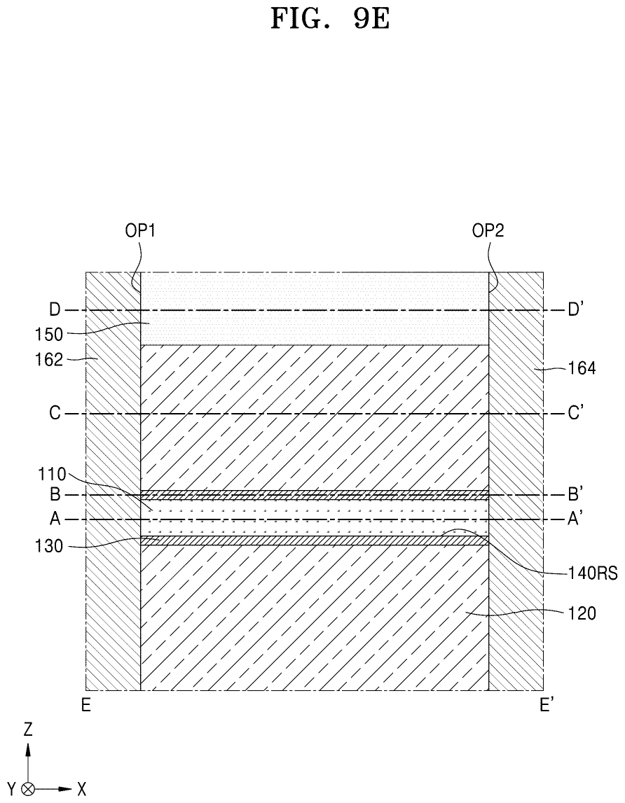

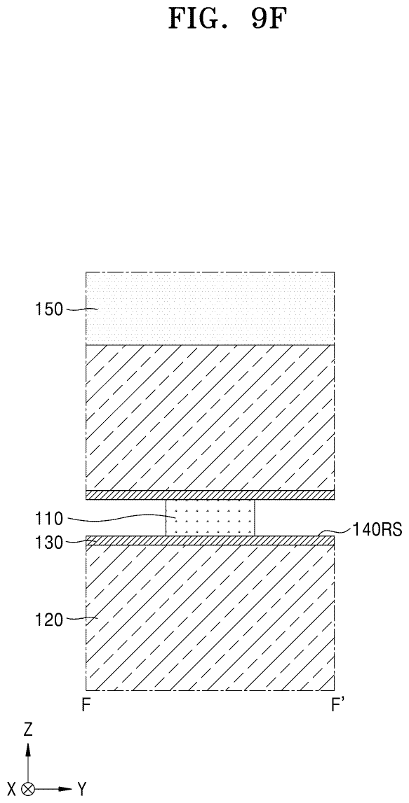

In FIGS. 9A to 9F, a semiconductor pattern 110 may be formed to fill a portion of the removal space 140RS. The semiconductor pattern 110 may be formed by forming a semiconductor material layer that fills the removal space 140RS and the plurality of third openings OP3, and then removing portions of the semiconductor material layer that fill the plurality of third openings OP3 and a portion of the removal space 140RS adjacent to the plurality of third openings OP3.

The semiconductor pattern 110 may be formed to be apart from each of the plurality of third openings OP3 and to fill a portion of the removal space 140RS. The semiconductor pattern 110 may be arranged between a pair of third openings OP3 that are adjacent to each other in the second horizontal direction (Y direction) and apart from each other by the second separation distance SD2, and may not be arranged between a pair of third openings OP3 that are adjacent to each other in the first horizontal direction (X direction) and apart from each other by the first separation distance SD1 that is less than the second separation distance SD2. The semiconductor pattern 110 may be formed to have a bar shape extending in the first horizontal direction (X direction) from the first opening OP1 to the second opening OP2 in a plan view.

The semiconductor pattern 110 may include an oxide semiconductor material or a 2D semiconductor material. For example, the oxide semiconductor material may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. For example, the 2D semiconductor material may include MoS₂, WSe₂, graphene, carbon nano tubes, or a combination thereof. For example, the semiconductor pattern 110 may include a single layer or a multi-layer including the oxide semiconductor material. In some implementations, the semiconductor pattern 110 may include a material having a band gap energy that is greater than the band gap energy of silicon. For example, the semiconductor pattern 110 may include a material having a band gap energy of about 1.5 eV to about 5.6 eV. For example, the semiconductor pattern 110 may include a material that may have optimal channel performance when having a band gap energy of about 2.0 eV to about 4.0 eV.

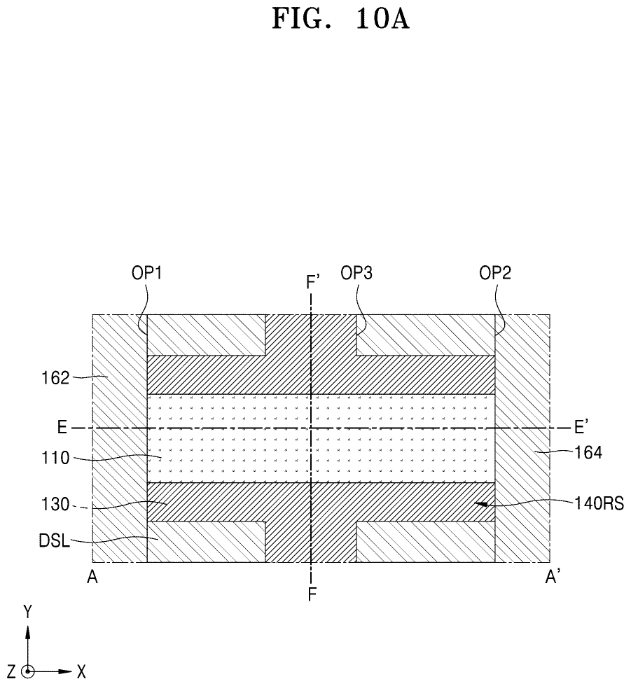

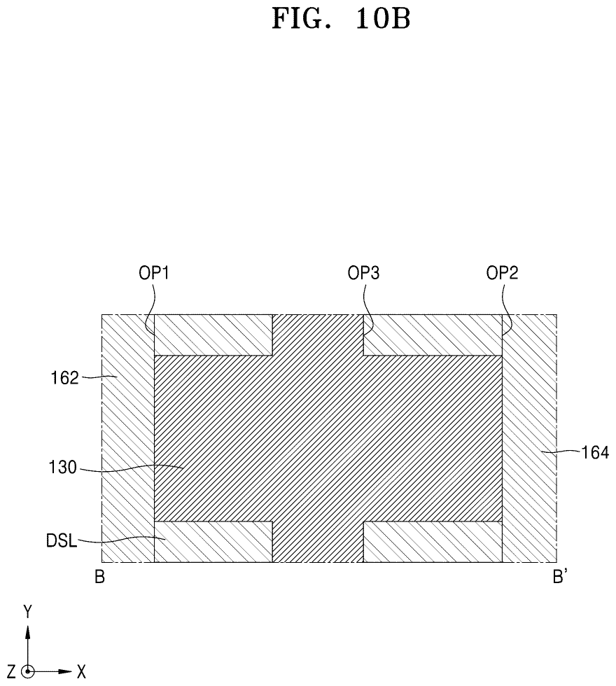

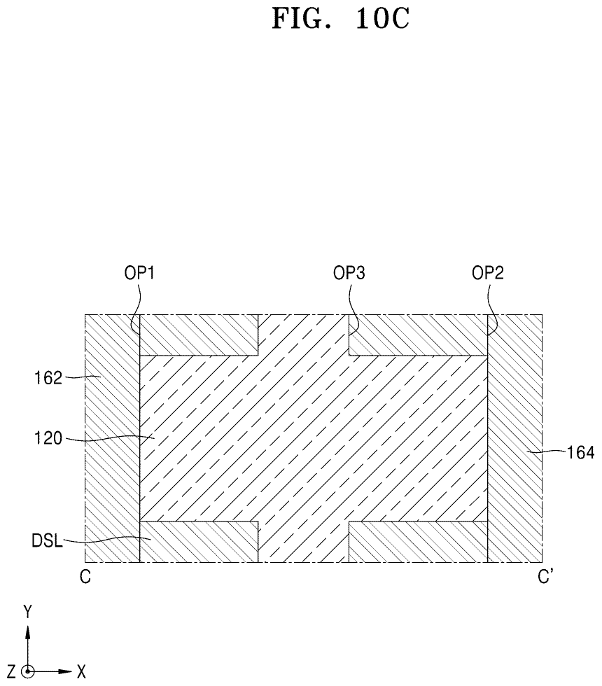

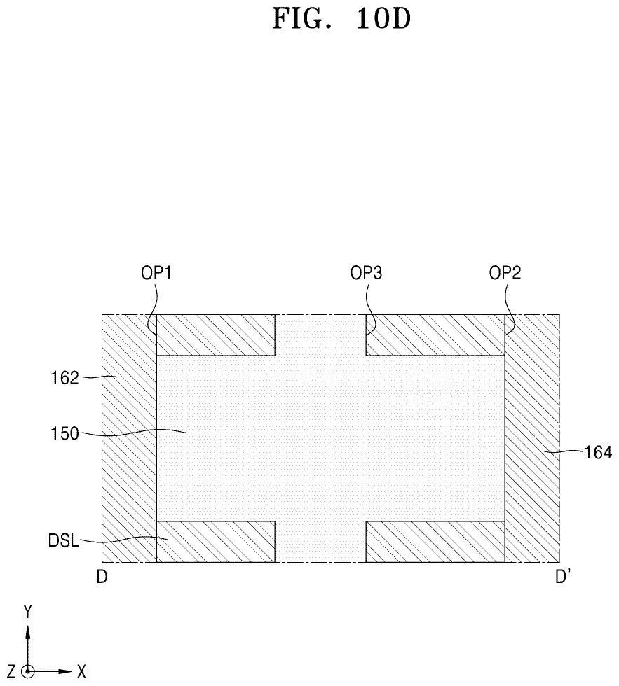

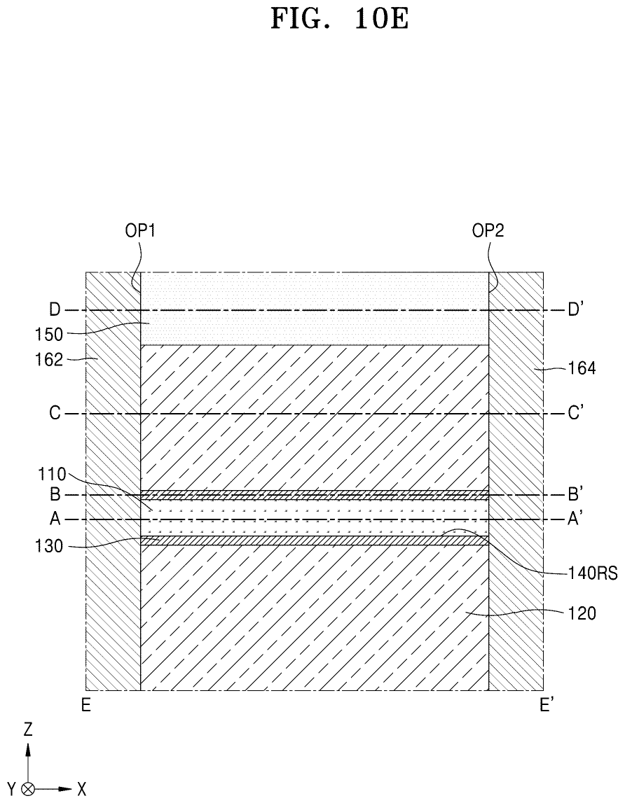

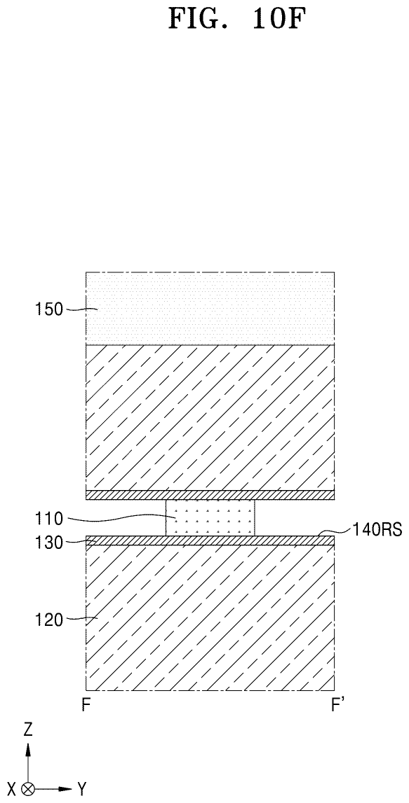

In FIGS. 10A to 10F, a plurality of device separation layers DSL may be formed to fill the plurality of third openings OP3. The plurality of device separation layers DSL may be formed to completely fill the plurality of third openings OP3 and not to fill at least a portion of the removal space 140RS that is not filled by the semiconductor pattern 110. In some implementations, the plurality of device separation layers DSL may be formed to completely fill a portion of the removal space 140RS that is adjacent to the plurality of third openings OP3 and not to completely fill a portion of the removal space 140RS that is not filled by the semiconductor pattern 110. For example, the plurality of device separation layers DSL may be formed to be apart from the semiconductor pattern 110.

For example, the device separation layer DSL may include a material including at least one of a silicon oxide layer, a silicon nitride layer, and a silicon oxynitride layer. The device separation layer DSL may include a single layer including one type of insulating layer, a double layer including two types of insulating layers, or a multi-layer including a combination of at least three types of insulating layers. For example, the device separation layer DSL may include a double layer or a multi-layer including an oxide layer and a nitride layer. However, according to the inventive concept, the configuration of the device separation layer DSL is not limited thereto.

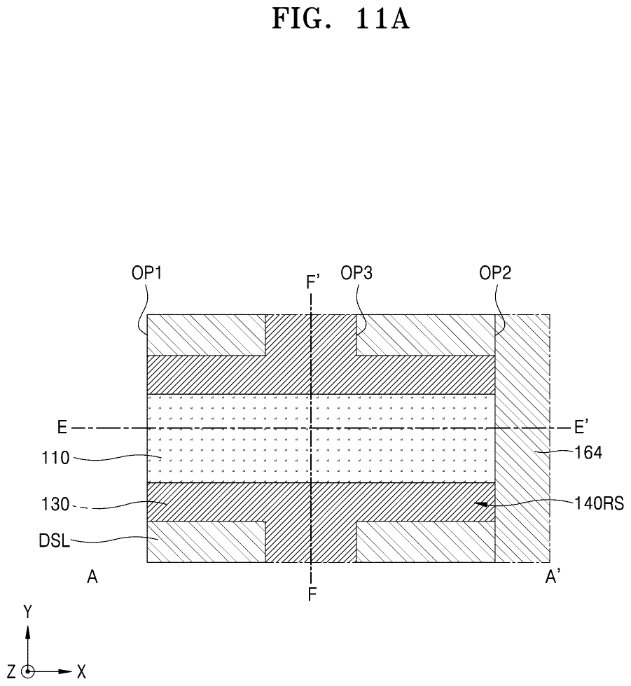

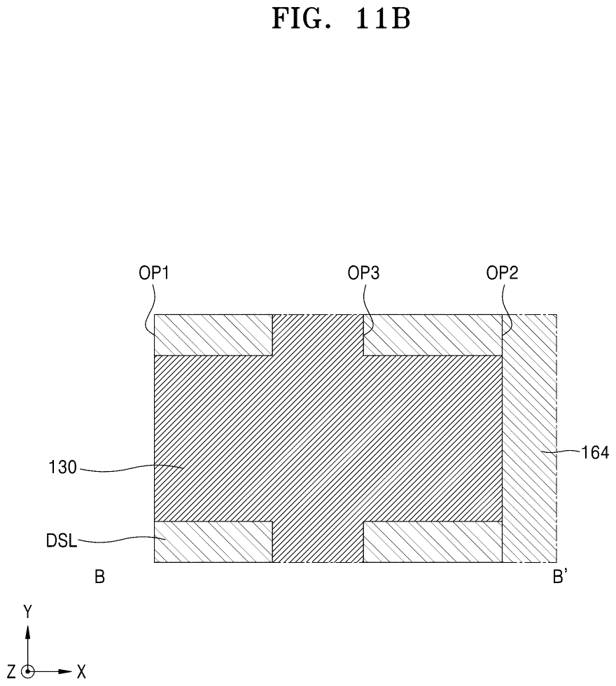

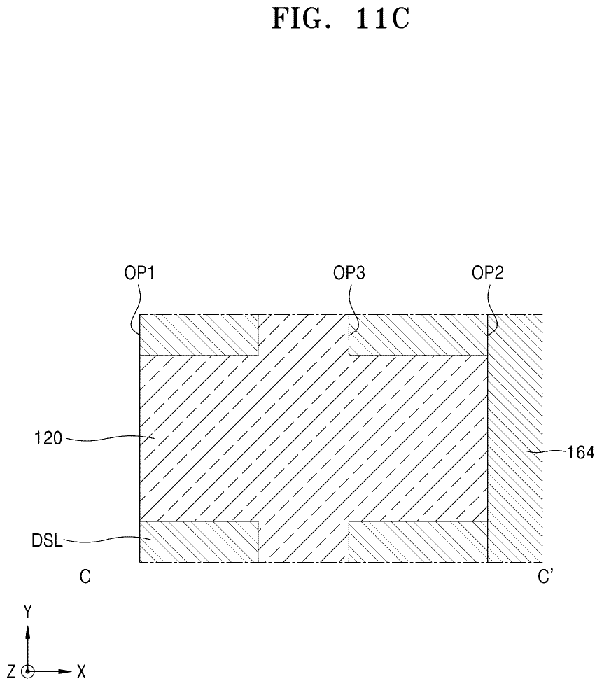

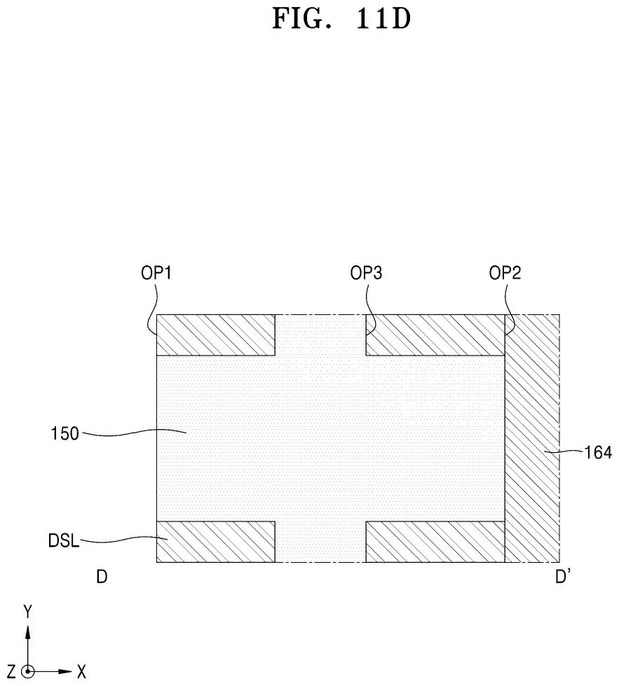

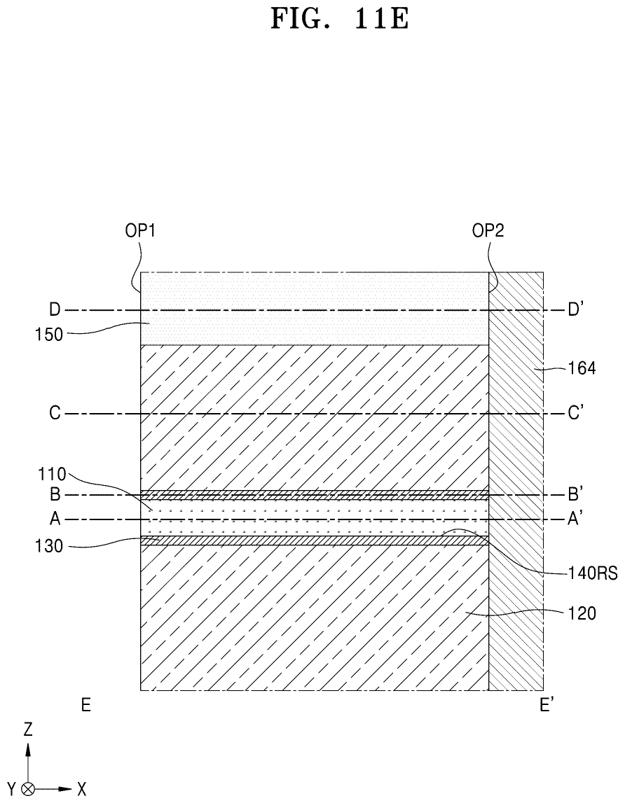

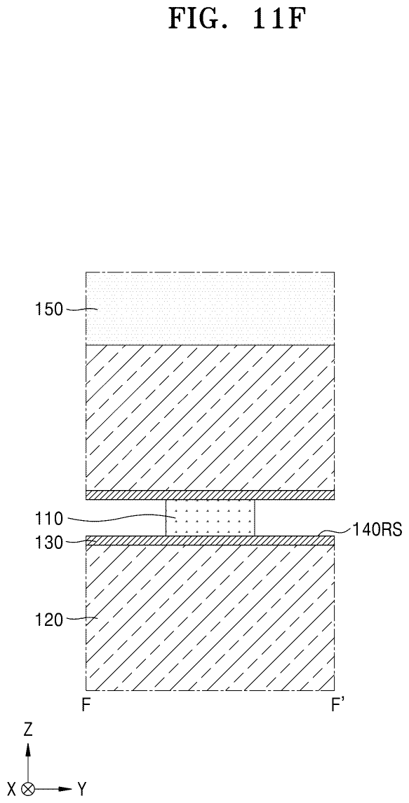

In FIGS. 10A to 10F and 11A to 11F, the first mold insulating layer 162 filling the first opening OP1 may be removed. In some implementations, after forming a mask pattern that does not cover the first opening OP1, the first mold insulating layer 162 may be removed by using the mask pattern as an etch mask. On the inner wall of the first opening OP1 from which the first mold insulating layer 162 has been removed, respective side surfaces of the two sacrificial insulating layers 120, the two first capping layers 130, the semiconductor pattern 110, the vertical separation insulating layer 150, and the device separation layer DSL may be exposed.

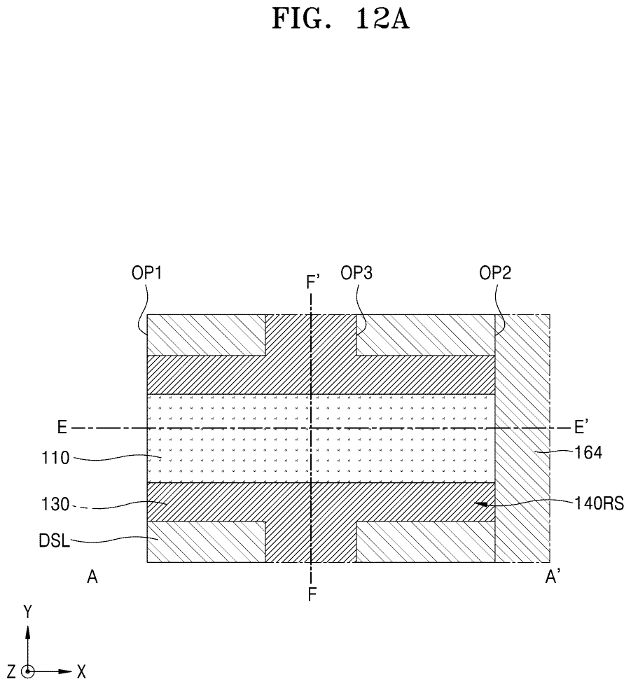

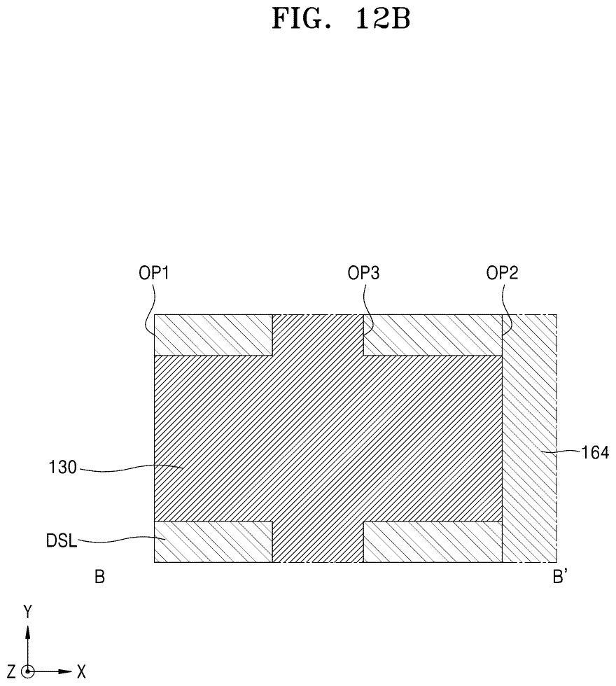

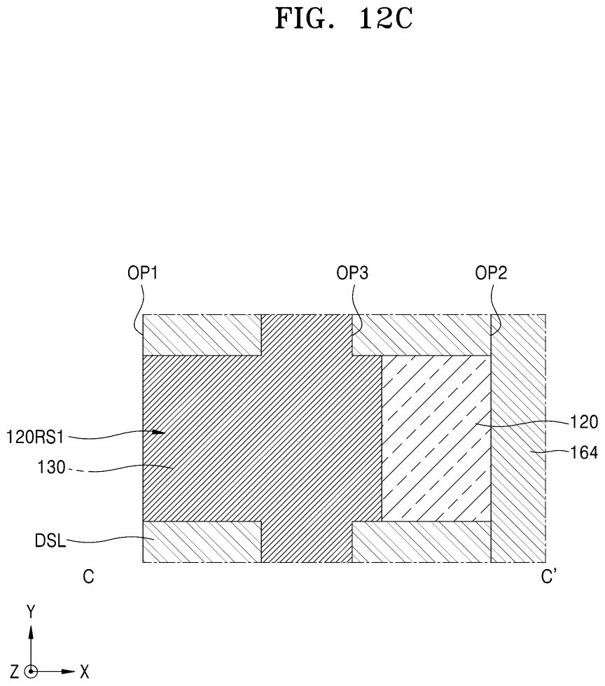

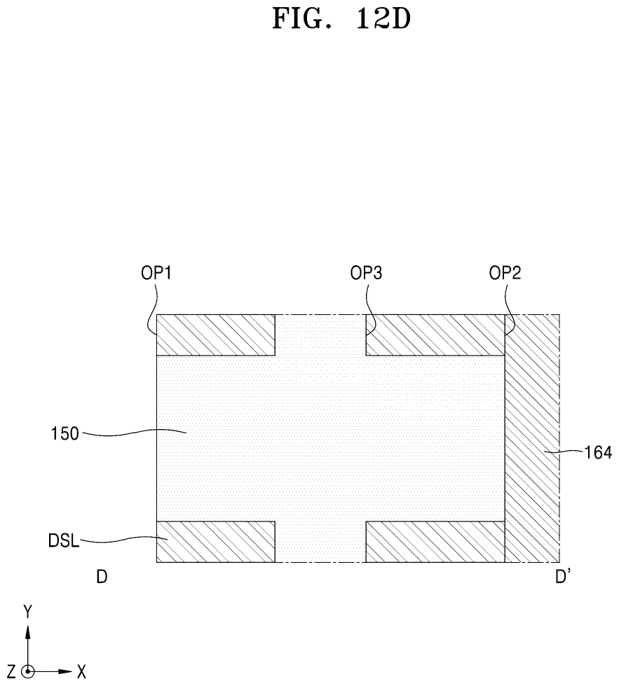

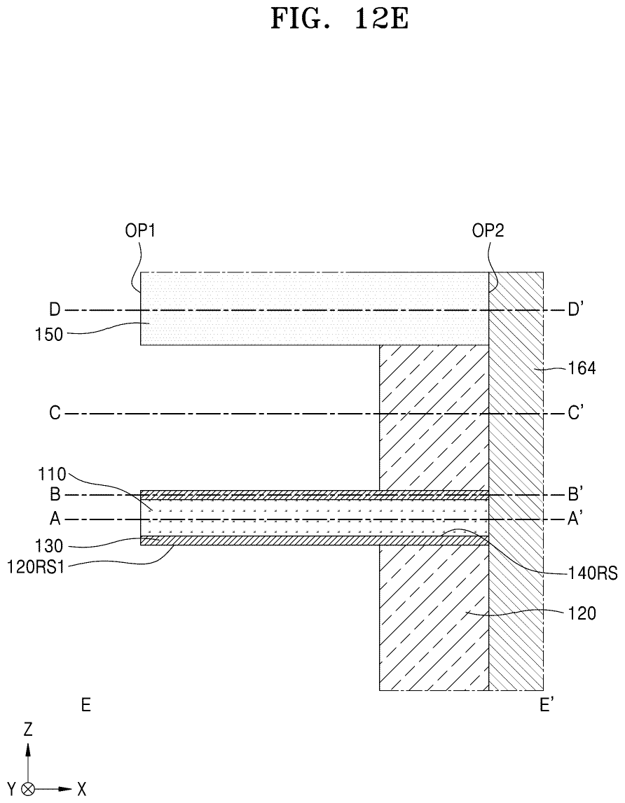

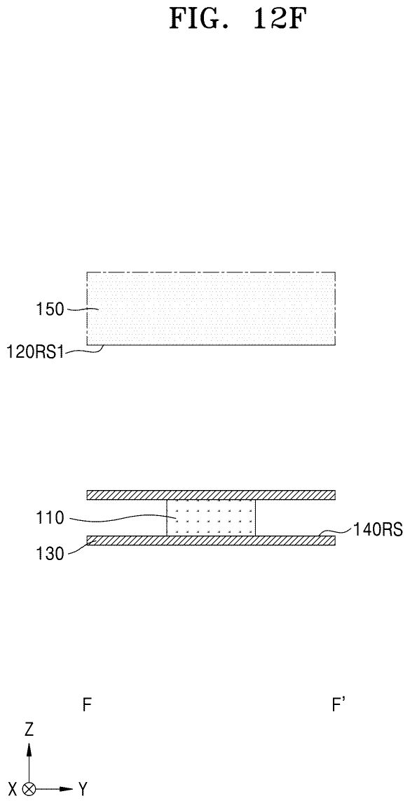

In FIGS. 12A to 12F, a portion of the sacrificial insulating layer 120 that is exposed through the first opening OP1 may be removed to form a first recess space 120RS1. The first recess space 120RS1 may extend in the first horizontal direction (X direction) from the first opening OP1, and may not extend to the second opening OP2. Another portion of the sacrificial insulating layer 120, the first capping layer 130, the device separation layer DSL, and the vertical separation insulating layer 150 may be exposed within the first recess space 120RS1. The first recess space 120RS1 may be formed by removing a portion of the sacrificial insulating layer 120, which includes a portion of the sacrificial insulating layer 120 that is located between a pair of third openings OP3 adjacent to each other in the first horizontal direction (X direction).

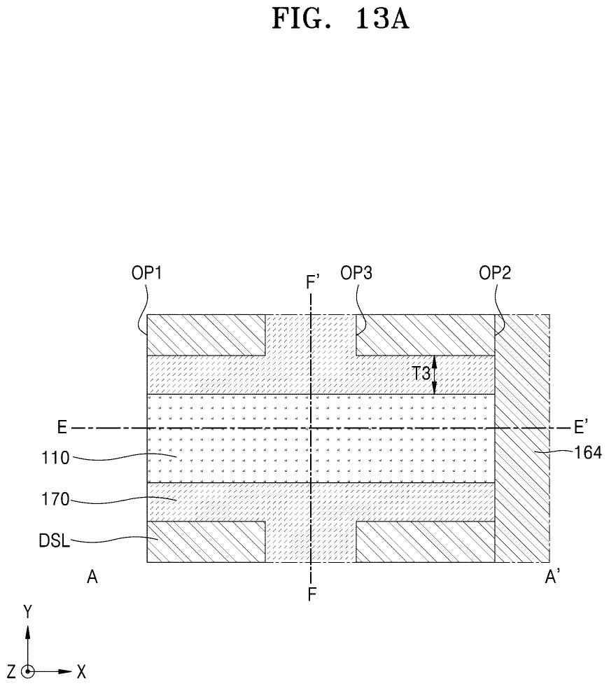

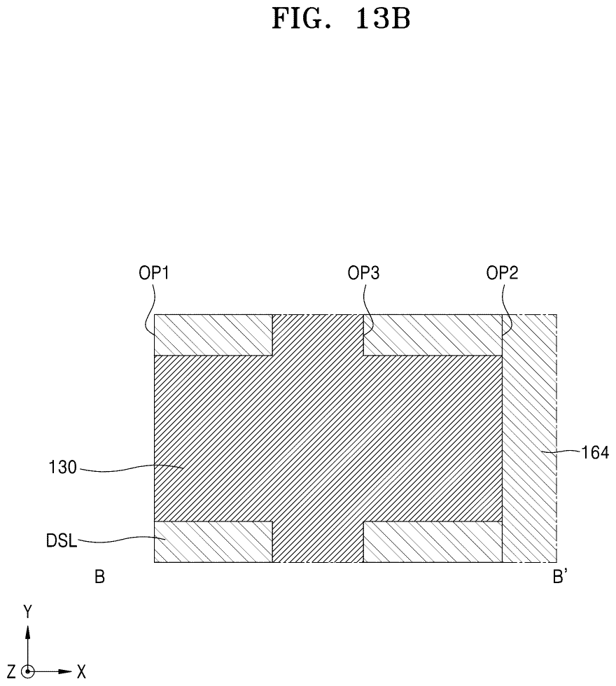

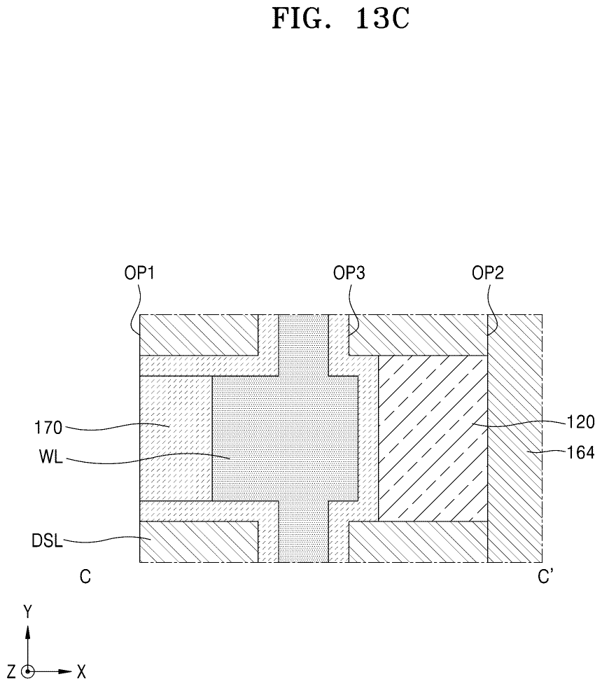

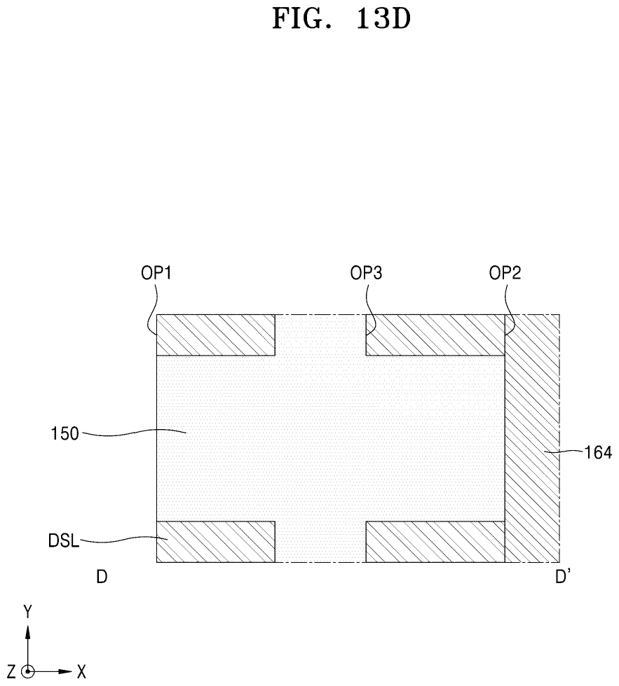

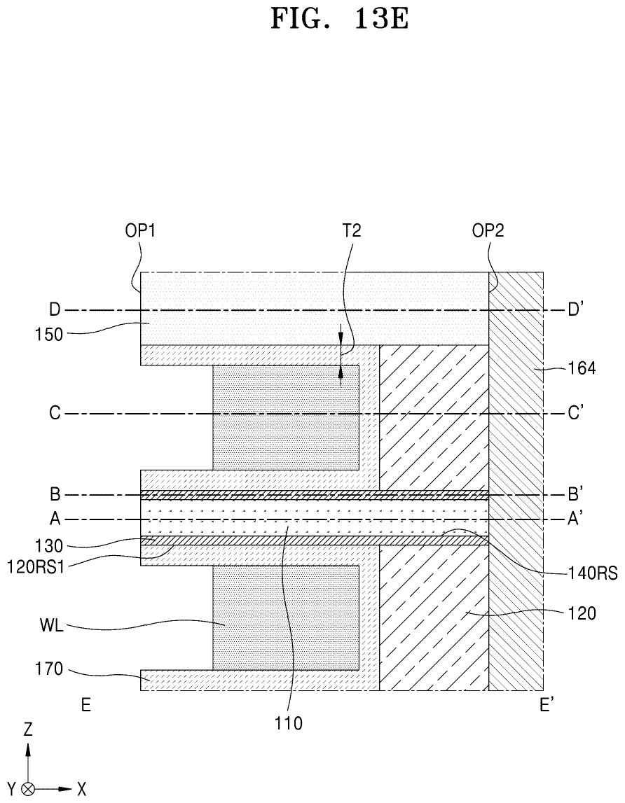

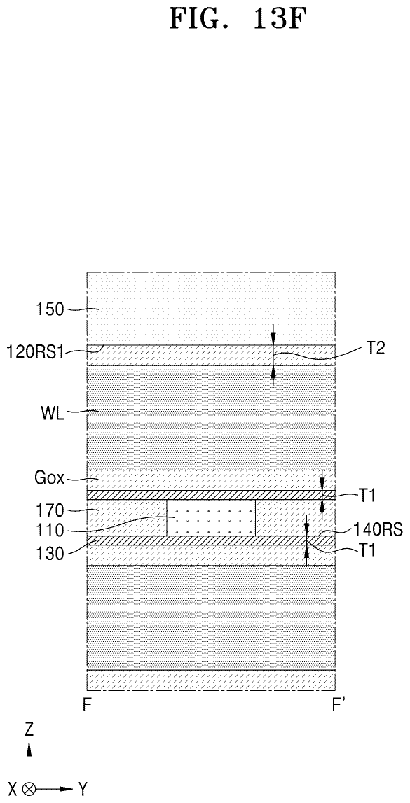

In FIGS. 13A to 13F, a dielectric layer 170 may be formed to cover a surface exposed within the first recess space 120RS1 and fill the removal space 140RS. The dielectric layer 170 may be formed to conformally cover respective surfaces of the sacrificial insulating layer 120, the first capping layer 130, the device separation layer DSL, and the vertical separation insulating layer 150 that are exposed within the first recess space 120RS1. The dielectric layer 170 may be formed to completely fill the removal space 140RS and not to completely fill the first recess space 120RS1. The dielectric layer 170 may be formed not to completely fill a portion of the first recess space 120RS1 that is located between a pair of device separation layers DSL filling a pair of third openings OP3 adjacent to each other in the first horizontal direction (X direction) in the first recess space 120RS1. The dielectric layer 170 may be formed to completely cover a side surface of the semiconductor pattern 110 in the second horizontal direction (Y direction) within the removal space 140RS.

After forming the dielectric layer 170, a word line WL may be formed on the dielectric layer 170 to fill a portion of the first recess space 120RS1. The word line WL may be formed by forming a word line material layer that completely fills the first recess space 120RS1, and then removing a portion of the word line material layer through the first opening OP1. The word line WL may be formed to fill a portion of the first recess space 120RS1 and to completely fill a portion of the first recess space 120RS1 that is located between a pair of device separation layers DSL filling a pair of third openings OP3 adjacent to each other in the first horizontal direction (X direction).

The dielectric layer 170 may cover a surface of the word line WL and have a second thickness T2. The second thickness T2 may be greater than the first thickness T1. For example, the second thickness T2 may be 3 nm or more. In some implementations, the second thickness T2 may be at least twice the first thickness T1. The dielectric layer 170 may have a third thickness T3 between the semiconductor pattern 110 and the device separation layer DSL in the second horizontal direction (Y direction) within the removal space 140RS. The third thickness T3 may be greater than the first thickness T1. In some implementations, the third thickness T3 may be equal to or greater than the second thickness T2.

The dielectric layer 170 may include at least one selected from silicon oxide, a high-k dielectric material having a higher dielectric constant than silicon oxide, and a ferroelectric material. In some embodiments, at least a portion of the dielectric layer 170 may include the same material as the first capping layer 130. For example, the dielectric layer 170 may include the same material as the first capping layer 130. In some implementations, the dielectric layer 170 may have a stacked structure including a first dielectric layer including silicon oxide, and a second dielectric layer including at least one selected from a high-k dielectric material and a ferroelectric material. For example, the second dielectric layer of the dielectric layer 170 may include the same material as the first capping layer 130.

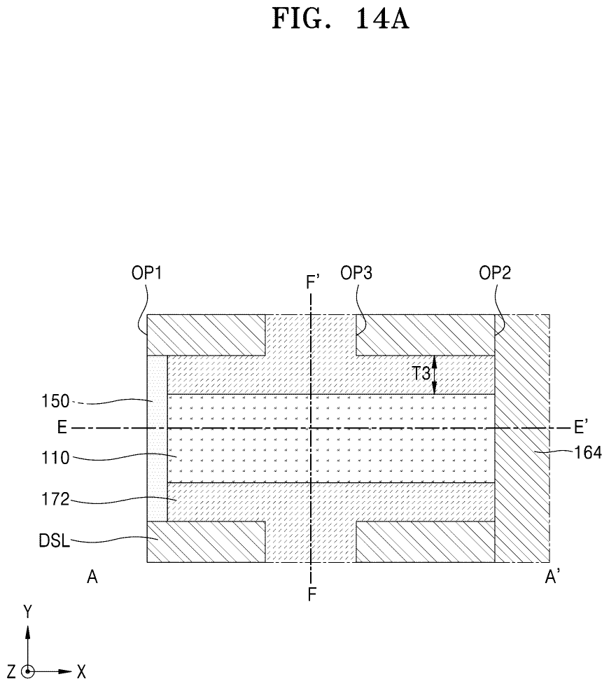

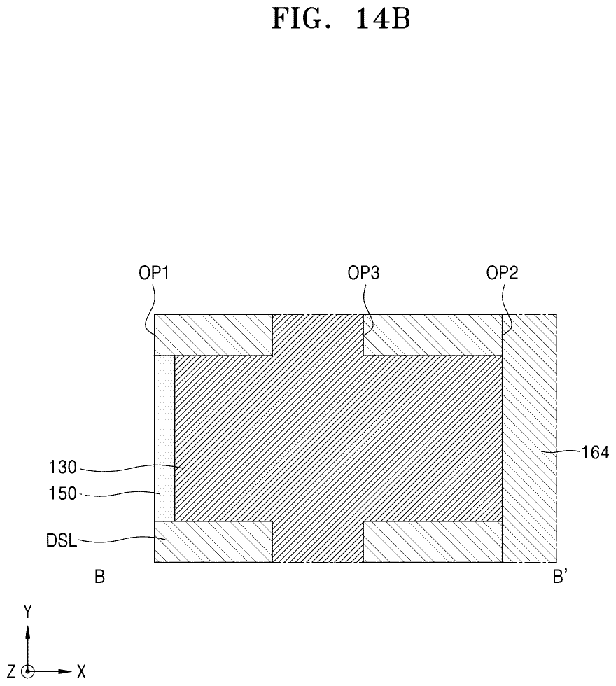

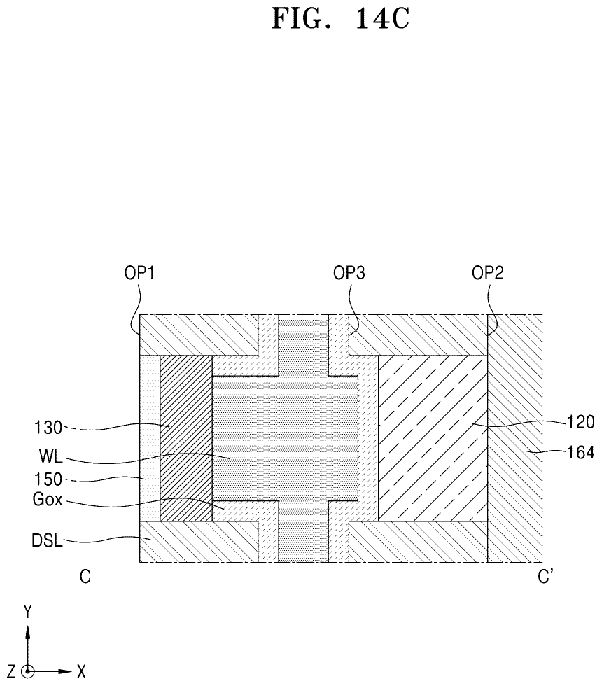

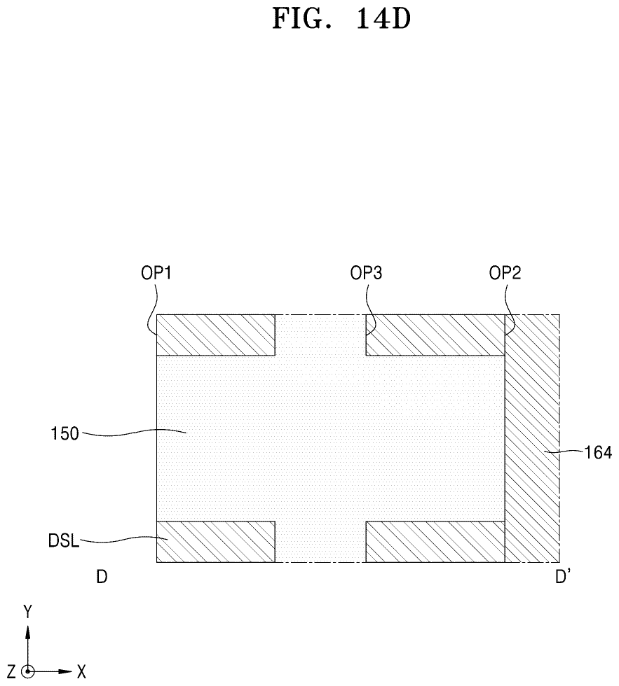

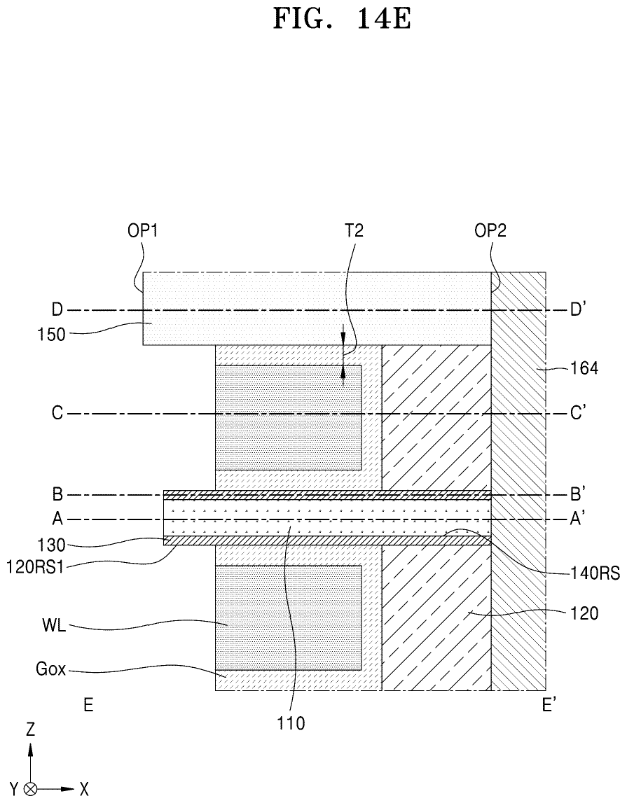

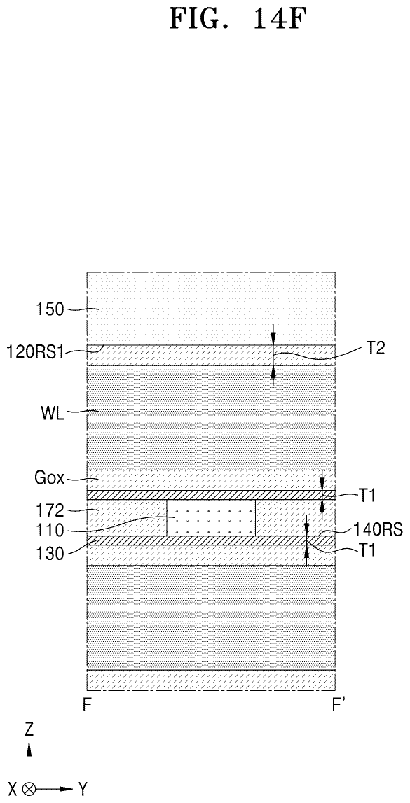

In FIGS. 13A to 13F and 14A to 14F, a portion of the dielectric layer 170 that is not covered by the word line WL within the first recess space 120RS1 may be removed to form a gate dielectric layer Gox. Within the removal space 140RS, a portion of the dielectric layer 170 that covers a side surface of the semiconductor pattern 110 in the second horizontal direction (Y direction) may become a second capping layer 172. The first capping layer 130 may cover upper and lower surfaces of the semiconductor pattern 110, and the second capping layer 172 may cover two side surfaces of the semiconductor pattern 110 in the second horizontal direction (Y direction). In some implementations, at least a portion of the second capping layer 172 may include the same material as the first capping layer 130. For example, the second capping layer 172 may include the same material as the first capping layer 130.

In the process of removing a portion of the dielectric layer 170, portions of respective ends of the semiconductor pattern 110 and the first capping layers 130 respectively covering the upper and lower surfaces of the semiconductor pattern 110, the respective ends facing the first opening OP1, may be removed. For example, in the process of removing a portion of the dielectric layer 170, respective ends of the semiconductor pattern 110 and the first capping layers 130 respectively covering the upper and lower surfaces of the semiconductor pattern 110, the respective ends facing the first opening OP1, may be moved into the first recess space 120RS1 so as to be apart from the first opening OP1. For example, in the process of removing a portion of the dielectric layer 170, respective ends of the semiconductor pattern 110 and the first capping layers 130 respectively covering the upper and lower surfaces of the semiconductor pattern 110, the respective ends facing the first opening OP1, may be moved into the first recess space 120RS1 by at least the second thickness T2 so as to be apart from the first opening OP1.

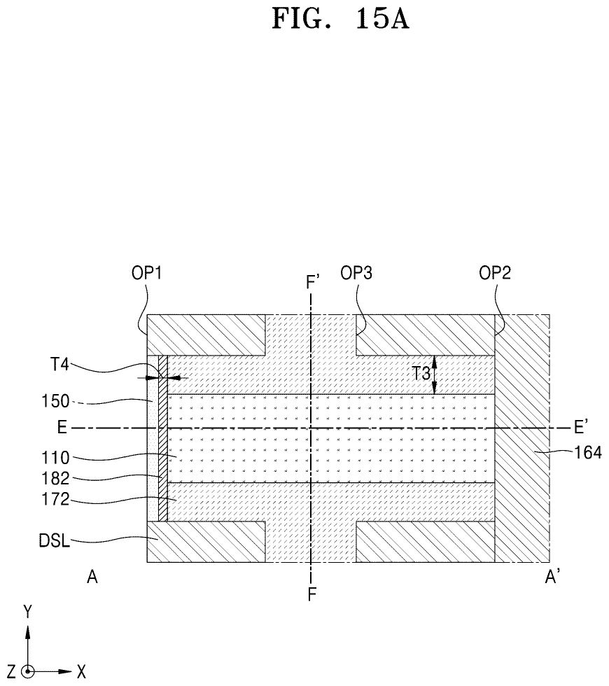

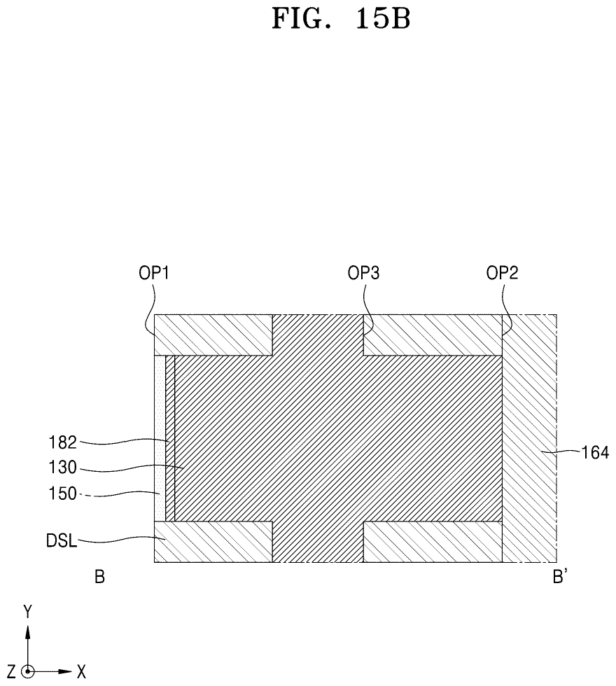

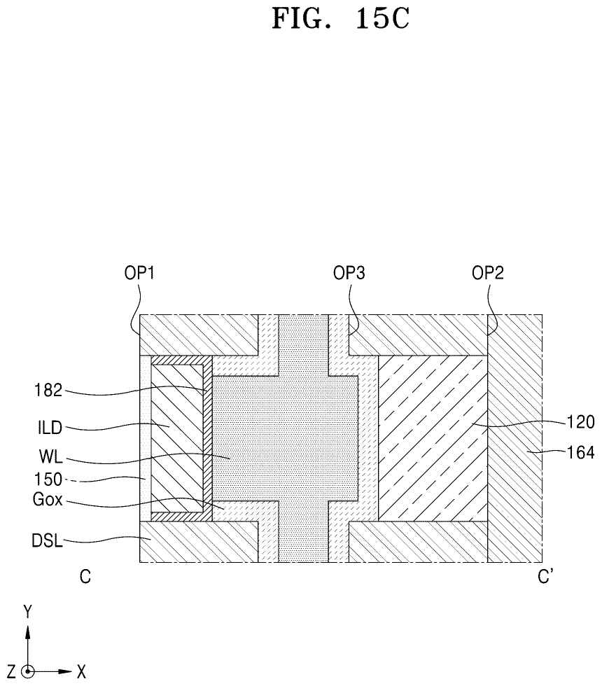

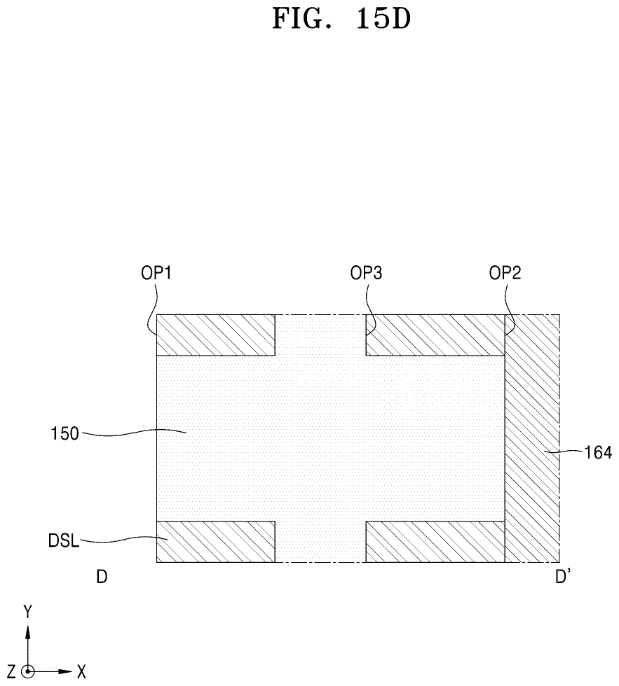

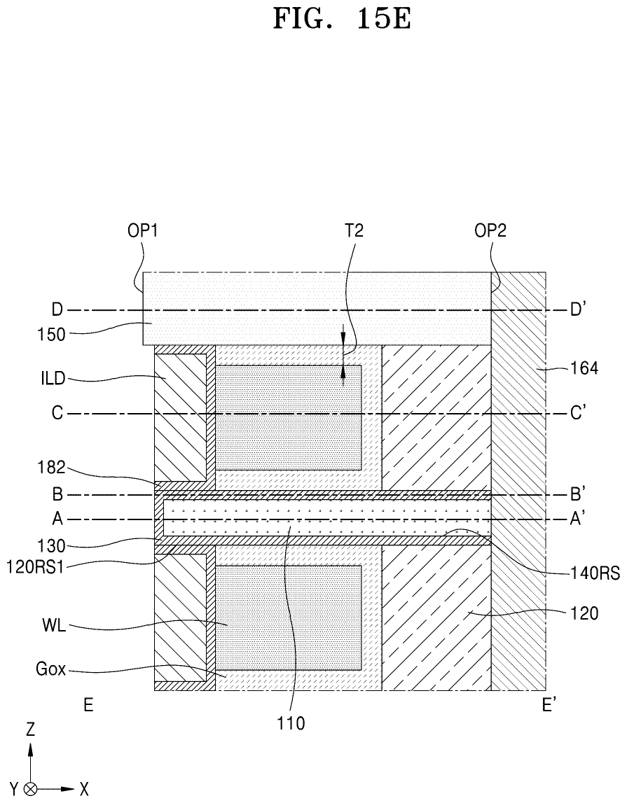

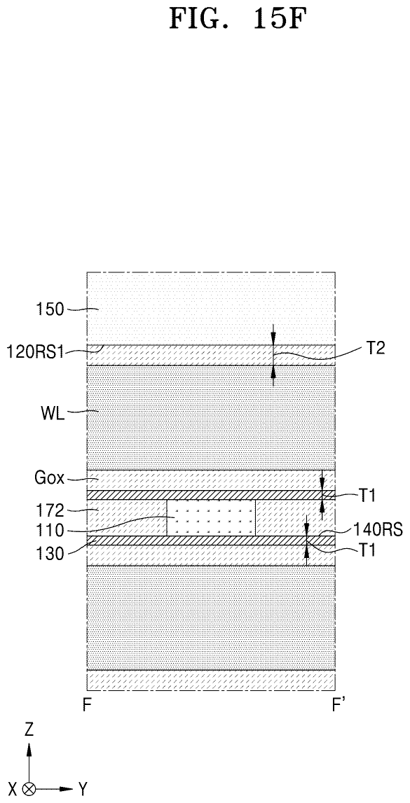

In FIGS. 15A to 15F, a third capping layer 182 covering a surface exposed within the first recess space 120RS1 and an interlayer insulating layer ILD filling a portion of the first recess space 120RS1 may be formed. For example, after forming the third capping layer 182 that conformally covers respective surfaces of the word line WL, the gate dielectric layer Gox, the semiconductor pattern 110, the first capping layer 130, the second capping layer 172, the device separation layer DSL, and the vertical separation insulating layer 150 within the first recess space 120RS1, a preliminary interlayer insulating layer that covers the third capping layer 182 and completely fills the first recess space 120RS1 may be formed, and a portion of the preliminary interlayer insulating layer may be removed so that a portion of the third capping layer 182 that covers the surface of the semiconductor pattern 110 is exposed, thereby forming the interlayer insulating layer ILD.

The third capping layer 182 may include at least one selected from silicon oxide, a high-k dielectric material having a higher dielectric constant than silicon oxide, and a ferroelectric material. In some embodiments, the third capping layer 182 may include a metal oxide. For example, the third capping layer 182 may include aluminum oxide (AlO) or hafnium oxide (HfO).

In some implementations, the third capping layer 182 may include the same material as the first capping layer 130. The third capping layer 182 may be formed to have a fourth thickness T4. The fourth thickness T4 may be less than the second thickness T2. In some embodiments, the fourth thickness T4 may be substantially equal to the first thickness T1. The interlayer insulating layer ILD may include a material including at least one of a silicon oxide layer, a silicon nitride layer, and a silicon oxynitride layer. For example, the interlayer insulating layer ILD may include a double layer or a multi-layer including an oxide layer and a nitride layer, but is not limited thereto.

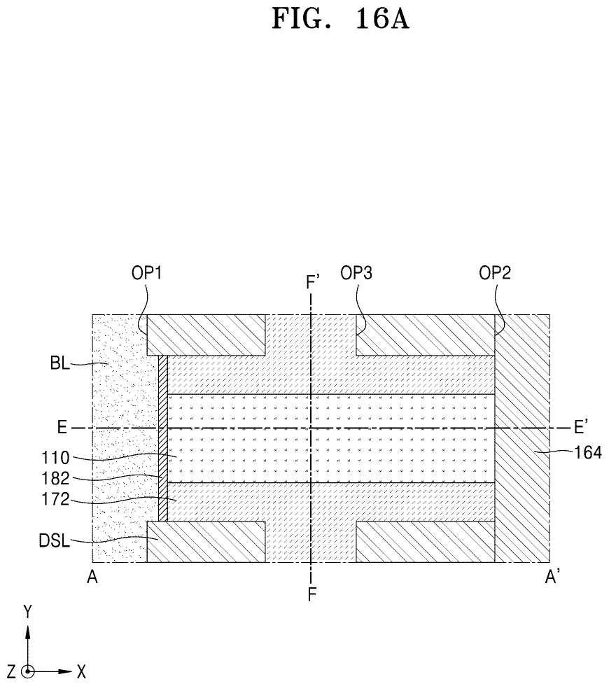

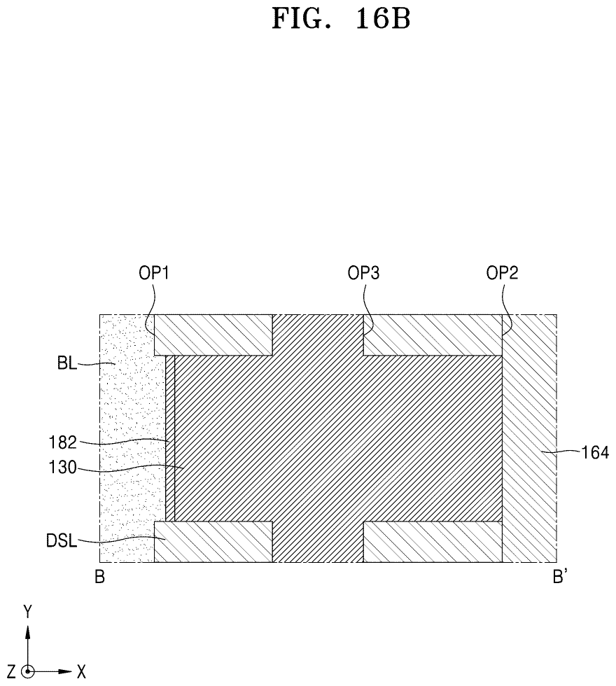

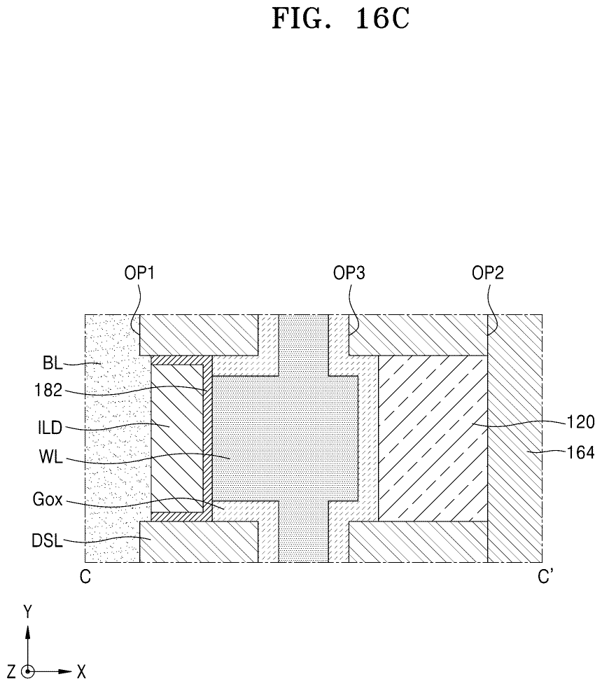

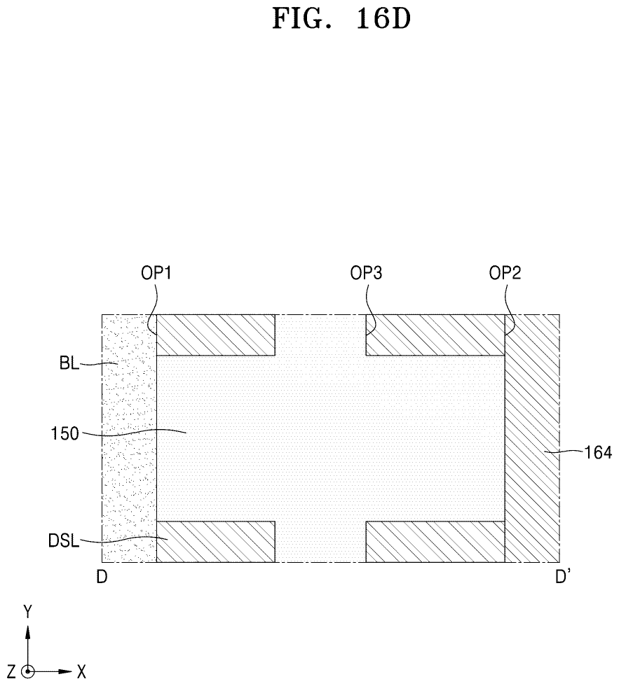

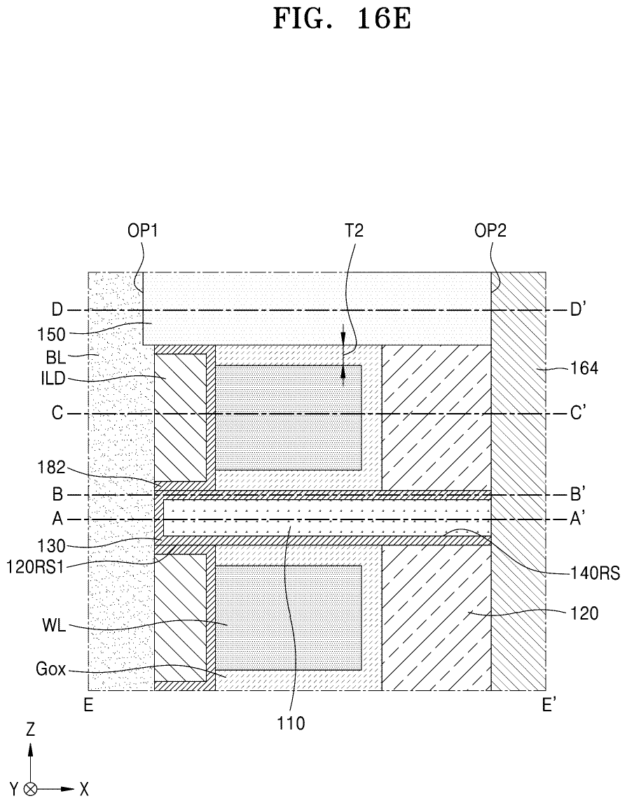

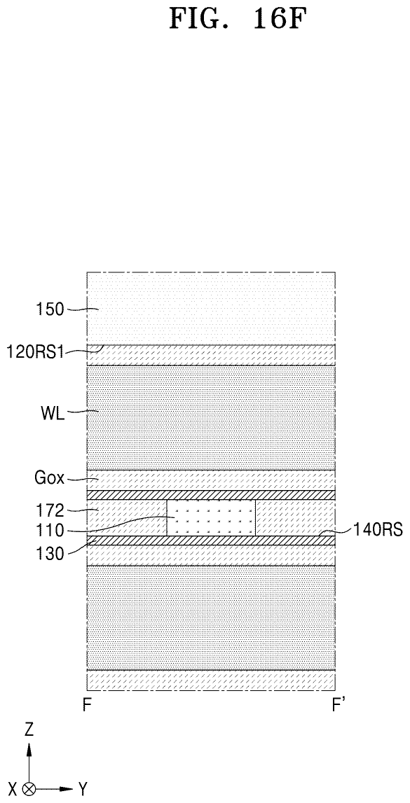

In FIGS. 16A to 16F, a bit line BL may be formed to fill the first opening OP1 and the first recess space 120RS1. The bit line BL may be formed to extend in the vertical direction (Z direction). The bit line BL may be formed to be in contact with a portion of the third capping layer 182 that covers a side surface of the semiconductor pattern 110 that faces the first opening OP1. The side surface of the semiconductor pattern 110 that faces the first opening OP1 may be referred to as a side surface of an end of the semiconductor pattern 110 in the first horizontal direction (X direction).

The bit line BL may include a metal. In some implementations, the bit line BL may include a conductive barrier layer in contact with a portion of the third capping layer 182 that covers the side surface of the end of the semiconductor pattern 110 in the first horizontal direction (X direction), and a conductive filling layer covering the conductive barrier layer. The conductive barrier layer may include, for example, a metal, a conductive metal nitride, a conductive metal silicide, or a combination thereof. For example, the conductive barrier layer may include TiN. The conductive filling layer may include, for example, doped silicon, Ru, RuO, Pt, PtO, Ir, IrO, SrRuO (SRO), (Ba, Sr)RuO (BSRO), CaRuO (CRO), BaRuO, La(Sr, Co)O, Ti, TiN, W, WN, Ta, TaN, TiAlN, TiSiN, TaAlN, TaSiN, or a combination thereof. In some embodiments, the conductive filling layer may include W.

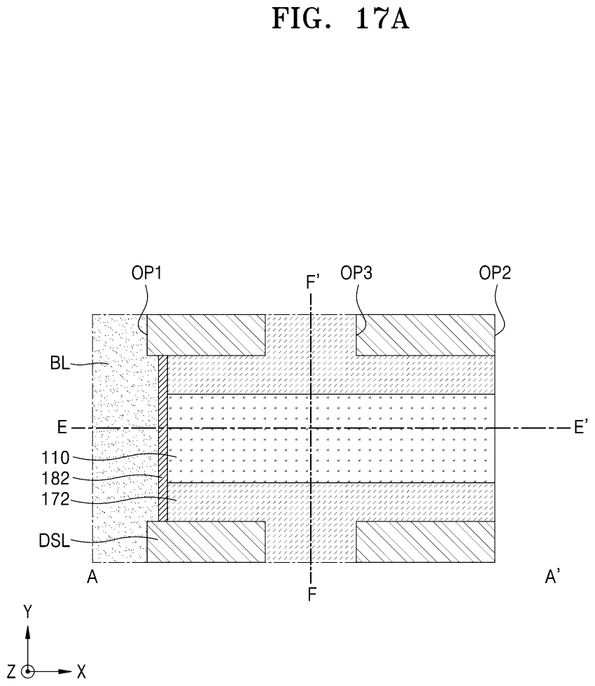

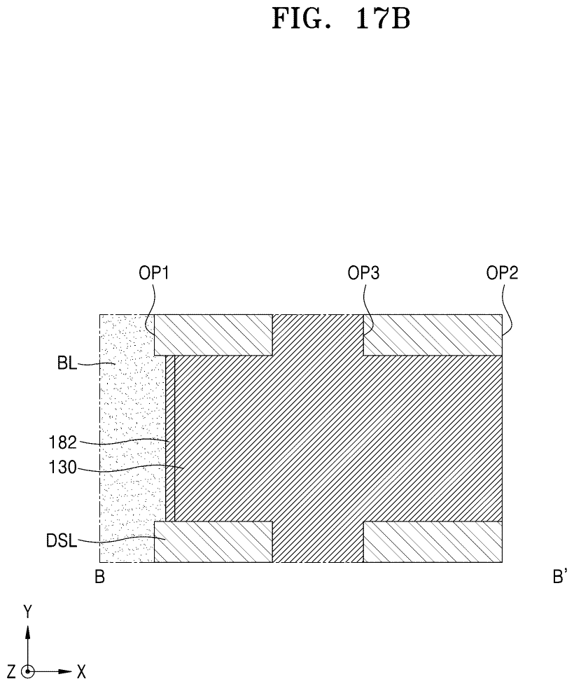

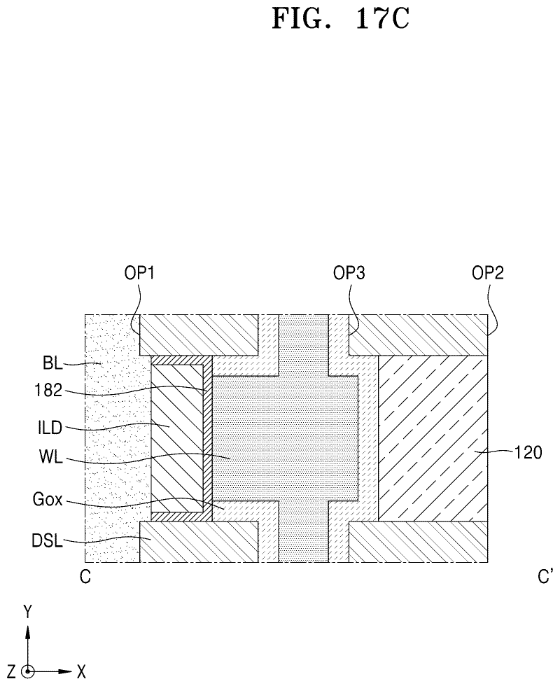

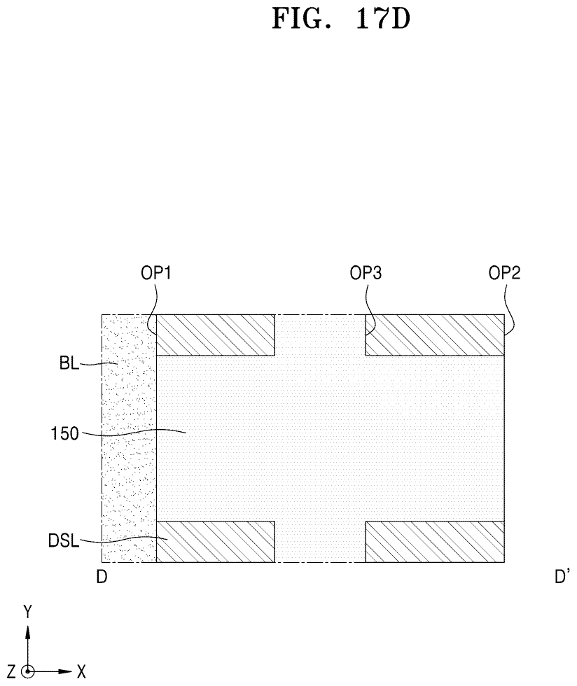

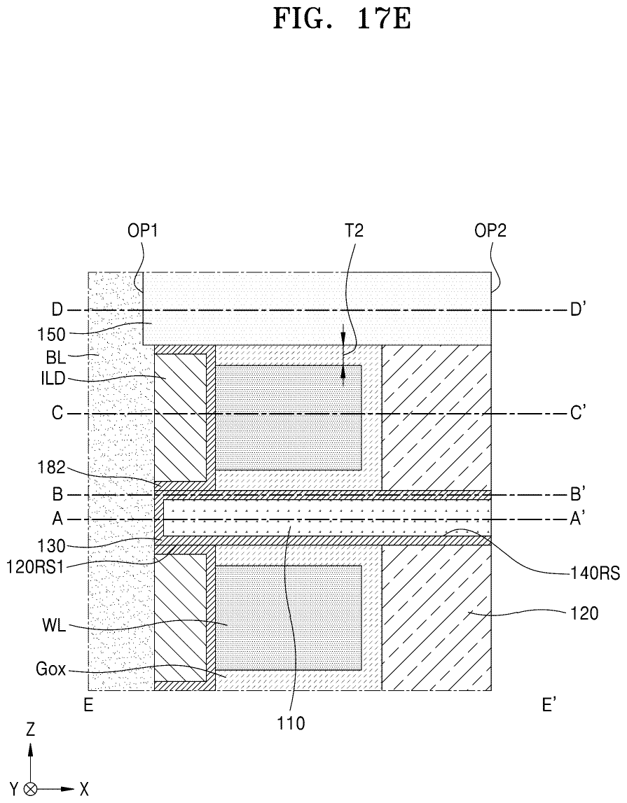

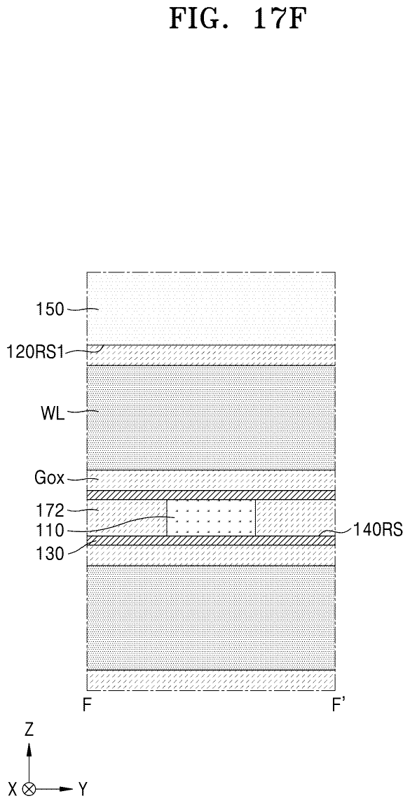

In FIGS. 16A to 16F and 17A to 17F, the second mold insulating layer 164 filling the second opening OP2 may be removed. On the inner wall of the second opening OP2 from which the second mold insulating layer 164 has been removed, respective side surfaces of the two sacrificial insulating layers 120, the two first capping layers 130, the semiconductor pattern 110, the vertical separation insulating layer 150, and the device separation layer DSL may be exposed.

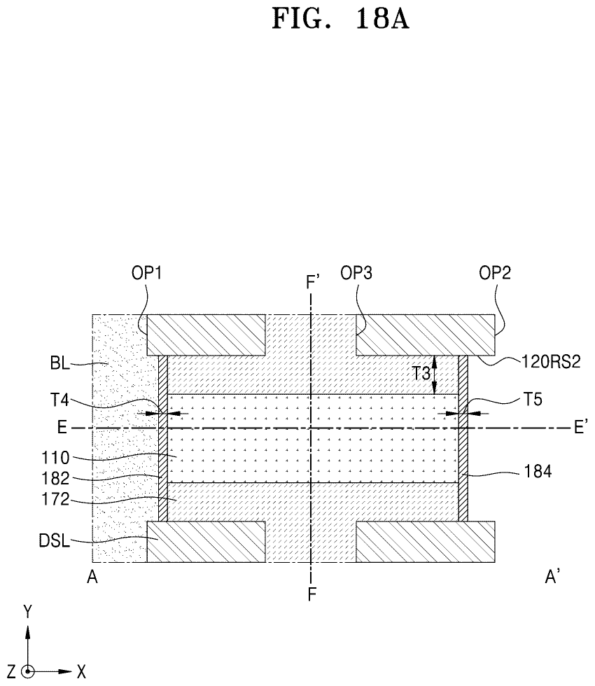

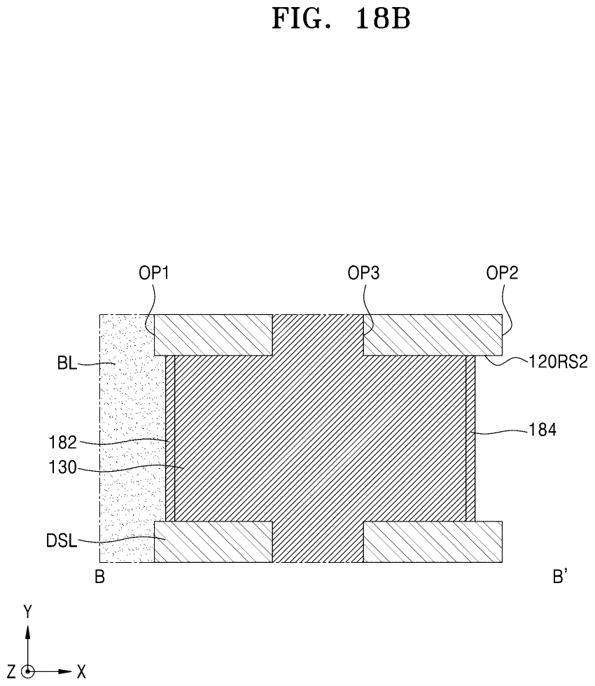

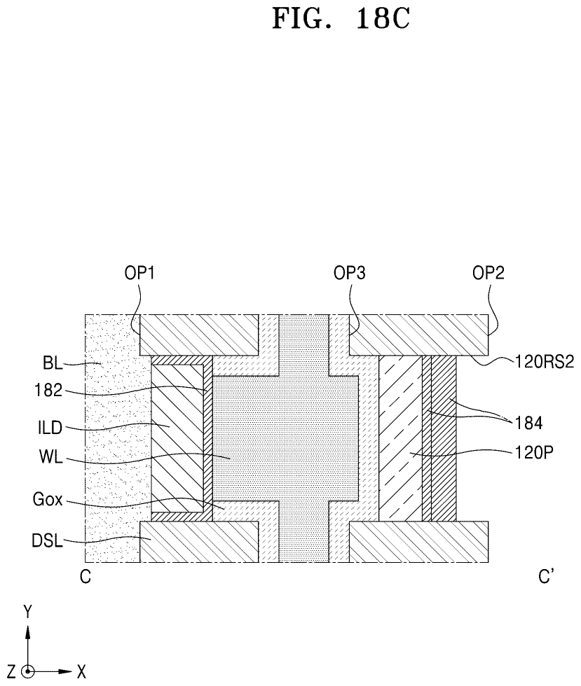

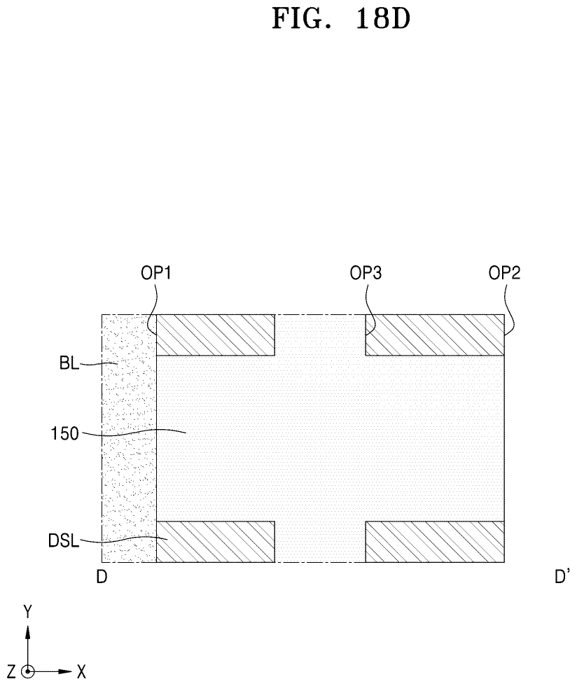

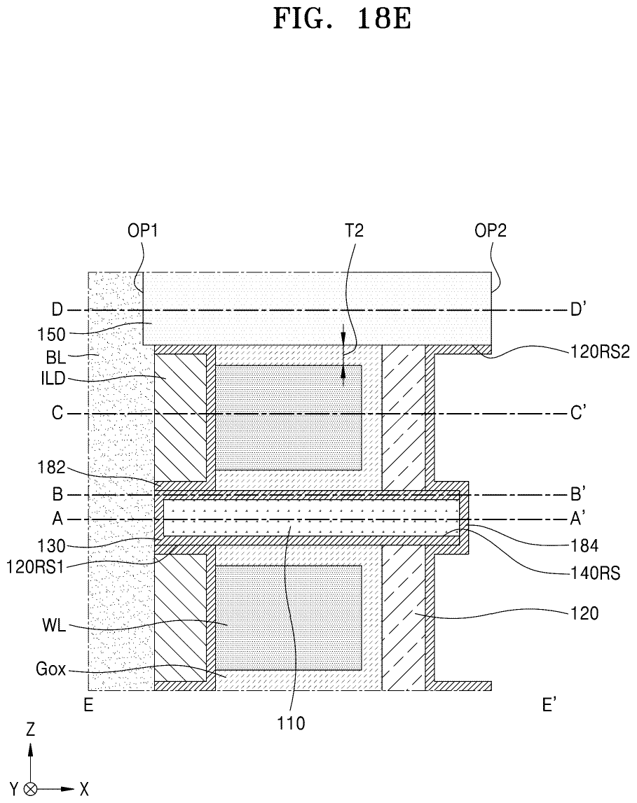

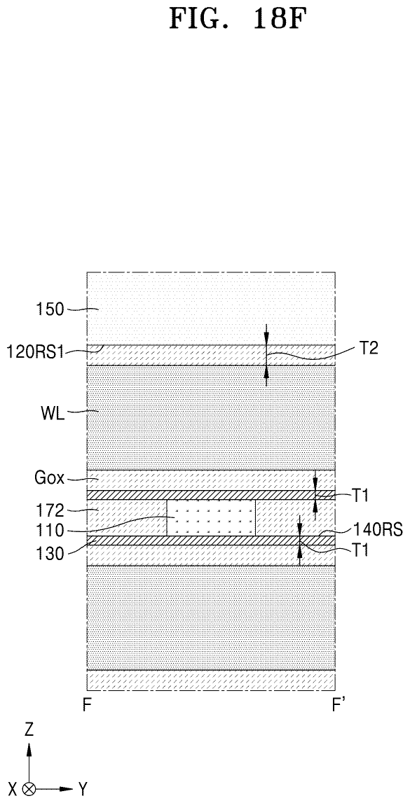

In FIGS. 17A to 17F and 18A to 18F, a portion of the sacrificial insulating layer 120 that is exposed through the second opening OP2 may be removed to form a second recess space 120RS2. A portion of the sacrificial insulating layer 120 that remains after the second recess space 120RS2 has been formed may become an insulating pattern 120P. In the process of forming the second recess space 120RS2, portions of respective ends of the semiconductor pattern 110 and the first capping layers 130 respectively covering the upper and lower surfaces of the semiconductor pattern 110, the respective ends facing the second opening OP2, may be removed. For example, in the process of forming the second recess space 120RS2, respective ends of the semiconductor pattern 110 and the first capping layers 130 respectively covering the upper and lower surfaces of the semiconductor pattern 110, the respective ends facing the second opening OP2, may be moved into the second recess space 120RS2 so as to be apart from the second opening OP2. For example, in the process of forming the second recess space 120RS2, respective ends of the semiconductor pattern 110 and the first capping layers 130 respectively covering the upper and lower surfaces of the semiconductor pattern 110, the respective ends facing the second opening OP2, may be moved into the second recess space 120RS2 by at least the second thickness T2 so as to be apart from the second opening OP2.

A fourth capping layer 184 may be formed to cover a surface exposed within the second recess space 120RS2. For example, the fourth capping layer 184 may be formed to conformally cover respective surfaces of the semiconductor pattern 110, the sacrificial insulating layer 120, the first capping layer 130, and the vertical separation insulating layer 150.

The fourth capping layer 184 may include at least one selected from silicon oxide, a high-k dielectric material having a higher dielectric constant than silicon oxide, and a ferroelectric material. In some embodiments, the fourth capping layer 184 may include a metal oxide. For example, the fourth capping layer 184 may include aluminum oxide (AlO) or hafnium oxide (HfO). In some implementations, the fourth capping layer 184 may include the same material as the first capping layer 130. The fourth capping layer 184 may be formed to have a fifth thickness T5. The fifth thickness T5 may be less than the second thickness T2. In some embodiments, the fifth thickness T5 may be substantially equal to the first thickness T1.

FIGS. 19A to 19F are diagrams illustrating an example of a semiconductor memory device according to some implementations. In detail, FIGS. 19A, 19B, 19C, and 19D are horizontal cross-sectional views of portions taken along lines A-A′, B-B′, C-C′, and D-D′ of FIG. 19E, respectively, and FIGS. 19E and 19F are vertical cross-sectional views of portions taken along lines E-E′ and F-F′ of FIG. 19A, respectively. For convenience of illustration, FIGS. 19E and 19F show only a portion corresponding to the stack structure STC portion of FIGS. 4E and 4F.

In FIGS. 19A to 19F, an information storage element SP may be formed to fill the second recess space 120RS2, thereby forming the semiconductor memory device 100. In some implementations, the information storage element SP may be formed to fill the second recess space 120RS2 and the second opening OP2. The information storage element SP may be formed to be in contact with a portion of the fourth capping layer 184 that covers a side surface of the semiconductor pattern 110 that faces the second opening OP2. The side surface of the semiconductor pattern 110 that faces the second opening OP2 may be referred to as a side surface of the other end of the semiconductor pattern 110 in the first horizontal direction (X direction). The semiconductor pattern 110 may extend in the first horizontal direction (X direction). For example, the semiconductor pattern 110 may extend in the first horizontal direction (X direction) between the bit line BL and the information storage element SP. The bit line BL may extend in the vertical direction (Z direction).

The word line WL may have a double-gate shape including a lower word line WLD located below the semiconductor pattern 110 and an upper word line WLU located above the semiconductor pattern 110. A gate dielectric layer Gox may be provided between the lower word line WLD and the semiconductor pattern 110 and between the upper word line WLU and the semiconductor pattern 110. The gate dielectric layer Gox may have the second thickness T2. Each of the lower word line WLD and the upper word line WLU may extend in the second horizontal direction (Y direction). In the first horizontal direction (X direction), a portion of each of the lower word line WLD and the upper word line WLU may have a first horizontal width W1, and another portion of each of the lower word line WLD and the upper word line WLU may have a second horizontal width W2 that is less than the first horizontal width W1. For example, in each of the lower word line WLD and the upper word line WLU, a portion overlapping the semiconductor pattern 110 in the vertical direction (Z direction) and another portion adjacent to such a portion may each have the first horizontal width W1, which is relatively large. Also, in each of the lower word line WLD and the upper word line WLU, a portion arranged between a pair of third openings OP3 adjacent to each other in the first horizontal direction (X direction) and a pair of device separation layers DSL filling the pair of third openings OP3 and another portion adjacent to such a portion may each have the second horizontal width W2, which is relatively small. A portion of each of the lower word line WLD and the upper word line WLU that has the first horizontal width W1 may be referred to as a first portion, and a portion of each of the lower word line WLD and the upper word line WLU that has the second horizontal width W2 may be referred to as a second portion.

The semiconductor pattern 110 may include a source region 110S, a drain region 110D, and a channel region 110C located between the source region 110S and the drain region 110D. The channel region 110C may be a portion of the semiconductor pattern 110 that overlaps the word line WL in the vertical direction (Z direction). The source region 110S may be a portion of the semiconductor pattern 110 that is located between the channel region 110C and the bit line BL. The drain region 110D may be a portion of the semiconductor pattern 110 that is located between the channel region 110C and the information storage element SP. The bit line BL may be in contact with the third capping layer 182 covering the source region 110S, and the information storage element SP may be in contact with the fourth capping layer 184 covering the drain region 110D.

The plurality of device separation layers DSL may be apart from each other in each of the first horizontal direction (X direction) and the second horizontal direction (Y direction), and may extend in the vertical direction (Z direction). The plurality of device separation layers DSL may be apart from the semiconductor pattern 110. In a plan view, the semiconductor pattern 110 may be apart from each of a pair of device separation layers DSL, which are apart from each other in the second horizontal direction (Y direction) and in contact with the bit line BL, and another pair of device separation layers DSL, which are apart from each other in the second horizontal direction (Y direction) and in contact with the information storage element SP, and may extend in the first horizontal direction (X direction) between the pair of device separation layers DSL in contact with the bit line BL and between the other pair of device separation layers DSL in contact with the information storage element SP.

The first capping layer 130, the second capping layer 172, the third capping layer 182, and the fourth capping layer 184 may constitute a capping structure CPL. Each of the first capping layer 130, the third capping layer 182, and the fourth capping layer 184 may include the same material. In some implementations, each of the first capping layer 130, the third capping layer 182, and the fourth capping layer 184, and at least a portion of the second capping layer 172 may include the same material. For example, the first capping layer 130, the second capping layer 172, the third capping layer 182, and the fourth capping layer 184 may include the same material. The second capping layer 172 may be formed together with the gate dielectric layer Gox, and may include the same material as the gate dielectric layer Gox. In some implementations, at least a portion of the gate dielectric layer Gox, at least a portion of the second capping layer 172, the first capping layer 130, the third capping layer 182, and the fourth capping layer 184 may include the same material. For example, the gate dielectric layer Gox, the first capping layer 130, the second capping layer 172, the third capping layer 182, and the fourth capping layer 184 may all include the same material.

The capping structure CPL may surround the semiconductor pattern 110. For example, the capping structure CPL may completely surround the semiconductor pattern 110 so as to cover upper and lower surfaces, two side surfaces in the first horizontal direction (X direction), and two side surfaces in the second horizontal direction (Y direction) of the semiconductor pattern 110. Each of the upper and lower surfaces of the semiconductor pattern 110 may be covered by the first capping layer 130. The first capping layer 130 may be arranged between the gate dielectric layer Gox covering the word line WL and the semiconductor pattern 110 and between the insulating pattern 120P and the semiconductor pattern 110. Each of the two side surfaces of the semiconductor pattern 110 in the second horizontal direction (Y direction) may be covered by the second capping layer 172. The second capping layer 172 may be arranged between the device separation layer DSL and the semiconductor pattern 110. A side surface of an end of the semiconductor pattern 110 in the first horizontal direction (X direction) may be covered by the third capping layer 182, and a side surface of the other end of the semiconductor pattern 110 in the first horizontal direction (X direction) may be covered by the fourth capping layer 184. The third capping layer 182 may be arranged between the bit line BL and the semiconductor pattern 110 and between the bit line BL and the second capping layer 172. In some implementations, the third capping layer 182 may be arranged between the bit line BL and the semiconductor pattern 110, between the interlayer insulating layer ILD and the gate dielectric layer Gox, between the interlayer insulating layer ILD and the word line WL, and between the interlayer insulating layer ILD and the vertical separation insulating layer 150. The fourth capping layer 184 may be arranged between a first electrode 192 of the information storage element SP and the semiconductor pattern 110 and between the first electrode 192 of the information storage element SP and the second capping layer 172. In some implementations, the fourth capping layer 184 may be arranged between the first electrode 192 of the information storage element SP and the semiconductor pattern 110, between the first electrode 192 of the information storage element SP and the insulating pattern 120P, and between the first electrode 192 of the information storage element SP and the vertical separation insulating layer 150.

The first capping layer 130 covering each of the upper and lower surfaces of the semiconductor pattern 110 may have the first thickness T1, the second capping layer 172 covering each of the two side surfaces of the semiconductor pattern 110 in the second horizontal direction (Y direction) may have the third thickness T3, the third capping layer 182 covering the side surface of the end of the semiconductor pattern 110 in the first horizontal direction (X direction) may have the fourth thickness T4, and the fourth capping layer 184 covering the side surface of the other end of the semiconductor pattern 110 in the first horizontal direction (X direction) may have the fifth thickness T5.

Each of the first capping layer 130, the third capping layer 182, and the fourth capping layer 184 may be formed to have a thickness that may cause tunneling while blocking hydrogen movement between two layers between which each of the first capping layer 130, the third capping layer 182, and the fourth capping layer 184 is provided.

For example, the first capping layer 130 may be provided between the channel region 110C of the semiconductor pattern 110 and the word line WL. The word line WL, the gate dielectric layer Gox, the channel region 110C, and portions of the first capping layer 130 respectively covering upper and lower surfaces of the channel region 110C may together form a metal-oxide-semiconductor (MOS) capacitor. Because the first capping layer 130 has the first thickness T1 that may cause tunneling, the channel region 110C and the portions of the first capping layer 130 respectively covering the upper and lower surfaces of the channel region 110C may correspond to the “S (semiconductor)” of the MOS capacitor. The gate dielectric layer Gox, the insulating pattern 120P, and the fourth capping layer 184 may be provided between the word line WL and the information storage element SP. The insulating pattern 120P may include a nitride. In some embodiments, the insulating pattern 120P may include silicon nitride. A portion of the first capping layer 130 may be provided between the insulating pattern 120P and the semiconductor pattern 110. The first capping layer 130 may block hydrogen movement, and thus may prevent hydrogen from penetrating from the insulating pattern 120P into the semiconductor pattern 110, thereby preventing the semiconductor pattern 110 from being deteriorated.

For example, the third capping layer 182 may be provided between the source region 110S of the semiconductor pattern 110 and the bit line BL. Because the third capping layer 182 has the fourth thickness T4 that may cause tunneling, the source region 110S of the semiconductor pattern 110 and the bit line BL may be electrically connected to each other. The third capping layer 182 may block hydrogen movement, and thus may prevent hydrogen from penetrating from the bit line BL into the semiconductor pattern 110, thereby preventing the semiconductor pattern 110 from being deteriorated.

For example, the fourth capping layer 184 may be provided between the drain region 110D of the semiconductor pattern 110 and the information storage element SP. Because the fourth capping layer 184 has the fifth thickness T5 that may cause tunneling, the drain region 110D of the semiconductor pattern 110 and the information storage element SP may be electrically connected to each other. For example, the drain region 110D of the semiconductor pattern 110 and the first electrode 192 of the information storage element SP may be electrically connected to each other. The fourth capping layer 184 may block hydrogen movement, and thus may prevent hydrogen from penetrating from the first electrode 192 of the information storage element SP into the semiconductor pattern 110, thereby preventing the semiconductor pattern 110 from being deteriorated.

The first thickness T1, the fourth thickness T4, and the fifth thickness T5 may be equal to each other. For example, the first thickness T1, the fourth thickness T4, and the fifth thickness T5 may each be 3 nm or less. In some embodiments, the first thickness T1, the fourth thickness T4, and the fifth thickness T5 may each be about 1 nm to about 1.5 nm. The second capping layer 172 may be formed to have a thickness that may block hydrogen movement between two layers between which the second capping layer 172 is provided. The third thickness T3 may be greater than the first thickness T1. In some implementations, the third thickness T3 may be equal to or greater than the second thickness T2.

For example, the second capping layer 172 may be provided between the semiconductor pattern 110 and the plurality of device separation layers DSL. The second capping layer 172 may block hydrogen movement, and thus may prevent hydrogen from penetrating from the plurality of device separation layers DSL into the semiconductor pattern 110, thereby preventing the semiconductor pattern 110 from being deteriorated.

In some implementations, the information storage element SP may be a capacitor including a first electrode 192, a second electrode 196, and a capacitor dielectric layer 194 provided between the first electrode 192 and the second electrode 196. The first electrode 192 may be formed to be in contact with a portion of the fourth capping layer 184 that covers the side surface of the other end of the semiconductor pattern 110 in the first horizontal direction (X direction). For example, the first electrode 192 may be formed to cover the fourth capping layer 184 covering a surface exposed within the second recess space 120RS2. The capacitor dielectric layer 194 may be formed to cover the first electrode 192 covering the fourth capping layer 184. For example, the capacitor dielectric layer 194 may be formed to conformally cover the first electrode 192. The second electrode 196 may be formed to cover the capacitor dielectric layer 194. In some embodiments, the second electrode 196 may be formed to fill both the second recess space 120RS2 and the second opening OP2. The second electrode 196 may be connected to the ground wiring PP shown in FIG. 3, or may be a portion of the ground wiring PP. In some embodiments, a portion of the second electrode 196 that fills the second opening OP2 may be the ground wiring PP shown in FIG. 3. The first electrode 192 and the second electrode 196 may be referred to as a lower electrode and an upper electrode, respectively.

The first electrode 192 may include a metal, a conductive metal nitride, a conductive metal silicide, or a combination thereof. In some implementations, the first electrode 192 may include a high-melting point metal layer, such as a cobalt layer, a titanium layer, a nickel layer, a tungsten layer, and a molybdenum layer. For example, the first electrode 192 may include a metal nitride layer, such as a titanium nitride layer, a titanium silicon nitride layer, a titanium aluminum nitride layer, a tantalum nitride layer, a tantalum silicon nitride layer, a tantalum aluminum nitride layer, and a tungsten nitride layer. The capacitor dielectric layer 194 may include at least one selected from a high-k dielectric material, which has a higher dielectric constant than silicon oxide, and a ferroelectric material. The capacitor dielectric layer 194 may have a thickness that is greater than the first thickness T1. In some implementations, the capacitor dielectric layer 194 may have a thickness that is equal to or less than the second thickness T2 and greater than the first thickness T1. For example, the capacitor dielectric layer 194 may include at least one of a metal oxide and a dielectric material having a perovskite structure. In some implementations, the capacitor dielectric layer 194 may include at least one material selected from hafnium oxide (HfO), hafnium silicate (HfSiO), hafnium oxynitride (HfON), hafnium silicon oxynitride (HfSiON), lanthanium oxide (LaO), lanthanium aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). The second electrode 196 may include, for example, doped silicon, Ru, RuO, Pt, PtO, Ir, IrO, SrRuO (SRO), (Ba,Sr)RuO (BSRO), CaRuO (CRO), BaRuO, La(Sr,Co)O, Ti, TiN, W, WN, Ta, TaN, TiAlN, TiSiN, TaAlN, TaSiN, or a combination thereof. In some embodiments, the second electrode 196 may include W.

The semiconductor memory device 100 may include the capping structure CPL surrounding the semiconductor pattern 110, and thus, hydrogen may be prevented from penetrating into the semiconductor pattern 110 from the insulating pattern 120P, the bit line BL, the first electrode 192 of the information storage element SP, the device separation layer DSL, etc. Also, in the capping structures CPL, the first capping layer 130 provided between the gate dielectric layer Gox and the semiconductor pattern 110, the third capping layer 182 provided between the bit line BL and the semiconductor pattern 110, and the fourth capping layer 184 provided between the first electrode 192 of the information storage element SP and the semiconductor pattern 110 may each have a thickness that may cause tunneling, and thus, the channel region 110C of the semiconductor pattern 110 may function as a channel of a cell transistor CT (see FIG. 3), and the source region 110S and the drain region 110D of the semiconductor pattern 110 may be electrically connected to the bit line BL and the first electrode 192 of the information storage element SP, respectively.

Accordingly, the semiconductor pattern 110 may be prevented from being deteriorated, and thus, the semiconductor memory device 100 may have improved operational reliability.

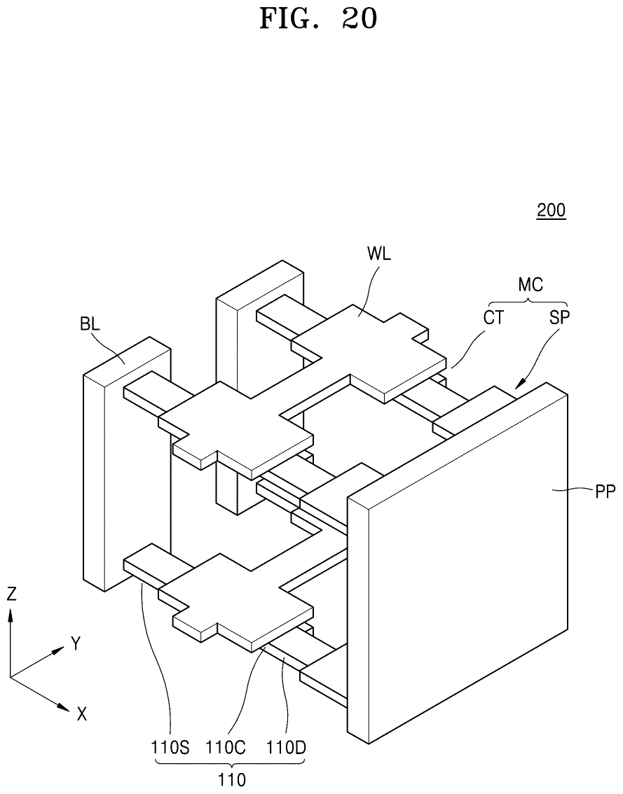

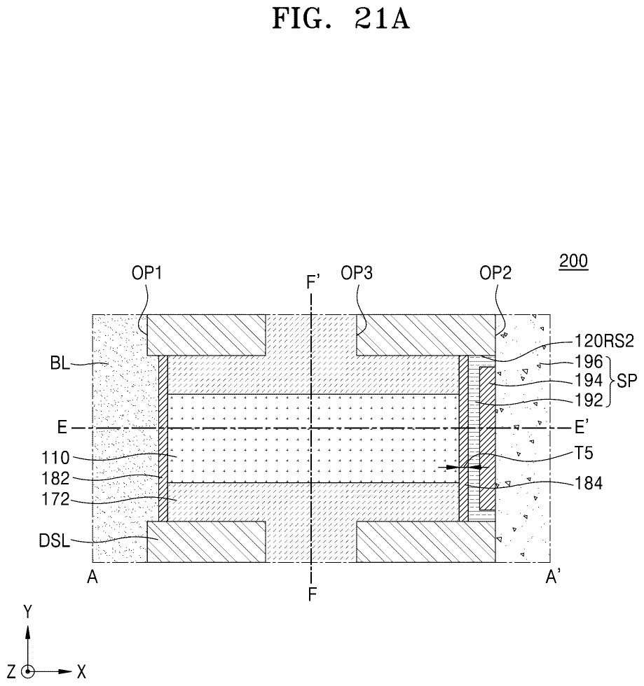

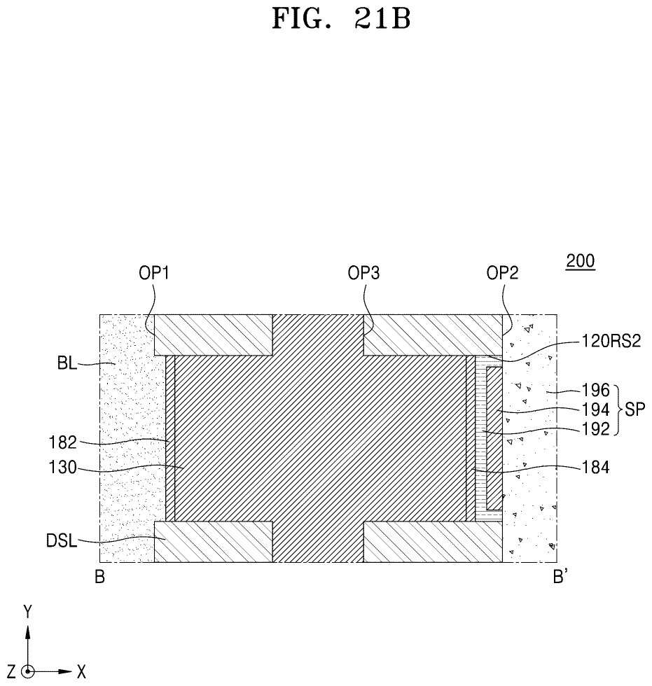

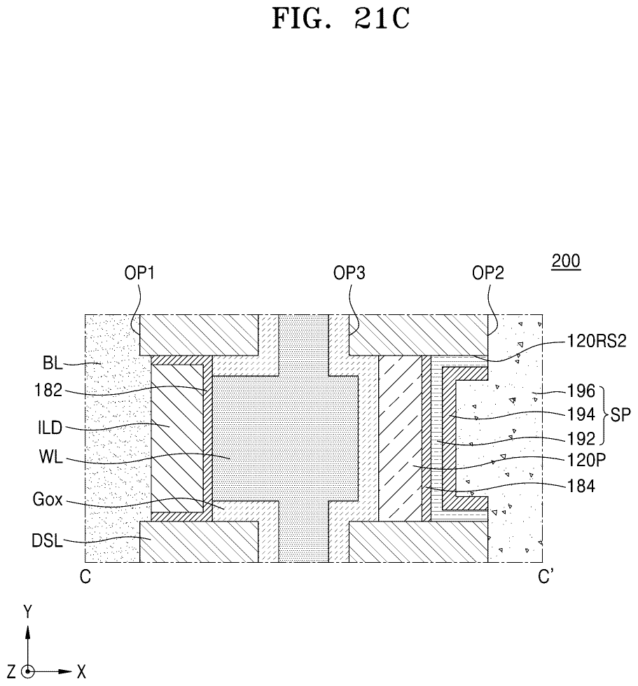

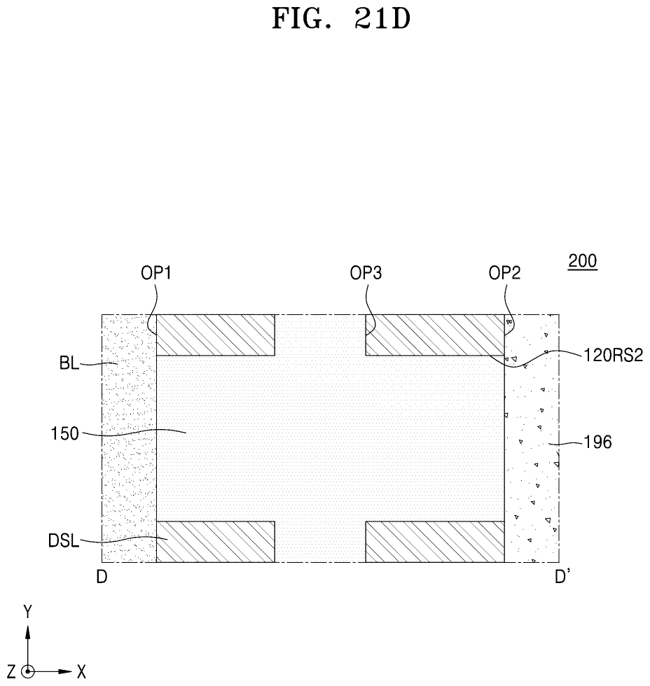

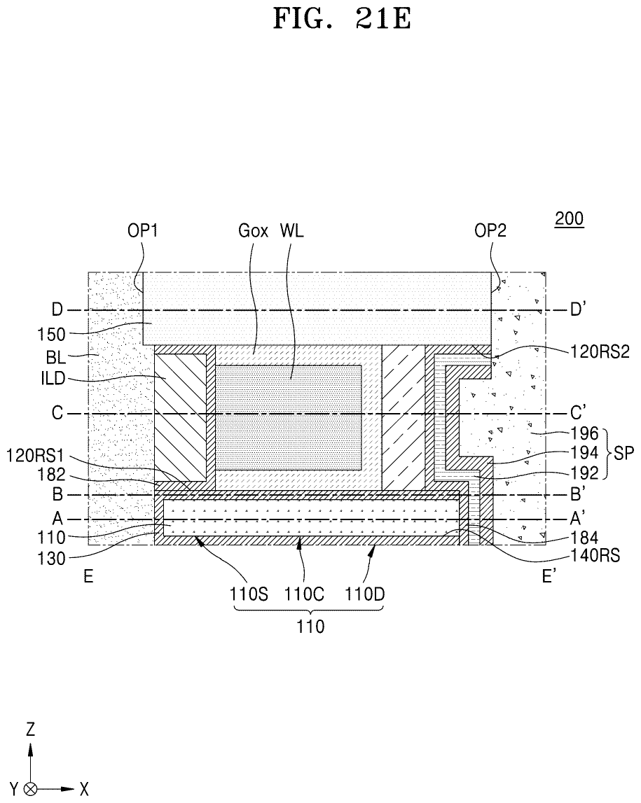

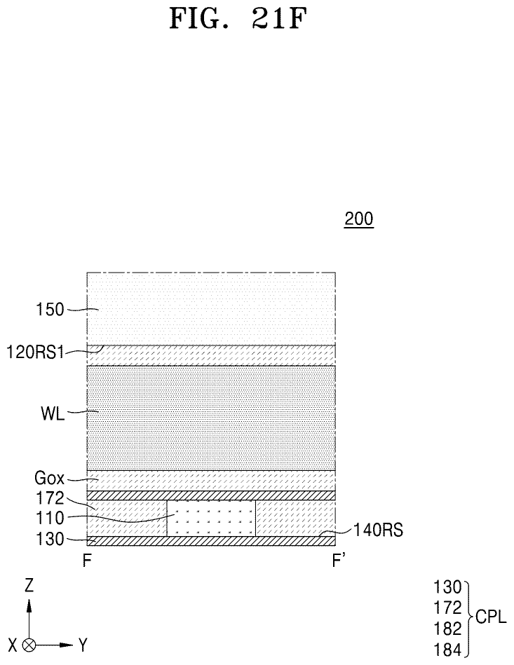

FIG. 20 is a perspective view illustrating an example of a memory cell included in a semiconductor memory device according to some implementations. In FIG. 20, a semiconductor memory device 200 may include a memory cell MC including a cell transistor CT and an information storage element SP. The cell transistor CT may be arranged between a word line WL and a bit line BL. The cell transistor CT may include a semiconductor pattern 110. An end of the semiconductor pattern 110 may face the bit line BL, and the other end of the semiconductor pattern 110 may face the information storage element SP. The end of the semiconductor pattern 110 may be electrically connected to the bit line BL, and the other end of the semiconductor pattern 110 may be electrically connected to the information storage element SP. A capping structure CPL (see FIG. 21F) may be provided between the semiconductor pattern 110 and the bit line BL and between the semiconductor pattern 110 and the information storage element SP.

The word line WL may extend in the second horizontal direction (Y direction), the bit line BL may extend in the vertical direction (Z direction), and the semiconductor pattern 110 may extend in the first horizontal direction (X direction). A gate dielectric layer Gox (see FIGS. 21E and 21F) may be provided between the word line WL and the semiconductor pattern 110. In some implementations, the bit line BL, the semiconductor pattern 110, and the information storage element SP may be sequentially located in the first horizontal direction (X direction).

The semiconductor pattern 110 may include a source region 110S, a drain region 110D, and a channel region 110C located between the source region 110S and the drain region 110D. The source region 110S of the semiconductor pattern 110 may be electrically connected to the bit line BL. The drain region 110D of the semiconductor pattern 110 may be electrically connected to the information storage element SP. In some implementations, the information storage element SP may be a capacitor including a first electrode, a second electrode, and a capacitor dielectric layer provided between the first electrode and the second electrode, wherein the first electrode of the capacitor may be electrically connected to a drain region of the cell transistor CT, and the second electrode of the capacitor may be connected to a ground wiring PP. The word line WL may surround at least a portion of the channel region 110C of the semiconductor pattern 110.

In some implementations, the word line WL may have a single-gate shape covering one of upper and lower surfaces of the channel region 110C of the semiconductor pattern 110. For example, the word line WL may cover the upper surface of the channel region 110C of the semiconductor pattern 110. In some implementations, the word line WL may cover the lower surface of the channel region 110C of the semiconductor pattern 110.

FIGS. 21A to 21F are diagrams illustrating an example of a semiconductor memory device according to some implementations. In detail, FIGS. 21A, 21B, 21C, and 21D are horizontal cross-sectional views of portions taken along lines A-A′, B-B′, C-C′, and D-D′ of FIG. 21E, respectively, and FIGS. 21E and 21F are vertical cross-sectional views of portions taken along lines E-E′ and F-F′ of FIG. 21A, respectively.

In FIGS. 21A to 21F, after stacking a plurality of stack structures STC each including one sacrificial insulating layer 120, two first capping layers 130, a sacrificial semiconductor layer 140, and a vertical separation insulating layer 150, instead of a plurality of stack structures STC each including two sacrificial insulating layers 120, two first capping layers 130, a sacrificial semiconductor layer 140, and a vertical separation insulating layer 150, as shown in FIGS. 4A to 4F, the manufacturing method described with reference to FIGS. 5A to 19F may be performed, thereby forming the semiconductor memory device 200.

The semiconductor memory device 200 may include a semiconductor pattern 110 extending in the first horizontal direction (X direction), a word line WL extending in a second horizontal direction (Y direction), a bit line BL electrically connected to an end of the semiconductor pattern 110 in the first horizontal direction (X direction) and extending in the vertical direction (Z direction), an information storage element SP electrically connected to the other end of the semiconductor pattern 110 in the first horizontal direction (X direction), and a capping structure CPL surrounding the semiconductor pattern 110.

In some implementations, the word line WL may have a single-gate shape located above the semiconductor pattern 110, but the present disclosure is not limited thereto. For example, the word line WL may have a single-gate shape located below the semiconductor pattern 110.

The semiconductor pattern 110 may include a source region 110S, a drain region 110D, and a channel region 110C located between the source region 110S and the drain region 110D. The channel region 110C may be a portion of the semiconductor pattern 110 that overlaps the word line WL in the vertical direction (Z direction). The source region 110S may be a portion of the semiconductor pattern 110 that is located between the channel region 110C and the bit line BL. The drain region 110D may be a portion of the semiconductor pattern 110 that is located between the channel region 110C and the information storage element SP. The bit line BL may be in contact with the third capping layer 182 covering the source region 110S, and the information storage element SP may be in contact with the fourth capping layer 184 covering the drain region 110D.

The first capping layer 130, the second capping layer 172, the third capping layer 182, and the fourth capping layer 184 may constitute a capping structure CPL. The capping structure CPL may surround the semiconductor pattern 110. For example, the capping structure CPL may completely surround the semiconductor pattern 110 so as to cover upper and lower surfaces, two side surfaces in the first horizontal direction (X direction), and two side surfaces in the second horizontal direction (Y direction) of the semiconductor pattern 110. Each of the upper and lower surfaces of the semiconductor pattern 110 may be covered by the first capping layer 130. Each of the two side surfaces of the semiconductor pattern 110 in the second horizontal direction (Y direction) may be covered by the second capping layer 172. A side surface of an end of the semiconductor pattern 110 in the first horizontal direction (X direction) may be covered by the third capping layer 182, and a side surface of the other end of the semiconductor pattern 110 in the first horizontal direction (X direction) may be covered by the fourth capping layer 184.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device comprising:
a semiconductor pattern extending in a first horizontal direction;
a capping structure surrounding the semiconductor pattern;
a bit line electrically connected to a first end of the semiconductor pattern in the first horizontal direction and extending in a vertical direction;
an information storage element electrically connected to a second end of the semiconductor pattern in the first horizontal direction;
a word line intersecting with the semiconductor pattern and extending in a second horizontal direction orthogonal to the first horizontal direction; and
a gate dielectric layer between the word line and the semiconductor pattern,
wherein the capping structure comprises a first capping layer, a second capping layer, a third capping layer, and a fourth capping layer,
wherein the first capping layer covers each of upper and lower surfaces of the semiconductor pattern,
wherein the second capping layer covers two side surfaces of the semiconductor pattern in the second horizontal direction,
wherein the third capping layer covers a side surface of the first end of the semiconductor pattern that faces the bit line in the first horizontal direction,
wherein the fourth capping layer covers a side surface of the second end of the semiconductor pattern that faces the information storage element in the first horizontal direction, and
wherein each of the first capping layer, the third capping layer, and the fourth capping layer has a thickness that is less than a thickness of the gate dielectric layer.

2. The semiconductor memory device of claim 1, wherein the second capping layer has a thickness that is greater than the thickness of each of the first capping layer, the third capping layer, and the fourth capping layer.

3. The semiconductor memory device of claim 1, wherein the second capping layer has a thickness that is a same as or greater than the thickness of the gate dielectric layer.

4. The semiconductor memory device of claim 1,
wherein each of the first capping layer, the third capping layer, and the fourth capping layer has a same thickness, and
wherein the gate dielectric layer has a thickness that is at least twice the thickness of each of the first capping layer, the third capping layer, and the fourth capping layer.

5. The semiconductor memory device of claim 1, wherein the gate dielectric layer, the second capping layer, the first capping layer, the third capping layer, and the fourth capping layer comprise a same material as each other.

6. The semiconductor memory device of claim 1,
wherein the semiconductor pattern comprises an oxide semiconductor material, and
wherein each of the first capping layer, the third capping layer, and the fourth capping layer comprises a metal oxide.

7. The semiconductor memory device of claim 1, comprising a plurality of device separation layers being apart from each other in each of the first horizontal direction and the second horizontal direction, extending in the vertical direction, and being apart from the semiconductor pattern,
wherein the plurality of device separation layers includes a first pair of device separation layers in contact with the bit line and a second pair of device separation layers in contact with the information storage element, and
wherein, in a plan view, the semiconductor pattern extends in the first horizontal direction between the first pair of device separation layers and between the second pair of device separation layers.

8. The semiconductor memory device of claim 7,
wherein the word line comprises a first portion and a second portion,
wherein the first portion has a first horizontal width in the first horizontal direction above the semiconductor pattern, and
wherein the second portion has a second horizontal width in the first horizontal direction between a pair of device separation layers apart from each other in the first horizontal direction, among the plurality of device separation layers,
wherein the second horizontal width is less than the first horizontal width.

9. The semiconductor memory device of claim 1,
wherein the first capping layer is provided between the gate dielectric layer and the semiconductor pattern,
wherein the third capping layer is provided between the bit line and the semiconductor pattern, and
wherein the fourth capping layer is provided between the information storage element and the semiconductor pattern.

10. The semiconductor memory device of claim 1, comprising an insulating pattern between the word line and the information storage element,
wherein the first capping layer is between the gate dielectric layer and the semiconductor pattern and between the insulating pattern and the semiconductor pattern.

11. A semiconductor memory device comprising:
a plurality of device separation layers being apart from each other in each of a first horizontal direction and a second horizontal direction and extending in a vertical direction, the second horizontal direction being orthogonal to the first horizontal direction;
a semiconductor pattern being apart from the plurality of device separation layers and extending in the first horizontal direction between the plurality of device separation layers;
a capping structure surrounding the semiconductor pattern;
a bit line electrically connected to a first end of the semiconductor pattern in the first horizontal direction and extending in the vertical direction;
an information storage element electrically connected to a second end of the semiconductor pattern in the first horizontal direction;
a word line intersecting with the semiconductor pattern and extending in the second horizontal direction;
an insulating pattern between the word line and the information storage element; and
a gate dielectric layer between the word line and the semiconductor pattern,
wherein a first portion of the capping structure that covers a side surface of the first end of the semiconductor pattern and a second portion of the capping structure that covers a side surface of the second end of the semiconductor pattern each have a thickness that is less than a thickness of the gate dielectric layer.

12. The semiconductor memory device of claim 11,
wherein the capping structure comprises a first capping layer, a second capping layer, a third capping layer, and a fourth capping layer,
wherein the first capping layer covers an upper surface and a lower surface of the semiconductor pattern,
wherein the second capping layer covers two side surfaces of the semiconductor pattern in the second horizontal direction,
wherein the third capping layer covers the side surface of the first end of the semiconductor pattern, and
wherein the fourth capping layer covers the side surface of the second end of the semiconductor pattern.

13. The semiconductor memory device of claim 12, wherein the second capping layer has a thickness that is greater than a thickness of each of the first capping layer, the third capping layer, and the fourth capping layer and is a same as or greater than the thickness of the gate dielectric layer.

14. The semiconductor memory device of claim 12,
wherein each of the first capping layer, the third capping layer, and the fourth capping layer has a thickness of 1 nm to 1.5 nm, and
wherein the gate dielectric layer has a thickness of 3 nm or more.

15. The semiconductor memory device of claim 12,
wherein the first capping layer is between the gate dielectric layer and the semiconductor pattern and between the insulating pattern and the semiconductor pattern,
wherein the second capping layer is between the plurality of device separation layers and the semiconductor pattern,
wherein the third capping layer is between the bit line and the semiconductor pattern, and
wherein the fourth capping layer is between the information storage element and the semiconductor pattern.

16. The semiconductor memory device of claim 15,
wherein the semiconductor pattern comprises an oxide semiconductor material,
wherein the bit line and the information storage element comprise a metal, and
wherein the insulating pattern comprises a nitride.

17. The semiconductor memory device of claim 11,
wherein the plurality of device separation layers includes a first pair of device separation layers adjacent to each other in the second horizontal direction and a second pair of device separation layers adjacent to each other in the second horizontal direction,
wherein the semiconductor pattern extends in the first horizontal direction between the first pair of device separation layers and the second pair of device separation layers, and
wherein the first pair of device separation layers contact the bit line, and the second pair of device separation layers contact the information storage element.

18. A semiconductor memory device comprising:
a plurality of device separation layers being apart from each other in each of a first horizontal direction and a second horizontal direction and extending in a vertical direction, the second horizontal direction being orthogonal to the first horizontal direction;
a semiconductor pattern being apart from the plurality of device separation layers, extending in the first horizontal direction between the plurality of device separation layers, and comprising an oxide semiconductor material;
a capping structure comprising a first capping layer, a second capping layer, a third capping layer, and a fourth capping layer, the capping structure surrounding the semiconductor pattern, the first capping layer covering an upper surface and a lower surface of the semiconductor pattern, the second capping layer covering side surfaces of the semiconductor pattern in the second horizontal direction, the third capping layer covering a side surface of a first end of the semiconductor pattern in the first horizontal direction, and the fourth capping layer covering a side surface of a second end of the semiconductor pattern in the first horizontal direction;
a bit line electrically connected to the first end of the semiconductor pattern in the first horizontal direction, contacting the third capping layer, and extending in the vertical direction;
an information storage element contacting the fourth capping layer, electrically connected to the second end of the semiconductor pattern in the first horizontal direction, and comprising a first electrode, a second electrode, and a capacitor dielectric layer between the first electrode and the second electrode;
a word line intersecting with the semiconductor pattern and extending in the second horizontal direction;
an insulating pattern between the word line and the first electrode and in contact with the first capping layer; and
a gate dielectric layer between the word line and the semiconductor pattern and contacting the first capping layer,
wherein each of the third capping layer and the fourth capping layer has a thickness that is less than a thickness of each of the second capping layer and the gate dielectric layer.

19. The semiconductor memory device of claim 18,
wherein each of the bit line and the first electrode comprises a metal,
wherein the insulating pattern comprises a nitride, and
wherein the capping structure comprises a metal oxide.

20. The semiconductor memory device of claim 18,
wherein each of the first capping layer, the third capping layer, and the fourth capping layer has a thickness of 1 nm to 1.5 nm, and
wherein the gate dielectric layer has a thickness that is at least twice the thickness of each of the first capping layer, the third capping layer, and the fourth capping layer.
